(19) United States
(12) Patent Application Publication
(10) Pub. No.: US 2024/0303393 A1
(43) Pub. Date: Sep. 12, 2024

(54) SYSTEMS AND METHODS FOR SIMULATING, COMPARING, AND ADJUSTING TEXTILE PROCESSING SYSTEMS TO HAVE IMPROVED IMPACT ON FINANCIAL AND ENVIRONMENTAL SUSTAINABILITY

(71) Applicant: Kemin Industries, Inc., Des Moines, IA (US)

(72) Inventors: Felipe Jannuzzi Guerreiro, Rome (IT); Giovanni Maiani, Riccione (IT)

(21) Appl. No.: 18/599,764

(22) Filed: Mar. 8, 2024

Related U.S. Application Data
(60) Provisional application No. 63/451,072, filed on Mar. 9, 2023.

(51) Int. Cl. G06F 30/20

(52) U.S. Cl. CPC G06F 30/20

(57) ABSTRACT

A process for evaluating changing an overall textile processing facility to be more sustainable that includes the steps of: defining a virtual wash plant having virtual pieces of equipment and virtual wash inputs; defining a baseline recipe for the production of a textile using the virtual wash plant; defining an alternate recipe for the production of the textile that is different than the baseline recipe using the virtual wash plant; determining a set of processing sustainability related cost and input usage differences between the baseline recipe and the alternate recipe; and changing the textile processing facility used recipe at the textile processing facility to correspond to the alternate recipe if the alternate recipe is determined to be more environmentally sustainable, more financially sustainable, or both more environmentally sustainable and financially sustainable than the baseline recipe.

### CROSS-REFERENCE TO RELATED APPLICATION

The present application claims the benefit of and priority to U.S. Provisional Patent Application No. 63/451,072, filed Mar. 9, 2023, entitled “SYSTEMS AND METHODS FOR SIMULATING, COMPARING, AND ADJUSTING TEXTILE PROCESSING SYSTEMS TO HAVE IMPROVED IMPACT ON FINANCIAL AND ENVIRONMENTAL SUSTAINABILITY,” the entire disclosure of which is incorporated by reference herein.

### BACKGROUND

The textile industry as a whole is among the most polluting industries worldwide, but with opportunities for improvement in both education about steps to prevent pollution and opportunities for innovation to make systems both economical and efficient while lowering pollution and environmental impact. Among various environmental impacts caused by various aspects of the processing of textiles, CO₂ emissions are quickly becoming a dominant facet due to rising concerns related to climate change. As awareness of the consequences of climate change increases worldwide, more and more pressures are exerted by customers and brands on industries to limit as much as possible the combustion of fossil fuels, thus including, coal, gasoline, methane, and other hydrocarbons. This can be achieved in several ways. For example, adopting heat exchangers or more efficient types of machinery (e.g., washing machines, boilers, heaters, dryers, etc.) or chemical products that allow for achieving the desired results at lower temperatures, thus requiring lower volumes of fuel to heat large amounts of water.

Similarly, the H₂O footprint of industrial activities is quickly acquiring importance in the sustainability frame since the availability of this natural molecule is becoming critical in large areas of the globe. For instance, the Aral Sea's water volume was 1,093 billion cubic meters in 1960 and 105 billion cubic meters in 2006. Fresh water usage has continued to occur throughout the world. For example, the so called BRICS countries (Brazil, India, and China) have increased the use of freshwater for industrial use from 301 billion cubic meters in 1901 to 1.6 trillion cubic meters in 2012. This problem is exacerbated by the withdrawal of fresh water for industrial uses in those regions of the world. For example, in China, the use of freshwater for industrial applications rose by 160% from 1965 to 2017. Reduction in water use should begin immediately to save water resources. As water footprint reduction becomes more and more urgent, the efficacy of actions to pursue water reduction efficiently are rarely directly apparent because they are intimately interconnected to other aspects of any given industrial process, including CO₂ emissions and financial considerations. For instance, the use of lasers to perform industrial treatments that are normally obtained by other means is often indicated as the best practice to reduce water footprint. However, in this example, this solution may negatively impact CO₂ emissions due to the high power requirement to use such systems, which in some ways counterbalances the positive environmental impact of reduced water usage. Moreover, these solutions can be costlier to the point that they are financially unpractical and/or financially unsustainable for smaller industries. So much so in some instances, companies will not undertake any change. Conversely, chemical products can be sometimes convenient for reducing the needed volumes of water (e.g., by reducing the liquor ratio, which is defined generally as the weight ratio between the total liquor and the dry textile material. For example, in the case of a dyeing process in particular, as the volume of liquor to be taken in a dyebath in proportion to the weight of the textile). However, while the use of chemical products may in certain circumstances reduce water usage, there are often tradeoffs in other areas such as increases in the potential for negative environmental impacts from the use of such chemicals.

Companies and people in the textile industry can also choose to install solar or wind power plants to reduce the CO₂ footprint. They can also potentially use other power suppliers derived from renewable sources of energy. However, this too can often have high costs of investment initially that may prevent significant changes from occurring.

The counterbalancing, interdependent and extreme complex interactions of parameters involved in textile processes make changes to ongoing processes virtually impossible to implement due to the uncertainties of the effects of changes and the extremely large associated costs to any change(s) in the textile industry. Laundries and potentially other textile-related industries do not have efficient tools to perform decisions based on science as they relate to their processes. The variables are great and the costs of new or different equipment very high. There are also significant costs if a change made is actually detrimental to the process and/or costs and/or the environmental impact. Rather, users tend to analyze aspects related to sustainability separately, which makes for an inaccurate assessment in virtually all instances. For example, the user can attempt to reduce the water footprint without analyzing the indirect costs deriving from a possible negative effect on the CO₂ footprint. Indeed, nearly all the main certification bodies certifying sustainability within the textile industry are more focused on analyzing the presence, or concentrations, of contaminants rather than examining the holistic effects of changes to the processing scenario employed, presumably this is due to the heretofore impossibly complex and unanalyzed interactions of the numerous changes possible in the process.

### SUMMARY

An aspect of the present disclosure is generally directed toward a process for implementing changes, which are typically physical changes to the system to a textile processing facility that positively impact the environmental sustainability, the financial sustainability, or both the environmental sustainability and financial sustainability of the textile processing facility that includes the steps of: defining a virtual wash plant having virtual pieces of equipment and virtual wash inputs with defined use parameters that include at least parameters related to energy, fuel, water used, carbon dioxide emitted, time, and cost where the use parameters correspond to physical pieces of equipment and physically available wash inputs at the textile processing facility; defining a baseline recipe for the production of a textile using the virtual wash plant that at least substantially corresponds to a textile processing facility used recipe at the textile processing facility implemented by the physical pieces of equipment and physically available wash inputs at the textile processing facility; defining an alternate recipe for the production of the textile that is different than the baseline recipe using the virtual wash plant; determining quantifiable baseline recipe data related to at least: a baseline recipe cost, a baseline recipe energy usage, a baseline recipe water usage, a baseline recipe processing time, and a baseline recipe carbon dioxide usage based on the processing of a textile using the baseline recipe for the production of the textile; determining the quantifiable alternate recipe data related to at least: an alternate recipe cost, an alternate recipe energy usage, an alternate recipe water usage, an alternate recipe processing time, and an alternate recipe carbon dioxide usage based on the processing of a textile using the alternate recipe for the production of the textile; determining a set of differences between the baseline recipe and the alternate recipe that includes at least the difference between the baseline recipe cost and the alternate recipe cost, the differences between the baseline recipe energy usage and the alternate recipe energy usage, the difference between the baseline recipe water usage and the alternate recipe water usage, the difference between the baseline recipe processing time and the alternate recipe processing time, and the baseline recipe carbon dioxide usage and the alternate recipe carbon dioxide usage; displaying a quantitative estimate of at least one of the set of differences to at least one user of a computing system having a graphical user interface that displays the at least one of the set of differences on an output display of a computing device; determining whether the baseline recipe or the alternate recipe is more environmentally sustainable, financial sustainable, or both the environmentally sustainable and financially sustainable by a processor evaluating the set of differences between the baseline recipe and the alternate recipe; and changing either or both of: (1) the use parameters corresponding to the physical pieces of equipment and the physically available wash inputs at the textile processing facility; and (2) the physical pieces of equipment and physically available wash inputs at the textile processing facility of the textile processing facility used recipe implemented at the textile processing facility to correspond to the alternate recipe if the alternate recipe is determined to be more environmentally sustainable, more financially sustainable, or both more environmentally sustainable and financially sustainable. According to any aspect of the present disclosure, the step of changing the physical pieces of equipment may include the addition of new equipment not already present at the textile processing facility such as by the purchase of newer, potentially more efficient equipment, or the addition of new or different physically available wash inputs and/or use parameters.

Yet another aspect of the present disclosure is generally directed toward a process for evaluating changing an overall textile processing facility to be more sustainable that includes the steps of: defining a virtual wash plant having virtual pieces of equipment and virtual wash inputs; defining a baseline recipe for the production of a textile using the virtual wash plant that at least substantially corresponds to a textile processing facility used recipe at the textile processing facility implemented by the physical pieces of equipment and physically available wash inputs at the textile processing facility; defining an alternate recipe for the production of the textile that is different than the baseline recipe using the virtual wash plant; determining a set of processing sustainability related cost and input usage differences between the baseline recipe and the alternate recipe; a user reviewing the set of processing sustainability related cost and input usage differences and determining whether the baseline recipe or the alternate recipe is more environmentally sustainable, financial sustainable, or both the environmentally sustainable and financially sustainable based on the set of processing sustainability related cost and input usage differences; and changing the facility used recipe at the textile processing facility to correspond to the alternate recipe if the alternate recipe is determined to be more environmentally sustainable, more financial sustainable, or both more environmentally sustainable and financially sustainable than the baseline recipe.

Another aspect of the present disclosure is generally directed toward a method of evaluating and altering a textile processing system to improve the sustainability of the textile processing system that includes the steps of: using a mobile computer system comprising a mobile computing processor, a signal transmitter, and a data signal receiver where the mobile computer system is located at a remote location from a textile process evaluation and comparison server system having one or more server processors; transmitting data from the mobile computer system to the textile process evaluation and comparison server via the mobile computer system and create a baseline process that emulates an existing process for creating a textile in a textile processing facility that includes a plurality of textile processing equipment and a plurality of textile processing materials where the data transmitted by the user via the mobile computing device includes data corresponding to physical details of the plurality of textile processing equipment and a plurality of data regarding textile processing materials that corresponds to physical details of the textile processing materials; at least one sensor associated with the water temperature of the water used by the plurality of textile processing equipment; using the data received from the user via the mobile application supplied to the one or more processors of the textile process evaluation and comparison server system to create and evaluate a plurality of alternative process used to produce the textile in the textile processing facility that utilizes the plurality of textile processing equipment data and the plurality of data regarding textile processing materials data to generate the plurality of alternative processes that are more environmentally sustainable, financially sustainable or both environmentally sustainable and financial sustainable alternative process; and altering the baseline recipe to coincide with a selected alternative process that is one of the plurality of alternative processes that improves the environmentally sustainable, financially sustainable or both environmentally sustainable and financial sustainable of the textile processing system more than the baseline recipe.

These and other aspects, objects, and features of the present disclosure and claimed invention will be understood and appreciated by those skilled in the art upon studying the following specification, claims, and appended drawings.

### BRIEF DESCRIPTION OF THE DRAWINGS

In the drawings:

FIG. 1 is a schematic view showing a plurality of users individually interacting with one another dynamically via a wish list server and other communicative components of an exemplary system according to an aspect of the present disclosure.

FIG. 2 is a schematic layout of various parameters considered in evaluating actual or virtual laundries using the systems of the present disclosure.

FIG. 3 is a schematic layout of a laundry system for processing fabric for clothing showing typical inputs and outputs and component interactions typically considered by the systems of the present disclosure.

FIG. 4 is an exemplary login graphical user interface display of a mobile computing application according to an aspect of the present disclosure.

FIG. 5 is an exemplary account creation graphical user interface display of a mobile computing application according to an aspect of the present disclosure.

FIG. 6 is an exemplary main washing plant listing graphical user interface display of a mobile computing application according to an aspect of the present disclosure.

FIG. 7 is an exemplary washing plant creation naming graphical user interface display of a mobile computing application according to an aspect of the present disclosure.

FIG. 8 is an exemplary washing plant creation location input graphical user interface display of a mobile computing application according to an aspect of the present disclosure.

FIG. 9 is an exemplary washing plant creation washing load data entry graphical user interface display of a mobile computing application according to an aspect of the present disclosure.

FIG. 10 is an exemplary washing plant creation washing machine selection graphical user interface display of a mobile computing application according to an aspect of the present disclosure.

FIG. 11 is an exemplary washing plant creation feed water temperature input graphical user interface display of a mobile computing application according to an aspect of the present disclosure.

FIG. 12 is an exemplary washing plant creation air temperature input graphical user interface display of a mobile computing application according to an aspect of the present disclosure.

FIG. 13 is an exemplary washing plant creation centrifuge selection graphical user interface display of a mobile computing application according to an aspect of the present disclosure.

FIG. 14 is an exemplary washing plant creation boiler selection graphical user interface display of a mobile computing application according to an aspect of the present disclosure.

FIG. 15 is an exemplary washing plant creation dryer selection graphical user interface display of a mobile computing application according to an aspect of the present disclosure.

FIG. 16A is a top portion of an exemplary washing plant setup review graphical user interface display of a mobile computing application according to an aspect of the present disclosure.

FIG. 16B is a bottom portion of an exemplary washing plant setup review graphical user interface display of a mobile computing application according to an aspect of the present disclosure.

FIG. 17 is an exemplary washing plant completion graphical user interface display of a mobile computing application according to an aspect of the present disclosure.

FIG. 18 is an exemplary wash recipe initial setup graphical user interface display of a mobile computing application according to an aspect of the present disclosure.

FIG. 19 is an exemplary cycle naming graphical user interface display of a mobile computing application according to an aspect of the present disclosure.

FIG. 20 is an exemplary cycle selection and review graphical user interface display of a mobile computing application according to an aspect of the present disclosure.

FIG. 21 is an exemplary wash recipe tutorial stage 1 graphical user interface display of a mobile computing application according to an aspect of the present disclosure.

FIG. 22 is an exemplary wash recipe tutorial stage 2 graphical user interface display of a mobile computing application according to an aspect of the present disclosure.

FIG. 23 is an exemplary wash recipe tutorial stage 3 graphical user interface display of a mobile computing application according to an aspect of the present disclosure.

FIG. 24 is an exemplary wash recipe tutorial stage 4 graphical user interface display of a mobile computing application according to an aspect of the present disclosure.

FIG. 25 is an exemplary wash recipe cycle selection graphical user interface display of a mobile computing application according to an aspect of the present disclosure.

FIG. 26 is an exemplary wash recipe cycle selection confirmation graphical user interface display of a mobile computing application according to an aspect of the present disclosure. A similar confirmation may be optionally used at any stage of the wash recipe cycle selection.

FIG. 27A is a top portion of an exemplary wash recipe cycle review graphical user interface display of a mobile computing application according to an aspect of the present disclosure.

FIG. 27B is a bottom portion of the exemplary wash recipe cycle review graphical user interface display of a mobile computing application according to an aspect of the present disclosure.

FIG. 28 is an exemplary initial laundry recipe data input pathway selection graphical user interface display of a mobile computing application according to an aspect of the present disclosure.

FIG. 29A is a top portion of an exemplary manual data input graphical user interface of a mobile computing application for a selected cycle if manual entry and specific data is selected by activation of the “No, I want to fill my own recipe” link shown in FIG. 28 according to an aspect of the present disclosure.

FIG. 29B is a bottom portion of an exemplary manual data input graphical user interface of a mobile computing application for a selected cycle if manual entry and specific data is selected by activation of the “No, I want to fill my own recipe” link shown in FIG. 28 according to an aspect of the present disclosure.

FIG. 29C is an exemplary manual data input graphical user interface of a mobile computing application for entering data and other information related to a chemical to be evaluated and analyzed with the systems of the present disclosure with an identification field to name the chemical, a dose entry field, and a unit field for data entry by the user.

FIG. 29D is an exemplary manual data input graphical user interface of a mobile computing application for entering data and other information related to auxiliary equipment that may be employed in a recipe considered and analyzed pursuant using the systems of the present disclosure with a processing time data entry field and a stage of the process user input selection where the user selects when the auxiliary equipment runs, before or after the washing process.

FIG. 29E is an exemplary manual data input graphical user interface of a mobile computing application for entering data and other information related to a laser scraping process step to be evaluated and analyzed with the systems of the present disclosure with an identification field to name the equipment being employed in the virtual system of the present disclosure, a machine operation time data entry and a labor operation time.

FIG. 29F is an exemplary manual data input graphical user interface of a mobile computing application for entering data and other information related to additional rinses employed in the systems, which is revealed by a user selecting the open menu arrow icon and having fields on the amount of rinses, the time/duration of the rinse, and the bath ratio.

FIG. 29G is an exemplary manual data input graphical user interface of a mobile computing application for entering data and other information related to centrifuges employed in the virtual systems of the present disclosure, which is revealed by a user selecting the open menu arrow icon to the right thereof and associated therewith by the user where the data to be entered by the user includes the centrifuge runtime and the pickup percentage.

FIG. 29H is an exemplary manual data input graphical user interface of a mobile computing application for entering data and other information related to driers/the drying step(s) employed in the virtual systems of the present disclosure, which is revealed by a user selecting the open menu arrow icon to the right thereof and associated therewith by the user where the data to be entered by the user includes at least the dryer runtime and the temperature thereof as well.

FIG. 30 is an exemplary graphical user interface cycle results display of the details of the cycle based on the data for the cycle created of a mobile computing application according to an aspect of the present disclosure.

FIG. 31 is an exemplary second wash recipe cycle review graphical user interface of a mobile computing application to add another cycle to the system according to an aspect of the present disclosure.

FIG. 32A is an exemplary top portion of a manual data entry graphical user interface for the second wash recipe cycle of a mobile computing application according to an aspect of the present disclosure.

FIG. 32B is an exemplary lower portion of a manual data entry graphical user interface for the second wash recipe cycle of a mobile computing application showing the drop down data entry for the “Add Rinses” menu according to an aspect of the present disclosure.

FIG. 32C is an exemplary lower portion of a manual data entry graphical user interface for the second wash recipe cycle of a mobile computing application showing the drop down data entry for the “Add Centrifuge” menu according to an aspect of the present disclosure.

FIG. 32D is an exemplary lower portion of a manual data entry graphical user interface for the second wash recipe cycle of a mobile computing application showing the drop down data entry for the “Add Drying” menu according to an aspect of the present disclosure.

FIG. 33 is an exemplary graphical user interface of a sustainability recipe input pathway route activated by selecting the “+Setup Greenofchange recipe” link in, for example, FIG. 27A according to a mobile computing application according to an aspect of the present disclosure.

FIG. 34 is an exemplary easily readable (typically both graphically and written) summary of the impact on carbon dioxide (typically shown as a green ring), energy (typically shown as a yellow ring), water usage (typically a blue ring), and time (typically a purple ring) in a graphical user interface having both graphical and numerical displays (typically positioned below and within the ring) of a mobile computing application according to an aspect of the present disclosure. The dashed lines below the rings in the drawings would typically be numeric figures revealed by the analysis of the systems of the present disclosure and are shown as placeholders in the drawings when the dashed lines appear. Activation of the “know more” link at the bottom of the display provide a more granular/a more detailed analysis of the evaluation.

FIG. 35 is an exemplary notification email preparing to open an electronic mail template within the mobile application or an electronic mail template through a third party email software application to be completed by the user of the mobile computing device and requesting instructions or guidance regarding how to set up a virtual recipe through the according to an aspect of the present disclosure.

FIG. 36 is an exemplary notification screen that email correspondence has been either manually requested or automatically requested via the mobile application using the user's profile email according to an aspect of the present disclosure.

FIG. 37A is a top portion of an exemplary graphical user interface of a sustainability cycle's input graphical user interface after selecting the cycle previously selected in an interface such as that shown in FIG. 25 according to an aspect of the present disclosure.

FIG. 37B is a lower portion of an exemplary graphical user interface of a sustainability cycle's input graphical user interface after selecting the cycle previously selected in an interface such as that shown in FIG. 25 according to an aspect of the present disclosure.

FIG. 38 is an exemplary savings/comparison interface that requests the number of batches that a given recipe may be done in one day according to an aspect of the present disclosure.

FIG. 39 is an exemplary display of detailed information comparing the differences between the established recipe and the proposed sustainability recipe detailing details of the process that change such as the amount of carbon dioxide, the amount of water saved and how many people could use that water and/or how much wheat or other crop that amount of water would produce, the energy saved and optionally how many homes that amount of saved power might power, and how many extra batches might be run using the newly proposed “greenofchange” recipe/sustainability recipe proposed according to an aspect of the present disclosure.

FIG. 40 is an alternative exemplary display of detailed information comparing the differences between the established recipe and the proposed sustainability recipe detailing the number of extra garment loads per year that may be processed using the proposed sustainability recipe comparison between the existing recipe and the “greenofchange” recipe/sustainability recipe proposed according to an aspect of the present disclosure. The information comparing the differences between the established recipe and the proposed sustainability recipe can include other comparisons. For example, the system may display how many bottles of water could be filled with the water saved with the change proposed, how many kg of potatoes could be produced, how much energy is consumed in a city. The systems of the present disclosure could also use artificial intelligence to make suggestions or use the geographic location of user to provide more relevant/local insights on the impact of the decisions to change to a new, more sustainable alternative recipe for their physical textile processing facility.

FIG. 41 is an exemplary display screen of a summary graphical user interface's right most display accessed by swiping a touch sensitive display or other user input request according to an aspect of the present disclosure where the user may select one or more outputs from the system of the present disclosure that he/she wants to have provided and review/see in the an electronically generated document, typically provided in a portable document format (pdf format).

FIG. 42 is an exemplary graphical user interface listing the washes created by a user based on the wash name assigned to the wash by the user according to an aspect of the present disclosure.

FIG. 43 is an exemplary starting landing page after a mobile computing application of the present disclosure is initially registered to a user, in this example, Rodrigo, according to an aspect of the present disclosure.

FIG. 44 is an exemplary user information graphical user interface displayed to the user after activation of a link, typically the photo and/or name portion of the starting landing page shown in FIG. 43 according to an aspect of the present disclosure.

### DETAILED DESCRIPTION

The textile processing industry needs a new tool or system(s) to accurately evaluate and consider the impact of changes to the processes they employ on sustainability and the environmental impact of their processes prior to undertaking the substantial risk and cost of doing so and thereby limiting or eliminating most or all of the risk in making changes to expensive and sometimes elaborate processing facilities, processing materials and/or processing steps. This has been historically challenging due to the number of possible changes to a textile process, the varying degrees of effectiveness of changes, the interdependency and the interaction of changes of one step in the process on other steps or processes involved in the overall process, the complexities of the implementation of changes, and financial costs of any changes made or contemplated, as discussed herein. Accordingly, an accurate system is needed that is capable of accurately taking into account various aspects and parameters involved in the textile industry, their degree of interaction with one another singularly, and/or combining considerations regarding the changes through a complex simulation or simulations that mimics real events. Systems of the present disclosure are able to deliver key information related, but not limited, to H₂O footprint, CO₂ footprint, financial aspects, and information related to productivity. The systems of the present disclosure may provide information and analysis related to other details of the specific industry being evaluated, in particular the laundry or other textile industry system such as waste water load, which is at the time of the filing of this application typically expressed by Biochemical Oxygen Demand (BOD), for example, BOD5 (the quantity of oxygen consumed by micro-organisms over a period of five days), chemical oxygen demand (COD) and/or the concentration of contaminants and chemicals such as surfactants classified by macro-categories in wastewater. When multiple objectives are set, there could be conflicts between two or more needs/adjustment factors. In these circumstances, the systems of the present disclosure are typically able to prioritize decisions and evaluate the best decisions.

Elements and parameters that are typically considered and provided by the systems of the present disclosure are a plurality of the following factors:
The air temperature (real-time and/or average ambient temperature);
The feed water temperature (average and/or real-time data) and cost per cubic meter;
The number of garments to be treated;
The name of the treatment;
The code of the treatment;
The weight of each garment;
The overall weight of the garments treated;
The type of washing machines, including brand, model, weight, maximum rpm speed, capacity, and power consumption;
The type of tumble driers, including brand, model, weight, maximum rpm speed, capacity, air flow rate, type of energy used, and electrical power consumption;
For dryers, especially those that do not come with a specification sheet or disclosed information regarding airflow, the airflow speed may be measured and then multiplying the value by the section of the pipe where the measure was performed. From a practical perspective, this is quite difficult to do. Additionally, some equipment has variable flow rates to minimize the dispersion of hot air (e.g., at the beginning the air is kept inside the drier, and then the section gradually opens to eliminate the moisture). Such systems pose objective difficulties in applying simple formulas. Thus, in similar circumstances, the drier may be identified as a device capable of dynamically managing the airflow. A mobile computing application may be used to determine the theoretical heat necessary to remove the residual moisture from the wet garments using the measured parameters; the type of spinners or centrifuges, including brand, model, weight, maximum rpm speed, capacity, and power consumption;
The auxiliary machines (e.g., nebulizing systems, foam generators), including brand, model, weight, volume of water generated, flow rate, and power consumption;
The scraping machines, laser machines, or other discontinuous devices, such as mannequins. If the equipment requires the sequential treatment of garments (e.g., two garments per cycle), then other parameters can be requested (e.g., swap time between one treatment and the following);
The boilers or heaters, including brand, model, type of fuel used, and thermal efficiency;
The fuels and/or heat sources that are or may be used to heat air and water, including molecules with a precisely defined heat of combustion (kJ/mol) or materials without a precise composition but with published heat of combustion (kJ/Kg). This can include fossil fuels such as coal, natural gas, heating oil and the like as well as renewable fuel/energy sources such as solar energy, wind energy, geothermal heat sources, and hydroelectric derived energy. Energy storage systems such as solid-state batteries may also be used as an energy source considered and evaluated in connection with the systems of the present disclosure;
If the combustible has a precise composition, identifiable by a single molecule, then at least the following information is typically provided: chemical formula, molar mass, and moles of CO₂ generated by the combustion of one mole of combustible;
The cost per Kg of the used fuel;
The cost per liter (or other standard measure of volume) of water used primarily to feed the washing machines in a laundry or other textile processing system/facility, but may also include water used in connection with other auxiliary machines such as nebulizing systems, which use water as well. The systems of the present disclosure may, but typically do not include water used as a coolant or used to generate steam in connection with this evaluation/quantification, but rather typically only the total water used to feed machines natively designed to use water in their typical use;
The geographical area, typically the country, where the industrial plant is located;
The carbon intensity of electricity per country or power suppliers (gCO₂/kWh);
The cost of the electricity (Currency, typically US dollars or Euros, but any currency could be used with real-time currency conversion rates dynamically used if the user changes the currency while conducting evaluations or using the systems of the present disclosure)/kWh);
The amount, typically liters, but any unit of measure of volume of a liquid could be used, of water needed in each washing cycle for each Kg of garments (bath ratio);
The temperature in any unit of temperature measure, Kelvin, Celsius or Fahrenheit of the bath in each washing cycle;
The duration of each cycle in minutes;
The particular chemical or chemicals involved in each washing cycle;
The dose of the chemicals used, typically expressed in grams/L (grams of chemicals for each liter of water), grams/Kg (grams of chemicals per each kilogram of fabric), and/or grams/pieces (pcs), percentage on the weight of fabrics. Pieces (pcs) may be substitute with and generally refers to the number of garments treated;
The monetary cost per kg of the chemicals;
Certifications of the chemicals used are typically utilized in the systems of the present disclosure. One or more standards may be used or considered in connection with the systems of the present disclosure. Exemplary standards that may be used include, but are not limited to the Global Organic Textile Standard (GOTS), BLUESIGN® by Bluesign Technologies of Switzerland, which is a sustainability standard that especially considers chemical composition of textile products to ensure healthy and safe materials, and/or the “Roadmap to Zero,” which is a program that focuses on three areas interlinked to provided improved chemical management, namely, input, process and output, which was developed by ZDHC, a multi-stakeholder organization that includes over 150 contributors from across the industry including Brands, Suppliers and Chemical Suppliers;
The category of the chemicals used in laundries or in other textile related processing facilities such as facilities that process yarn and fabrics (e.g., enzymes, finishing agents, water softeners, softeners, bleaching agents, pH lowering agents, pH raising agents, neutralizing agents, fixing agents); and
The chemical oxygen demand (COD) of a chemical, which is an indicative measure of the amount of oxygen that can be consumed by reactions in a measured solution; and the BOD5, which indicates how much dissolved oxygen (mg/l) is needed in a given time (five days for BOD5) for the biological degradation of the organic wastewater constituents and is an important parameter for the assessment of the degree of pollution that wastewater represents for the environment (receiving water).

The above list of textile processing information and factors are exemplary system factors, processing factors or other information that may be used in connection with the systems of the present disclosure. The above information categories are not exhaustive of all parameters that can be considered as input for the systems of the present disclosure. It is conceivable that information from various artificial intelligence sources may also be added and used in connection with the systems of the present disclosure. As discussed elsewhere herein, it is also important to note that while the systems of the present disclosure are typically used in the evaluations and adjustment of a laundry processing facilities used to process articles of clothing or portions thereof, systems of the present disclosure could also be used to evaluate potential financial and environmentally beneficial changes to facilities that process yarn and fabric or other items used in the production of items in the textile industry and conceivably in the furniture industry using the textiles as well. For example, the systems may be used to compare actual and proposed/virtual processing lines in yarn manufacturing houses, fabric processing facilities, dyeing houses, and weaving factories as well as industrial laundries.

All or any portion of the above-listed information and factors or subsets thereof can be used to create a “virtual laundry” or other virtual textile processing system, where all pieces of equipment and their characteristics are recorded. Subsequently, the “virtual laundry” will host “recipes” where different types of treatments are performed. These treatments may consist of multiple steps that are often standard treatments used within the laundry or other textile industry, but also can be freely defined by the user if a standard treatment is not being undertaken. The “virtual laundry” is typically a mobile application that a user accesses to conduct one or a plurality of comparative evaluations made possible by the systems of the present disclosure.

By combining all the inputted elements, the tool/system of the present disclosure can calculate a variety of calculated information including the following:
The kilowatts of electricity consumed by treatment of the garment being treated;
The grams of CO₂ emitted per garment in any washing step (while it may consider the cotton impact and transportation impact, systems of the present disclosure typically determine the grams of CO₂ emitted per garment in any washing step/device(s);
The liters of water used per treatment or garment;
The cost of the treatment or per garment, including the cost of chemicals, electricity, and fuel. If necessary, operating expense costs can be implemented as well;
The time of the treatment;
The BOD5 and/or the COD contribution;
The concentration of any of the contaminants; and
The percentage of certified chemicals used.

To visualize and quantify the ameliorations, the output can be compared with the existing treatment or with other treatments considered “standard”.

It is also noteworthy that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, the length or width of the structures and/or members or touch sensitive screen locations or other elements of the system may be varied. It should be noted that the elements and/or graphical user displays of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any processes or steps within the described processes disclosed herein may be combined with other disclosed processes or steps to form systems within the scope of the present disclosure. The exemplary systems and processes disclosed herein are for illustrative purposes and are not to be construed as limiting.

It is also to be understood that variations and modifications can be made on the aforementioned layouts of the touch sensitive screens of the computer applications, structures and methods without departing from the concepts of the present disclosure and claimed inventions, and further it is to be understood that such concepts are intended to be covered by the claims of the present application unless these claims by their language expressly state otherwise.

It should be understood that the disclosed innovations may assume various alternative orientations, except where expressly specified to the contrary. It is also to be understood that the specific devices and processes illustrated in the attached drawings and described in the following specification are simply exemplary embodiments of the inventive concepts defined in the appended claims. Specific dimensions and other physical characteristics relating to the embodiments disclosed herein are not to be considered as limiting, unless the claims expressly state otherwise. Where a range of values is provided, it is understood that each intervening value, to the tenth of the unit of the lower limit unless the context clearly dictates otherwise, between the upper and lower limit of that range, and any other stated or intervening value in that stated range, is encompassed within the scope of the present disclosure. The upper and lower limits of these smaller ranges may independently be included in the smaller ranges, and are also encompassed within the scope of the present disclosure, subject to any specifically excluded limit in the stated range. Where the stated range includes one or both of the limits, ranges excluding either or both of those included limits are also included in the scope of the present disclosure. All ranges and parameters, including but not limited to percentages, parts, and ratios, disclosed herein are understood to encompass any and all sub-ranges assumed and subsumed therein, and every number between the endpoints. For example, a stated range of “1 to 10” should be considered to include any and all sub-ranges beginning with a minimum value of 1 or more and ending with a maximum value of 10 or less (e.g., 1 to 6.1, or 2.3 to 9.4), and to each integer (1, 2, 3, 4, 5, 6, 7, 8, 9, 10) contained within the range. In this specification and the appended claims, the singular forms “a,” “an” and “the” include plural reference unless the context clearly dictates otherwise. All combinations of method steps or process steps as used herein can be performed in any order, unless otherwise specified or clearly implied to the contrary by the context in which the referenced combination is made.

To the extent that the terms “include(s)” or “including” or “have” or “having” are used in the specification or the claims, it is intended to be inclusive in a manner similar to the term “comprising” as that term is interpreted when employed as a transitional word in a claim. Furthermore, to the extent that the term “or” is employed (e.g., A or B) it is intended to mean “A” or “B” or both “A” and “B”. When the Applicant intends to indicate “only A or B but not both” then the term “only A or B but not both” or similar structure will be employed. Thus, use of the term “or” herein is the inclusive, and not the exclusive use. Also, to the extent that the terms “in” or “into” are used in the specification or the claims, it is intended to additionally mean “on” or “onto.” In this specification and the appended claims, the singular forms “a,” “an” and “the” include plural reference unless the context clearly dictates otherwise.

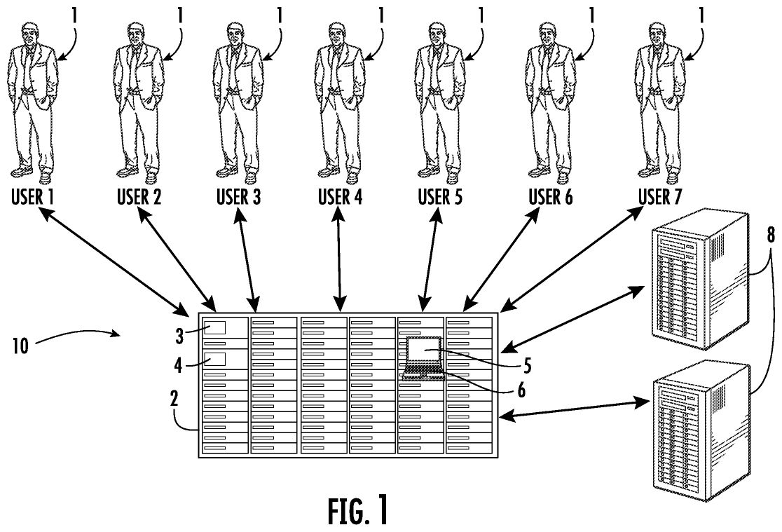

The first part of the textile facility analysis tool and systems of the present disclosure consists of modules used to create a virtual laundry, as schematized in FIG. 1.

The table “Heat of Combustion” is part of the database of information and details that is a component of a the “virtual laundry” of the present disclosure. As discussed herein, while the “virtual laundry” is described as processing garments, the systems may be adjusted and used to create a virtual yarn facility or a virtual fabric process facility or other textile processing facility. The Table 1 below contains records of different substances or materials that can act as combustible, which are used in the laundry to heat water, air, and/or other gases used in the industrial textile processing industry, typically garment, yarn or fabric processing industries.

Each record in this portion of the virtual laundry systems of the present disclosure contains fields that can include:

TABLE 1

| | | Variable | | |
|---|---|---|---|---|
| Name of the field | Type of field | name | Units | Notes |
| Identification | Index | FU_{ID} | | Replicates are not allowed. It |
| of the Heat of | | | | unequivocally identifies a record for |
| combustion Source | | | | each combustible. The Identification is |
| | | | | typically a numeric or alphanumeric code |
| Combustible | Text | FU_{Na} | | This factor describes the substance or |
| | | | | the material that is used as combustible. |
| Formula | Text/picture | FU_{For} | | This factor describes the formula of |
| | | | | the substance used as combustible. |
| | | | | Note: applicable only to those |
| | | | | combustible that have a precise |
| | | | | composition and are constituted by |
| | | | | a single molecule (e.g., methane, |
| | | | | octane). Blends of molecules (e.g., |
| | | | | gasoline, naphtha) should be |
| | | | | considered as materials. For |
| | | | | example, this can be a brute |
| | | | | chemical formula, which indicates |
| | | | | only which and how many atoms the |
| | | | | molecule is composed of or |
| | | | | something more complex such as a |
| | | | | structural image of a formula. By |
| | | | | way of example, the brute formula |
| | | | | for methane would be described as |
| | | | | CH₄, ethanol would be C₂H₅OH, |
| | | | | octane would be C₈H₁₈, while the |
| | | | | condensed structural formula for |
| | | | | octane would be CH₃(CH₂)₆CH₃. Any |
| | | | | of several different ways to define |
| | | | | the chemical formula could be used. |
| Heat of | Numeric | HOC | kJ/kg or | Heat of combustion. This factor can |
| Combustion | | | kJ/mol | be expressed in kJ/moles for |
| | | | | substances or in kJ/kg for materials. |
| | | | | Examples: |
| | | | | 802.34 kJ/mol (methane) |
| | | | | 44,000 kJ/Kg (diesel) |
| Unit | Text | HOC_{Un} | | This field is used to instruct the |
| | | | | system of the present disclosure if it |
| | | | | should express the heat of |
| | | | | combustion in kJ/kg or kJ/mol. |
| Cost per Kg | Currency | FU_{Price} | $/kg | It is used to instruct the system of |
| | | | | the present disclosure on the cost |
| | | | | per kg of the fuel used. |
| | | | | The currency can be USD, Euro, or |
| | | | | local currencies. |
| Molar Mass | Numeric | FU_{Mm} | gr/mol | This factor expresses the molar mass |
| | | | | of the combustible. It applies only to |
| | | | | combustibles that have a precise |
| | | | | composition and are constituted by |
| | | | | a single molecule (e.g., methane, octane). |
| Moles of CO₂ | Numeric | FU_{MCO} | | This factor instructs the system of the |
| | | | | present disclosure about how many moles |
| | | | | of CO₂ can be generated by the combustion |
| | | | | of a single mole of combustible. |
| | | | | It applies only to combustibles that |
| | | | | have a precise composition and are |
| | | | | constituted by a single molecule. |
| | | | | Examples: |
| | | | | The combustion of 1 mole of |
| | | | | methane generates 1 mole of CO₂ |
| | | | | The combustion of 1 mole of octane |
| | | | | generates 8 moles of CO₂ |
| | | | | For example: |
| | | | | Combustion of methane: |
| | | | | CH₄ + 2 O₂ → CO₂ + 2H₂O |
| | | | | Combustion of octane: |
| | | | | 2C₈H₁₈ + 25O₂ → 16CO₂ + 18H₂O |
| Grams of CO₂ per | Numeric | FU_{GrC} | gr | This field provides the information |
| Gram of | | | | needed for calculating the CO₂ |
| combustible | | | | emissions by the combustion of |
| | | | | materials that cannot be identified |
| | | | | by a single molecule (e.g., diesel, |
| | | | | wood, coal). |

### Countries-Energy Suppliers

The table “Countries” is typically part of a database of a virtual laundry according to the present disclosure. The Table 2 below and the information in the virtual laundry contains records of different countries of the world with relevant information regarding the average national carbon intensity of electricity values. Since the electricity can be sourced by different suppliers, the carbon intensity of the energy, as well as the cost per kWh, can differ from the national average data. Thus, the user can integrate the national data with those available from local energy providers with different commercial proposals and/or energy sources.

TABLE 2

| Name of the | Type of | Variable | | |
|---|---|---|---|---|
| field | field | name | Units | Notes |
| Identification | Index | CO_{ID} | | Replicates are not allowed. It unequivocally |
| of the | | | | identifies a record for each combination of |
| Country | | | | country + energy supplier. |
| Country | Text | CO_{Na} | | It tells the systems of the present disclosure |
| Name | | | | where the “virtual laundry” is physically |
| | | | | located in the actual world. |
| Country | Text | CO_{Cod} | | This field associates each country with a |
| Code | | | | country code. Typically, this code is not used |
| | | | | in the comparison or analysis of a virtual |
| | | | | laundry or other virtual textile system of the |
| | | | | present disclosure, but may be used and may |
| | | | | be used most typically in comparing proposed |
| | | | | systems implemented in different countries. |
| Company | Text | CO_{ES} | | If a specific energy company is selected as a |
| | | | | supplier of electricity, then it can be mentioned |
| | | | | in this field. This is intended to offer multiple |
| | | | | selections within a specific Country to allow |
| | | | | greater granularity and thus greater precision |
| | | | | in the functioning of the system of the present |
| | | | | disclosure as comparisons are made and |
| | | | | evaluations conducted. |
| | | | | Examples: |
| | | | | Italy (national avg) |
| | | | | Italy - Enel |
| | | | | Italy - Sorgenia |
| | | | | Italy - Edison |
| Carbon | Numeric | CIN | gr/kWh | This field is used to instruct the system of the |
| intensity of | | | | present disclosure what is the carbon intensity |
| electricity | | | | of electricity for a specific Country and year. |
| | | | | Values are expressed in grams of CO₂/kWh. |
| | | | | These values are usually available as the |
| | | | | national average annually. Each year's annual |
| | | | | carbon intensity of electricity is tracked within |
| | | | | the database systems of the present systems. |
| Year | Numeric | CI_{Y} | | It tells the system of the present disclosure |
| | | | | what is the reference year for the carbon |
| | | | | intensity of electricity. |
| Cost per | Currency | EN_{Price} | $/kWh | It instructs the system of the present disclosure |
| kWh | | | | about the cost per kWh of the electricity |
| | | | | sourced. On occurrence, the value can be |
| | | | | updated with the desired frequency. |
| Carbon Cost | Carbon | | | Policy for Carbon Cost may be used to generate |
| Compliance | Cost(s) | | | results of an analysis of a proposed virtual |
| with Country | | | | system or actual system to estimate and |
| Regulations | | | | provide information regarding carbon credits |
| | | | | available and impact of change on compliance |
| | | | | with regulations in a given jurisdiction based |
| | | | | on carbon emissions. |

Geographical location or energy suppliers can affect the final outputs, in terms of costs and carbon footprint through different values of the carbon intensity of electricity and cost per kWh. The Carbon intensity of electricity and cost per kWh will affect the final outputs, in terms of costs and carbon footprint, through the use of any device, equipment, or machinery that uses electricity (e.g., washing machines, lasers, driers). This also allows for a determination of carbon cost compliance and evaluation of carbon credits of a given laundry or other textile system (whether virtual or real) being evaluated by the systems of the present disclosure.

### Industrial Boilers

The Table 3 below is directed to factors related to “Boilers” that are used as part of a database according to the present disclosure and may be used as a factor that defines the virtual laundry.

The Table 3 contains records of commercial boilers that can be used to heat, directly or indirectly (e.g., by mean of steam), water, and air.

TABLE 3

| Name of the | Type of | Variable | | |
|---|---|---|---|---|
| field | field | name | Unit | Notes |
| Identification | Index | BO_{ID} | | Replicates are not allowed. It |
| of the Boiler | | | | unequivocally identifies a record for |
| | | | | each recorded boiler. The |
| | | | | identification can be any unique code, |
| | | | | which allows for queries of various |
| | | | | databases using the same numerical |
| | | | | ID. A certain brand and model may |
| | | | | be given the same ID across all |
| | | | | aspects of the systems of the present |
| | | | | disclosure. Typically, no duplicate |
| | | | | identifications are employed. |
| Brand | Text | BO_{Br} | | Manufacturer of the industrial boiler |
| Model | Text | BO_{Mo} | | Model of the industrial boiler |
| Thermal | Percent | BO_{Eff} | | It instructs the system of the present |
| efficiency | | | | disclosure about the capability of the |
| | | | | boiler to effectively convert chemical |
| | | | | energy into heat energy. |
| | | | | When this datum is not declared by |
| | | | | the manufacturer, it would be |
| | | | | possible to introduce assumptions |
| | | | | based on statistical data, which may |
| | | | | be inherited from similar models of |
| | | | | boilers or the kind of fuel used. |
| | | | | Thermal efficiency is a factor that is |
| | | | | primarily used in analyzing the impact |
| | | | | of a dryer in a laundry system of the |
| | | | | present disclosure. |
| | | | | Generic values, based on statistics, |
| | | | | may be used, or a reverse calculation |
| | | | | based on the comparison between |
| | | | | real and theoretical consumption of |
| | | | | fuel may be performed. |
| Combustible | Numeric | BO_{Fuel} | | This field is used to identify which |
| | | | | kind of combustible is used. The |
| | | | | numerical value is linked to the field |
| | | | | “FU_{ID}” of Table 1. |
| Year | Numeric | BO_{Y} | | Year of production of the boiler. |
| Country of | Numeric | BO_{Cou} | | Where the boiler was produced. This |
| Manufacture | | | | field is numeric. There is a “silent” |
| | | | | assumption according to which it links |
| | | | | to the indexed list of countries based |
| | | | | on the country ID. Specifically, BO_{Cou} |
| | | | | links to CO_{ID} |
| Cost | Currency | BO_{Cost} | $ | Cost of the boiler. |
| Depreciation Time | Numeric | BO_{DT} | | Depreciation time of the boiler, |
| | | | | expressed in years. |
| Weight | Numeric | BO_{W} | kg | Weight of the boiler expressed in kg. |
| Main material | Text/Numeric | BO_{Mat} | | This field could host text from a drop- |
| | | | | down menu or a numeric value linked |
| | | | | to an indexed list of metals. This |
| | | | | factor tells a system of the present |
| | | | | disclosure the main material involved |
| | | | | in the construction of the boiler (e.g., |
| | | | | stainless steel). This information, |
| | | | | combined with the weight of the |
| | | | | boiler, could represent the first step |
| | | | | for an approximate calculation of the |
| | | | | CO₂ emissions involved in the |
| | | | | manufacturing process of the boiler. |

### Washing Machines

The table “Washing Machines” such as Table 4 below is typically part of a database that defines a virtual laundry according to the present disclosure. Table 4 contains records of commercial washing machines that can be used to perform washings or treatments on garments. In industrial laundries, these pieces of equipment can be considered the core of most processes. The “unit” shown in the any of the tables described herein, including Table 4 below, may be adjusted based on conversion factors and automatically adjusted by the systems of the present disclosure when viewed or selected by the user using the mobile application(s) or the internet accessible website that is the interface between the user and the systems of the present disclosure.

TABLE 4

| Name of the | Type of | Variable | | |
|---|---|---|---|---|
| field | field | name | Unit | Notes |
| Identification | Index | WA_{ID} | | Replicates are not allowed. It unequivocally |
| of Washers | | | | identifies a record for each type of washing |
| | | | | machine. |
| Brand | Text | WA_{Br} | | Manufacturer of the washing machine. |
| Model | Text | WA_{Mo} | | Model of the washing machine. |
| Power | Numeric | WA_{KW} | kW | It instructs the system of the present disclosure |
| | | | | about the power requirements of the washing |
| | | | | machine expressed in kW. |
| | | | | In most cases, this value appears in metallic plates |
| | | | | on the rear of the washing machines. This value |
| | | | | may also be measured in real time in which case |
| | | | | the systems of the present disclosure will typically |
| | | | | use the real time values instead of the |
| | | | | manufacturer declared values. This may be done |
| | | | | in any instance of the systems of the present |
| | | | | disclosure where “power” fields are considered |
| | | | | including in the evaluation of spinners and lasers |
| | | | | etc. |
| Power-Spin | Numeric | WA_{PS} | kW | Some models of washing machines can also act as |
| | | | | spinners for mild centrifuges. Power required for |
| | | | | centrifuge, expressed in kW, can be declared in |
| | | | | this field if it applies. |
| Max RPM | Numeric | WA_{RPM} | | Maximum rotational speed. For instance, values |
| | | | | superior to 300 rpm may suggest that the model |
| | | | | is capable of performing mild centrifuge |
| | | | | operations. |
| Max Load | Numeric | WA_{ML} | kg | The value is expressed in kg. This field can be used |
| | | | | to detect errors during the creation of recipes if |
| | | | | the weight of garments treated exceeds the |
| | | | | capacity of the selected washing machine. |
| Year | Numeric | WA_{Y} | | Year of production of the washing machine. |
| Country of | Numeric | WA_{Cou} | | Where the washing machine was produced. |
| Manufacture | | | | This field is numeric and is linked to the indexed |
| | | | | list of countries. Specifically, WA_{Cou} links to CO_{ID} |
| Cost | Currency | WA_{Cost} | $ | Purchasing price of the washing machine. |
| Depreciation | Numeric | WA_{DT} | | Depreciation time of the washing machine, |
| Time | | | | expressed in years. |
| Weight | Numeric | WA_{W} | kg | Expressed in kg. |
| Main material | Text/ | WA_{Mat} | | This field could host text from a drop-down menu |
| | Numeric | | | or a numeric value linked to an indexed list of |
| | | | | metals. See also the last row of Table 3 regarding |
| | | | | the potential use of this field. |

### Centrifuges-Hydroextractors

Table 5 below show information regarding the “Centrifuges” that are typically included as part of a database defining a virtual laundry according to the present disclosure.

The table contains records of commercial centrifuges or hydroextractors that can be used to extract water from wet garments. In industrial laundries, these pieces of equipment are used after the main washing cycles. Some models of washing machines can integrate low-rpm centrifuges.

TABLE 5

| Name of the | Type of | Variable | | |
|---|---|---|---|---|
| field | field | name | Unit | Notes |
| Identification | Index | CE_{ID} | | Replicates are not allowed. It unequivocally |
| Centrifuge | | | | identifies a record for each type of |
| | | | | centrifuge. |
| Brand | Text | CE_{Br} | | Manufacturer of the centrifuge. |
| Model | Text | CE_{Mo} | | Model of the centrifuge. |
| Power | Numeric | CE_{KW} | kW | This factor instructs the system of the |
| | | | | present disclosure about the power |
| | | | | requirements of the centrifuge expressed in |
| | | | | kW. |
| | | | | In most cases, this value appears in metallic |
| | | | | plates on the rear of the centrifuge. |
| Max RPM | Numeric | CE_{RPM} | | Maximum rotational speed expressed in |
| | | | | revolutions per minute. |
| Max Load | Numeric | CE_{ML} | | The value is expressed in Kg. This field can be |
| | | | | used to detect errors during the creation of |
| | | | | recipes if the weight of garments treated |
| | | | | exceeds the capacity of the selected |
| | | | | centrifuge. |
| Year | Numeric | CE_{Y} | | Year of production of the centrifuge. |
| Country of | Text/ | CE_{Cou} | | Country where the centrifuge was |
| Manufacture. | Numeric | | | produced. |
| | | | | This field is numeric and is linked to the |
| | | | | indexed list of countries. Specifically, CE_{Cou} |
| | | | | links to CE_{ID} |
| Cost | Currency | CE_{Cost} | $ | Purchasing price of the centrifuge. |
| Depreciation | Numeric | CE_{DT} | | Depreciation time of the centrifuge, |
| Time | | | | expressed in years. |
| Weight | Numeric | CE_{W} | kg | Weight of the centrifuge, expressed in kg. |
| Main material | Text/ | CE_{Mat} | | See also the last row of Table 3 regarding the |
| | Numeric | | | potential use of this field. |

### Dryers

Table 6 shows the “Dryers” that may be part of a database defining a virtual laundry. The table contains records of commercial dryers that can be used to dry wet or moist garments after the treatments conducted using water-based baths. These pieces of equipment can be very different from each other. For instance, some use electricity, others use heat exchangers with streams of steam generated by the boilers. Other dryers may include sophisticated solutions that aim to recover part of the heat that otherwise would be lost in exhaust piping terminals.

The table below is given as an example of fields that can help to calculate contributions of carbon footprints and costs. Other factors may be included and considered in a virtual laundry system or other virtual textile processing system of the present disclosure.

TABLE 6

| Name of the | Type of | Variable | | |
|---|---|---|---|---|
| field | field | name | Unit | Notes |
| Identification | Index | DR_{ID} | | Replicates are not allowed. It |
| for a Dryer | | | | unequivocally identifies a record for each |
| | | | | type of dryer. |
| Brand | Text | DR_{Br} | | Manufacturer of the dryer. |
| Model | Text | DR_{Mo} | | Model of the dryer. |
| Power | Numeric | DR_{KW} | | This factor instructs the system of the |
| | | | | present disclosure about the power |
| | | | | requirements of the dryer expressed in |
| | | | | kW. |
| | | | | In most cases, this value appears in |
| | | | | metallic plates on any of the sides of the |
| | | | | dryer. |
| Air flowrate | Numeric | DR_{FR} | m³/min | This factor instructs the system of the |
| | | | | present disclosure about how many cubic |
| | | | | meters of air passes through the dryer. |
| | | | | The value is expressed in m³/min. |
| | | | | This value can have a dramatic effect on |
| | | | | CO₂ emissions when high flow rates are |
| | | | | combined with high temperatures and |
| | | | | prolonged drying time. |
| Moisture | Yes/No | DR_{MS} | | This checkbox can be potentially used to |
| sensor | | | | suggest the system of the present |
| | | | | disclosure that the dryer has devices to |
| | | | | optimize the airflow or the drying time. In |
| | | | | such a case, the system of the present |
| | | | | disclosure may calculate the theoretical |
| | | | | amount of fuel needed to dry the moist |
| | | | | garments. |
| Maximum | Numeric | DR_{ML} | kg | The value is expressed in kg. This field |
| Load | | | | can be used to detect errors during the |
| | | | | creation of recipes if the weight of |
| | | | | garments treated exceeds the capacity of |
| | | | | the selected dryer. |
| Type | Text/Numeric | DR_{Type} | | This field can be filled by a drop-down |
| | | | | menu or linked to the ID of a specific |
| | | | | table in order to establish if the dryer |
| | | | | uses electricity, steam, or any other heat |
| | | | | sources to perform the drying process. |
| Year | Numeric | DR_{Y} | | Year of production of the dryer. |
| Country of | Numeric | DR_{Cou} | | Where the dryer was produced. |
| Manufacture | | | | |
| Cost | Currency | DR_{Cost} | $ | Purchasing price of the dryer. |
| Depreciation | Numeric | DR_{DT} | | Depreciation time of the dryer, expressed |
| Time | | | | in years. |
| Weight | Numeric | DR_{W} | kg | Weight of the dryer expressed in kg. |
| Main | Text/Numeric | DR_{Mat} | | See also the last row of Table 3 regarding |
| material | | | | the potential use of this field. |

Regarding the airflow rate, many dryers do not come with airflow declared in their equipment specifications. Thus, the system may measure the section of the exhaust piping (m²) and the speed of the exhausted hot air with an anemometer (m/sec). Consequently, the systems of the present disclosure can calculate the airflow expressed in m³/sec. However, from a practical perspective, this is not always a practical solution and some owners of a dryer being used may refuse to perform such a kind of measurement. Moreover, many driers adopt sophisticated solutions to minimize heat dispersion. For example, by changing dynamically the flow rate (low at the beginning, high in a later stage of the drying process). This makes calculations of heat/energy/CO₂ footprint extremely complex and hard to apply to all models present in the market. Thus, as an alternative method to calculate the energy/fuel/CO₂, the systems of the present disclosure may propose to start from the residual moisture present at the end of the cycle before the drying process. For example, if 200 garments 0.5 Kg each=100 Kg of fabric; supposing that the cycle before the drying leads to a 1:10 bath ratio, this means 10 Kg of water are still present on garments. Hence, the boiler needs to provide enough heat to evaporate these 10 kgs of water.

### Lasers, Scraping Devices, and Other Equipment Sequential Treating Goods

Table 7 below shows “Lasers-Scraping” information that may be included as part of a database defining a virtual laundry. The information of this section also generally applies to scraping devices and other sequential treating equipment such as spraying cabins and sandblasting devices that sequentially treat goods in the textile industry, in particular the laundry industry. The table contains records/information of commercial machines that are used to perform abrasions or localized discolorations through the use of laser beams. These items often require that the garments are treated sequentially (e.g., one after another). Substituting a treated garment with the next requires an operator to remove the garment from the machine and insert a new one. This can significantly slow the processing time of an overall laundry. For that reason, some manufacturers have produced versions of their machine that can process more than just one garment per time. Additionally, manufacturers can introduce automation to minimize the time needed for the replacement of garments.

TABLE 7

| Name of the | Type of | Variable | | |
|---|---|---|---|---|
| field | field | name | Unit | Notes |
| Identification of | Index | LS_{ID} | | Replicates are not allowed. It |
| Laser Scraping | | | | unequivocally identifies a record |
| device | | | | for each type of device. |
| Brand | Text | LS_{Br} | | Manufacturer of the device. |
| Model | Text | LS_{Mo} | | Model of the device. |
| Power | Numeric | LS_{KW} | kW | It instructs the system of the |
| | | | | present disclosure about the |
| | | | | power requirements of the device |
| | | | | expressed in kW. |
| | | | | In most cases, this value appears |
| | | | | in metallic plates on any of the |
| | | | | sides of the device. |
| Type | Text/ | LS_{Ty} | | This field can be filled by a drop- |
| | Numeric | | | down menu or linked to the ID of |
| | | | | a specific table in order to |
| | | | | establish the type of device used |
| | | | | (e.g., laser, mannequins, spraying |
| | | | | cabin, sandblasting device). |
| Pieces per time | Numeric | LS_{PPt} | | This value tells the system of the |
| | | | | present disclosure how many |
| | | | | garments can be treated |
| | | | | simultaneously by the device. |
| Swap time | Numeric | LS_{SWt} | sec | This value tells the system of the |
| | | | | present disclosure how many |
| | | | | seconds are needed for the device |
| | | | | to remove the treated garment |
| | | | | with the next queued in the |
| | | | | process. |
| Year | Numeric | LS_{Y} | | Year of production of the device. |
| Country of | Numeric | LS_{Cou} | | Where the device was produced. |
| Manufacture | | | | |
| Cost | Currency | LS_{Cost} | | Purchasing price of the device. |
| Depreciation | Numeric | LS_{DT} | | Depreciation time of the device, |
| Time | | | | expressed in years. |
| Weight | Numeric | LS_{W} | kg | Weight of the device expressed in |
| | | | | kg. |
| Main material | Text/ | LS_{Mat} | | See also the last row of Table 3 |
| | Numeric | | | regarding the potential use of this |
| | | | | field. |

### Auxiliary Equipment

Table 8 below show “Auxiliary Equipment” components of information that may be part of a database defining a virtual laundry according to an aspect of the present disclosure. Table 8 contains records of commercial equipment that are not specified above and that are sometimes used to integrate tasks that are more frequently found in industrial laundries, yarn manufacturing houses, fabric processing facilities, dyeing houses, and weaving factories. These items can include pieces of equipment that are intended to support other machines. For example, nebulizing systems can be coupled with washing machines or tumble dyers to inject aerosols consisting of blends water-chemicals. Similarly, “Smart Foam Machines” can work synergistically with washing machines to use foam as carriers.

TABLE 8

| Name of the | Type of | Variable | | |
|---|---|---|---|---|
| field | field | Type | Unit | Notes |
| Identification | Index | AU_{ID} | | Replicates are not allowed. It |
| for Auxiliary | | | | unequivocally identifies a record for |
| Machines | | | | each type of auxiliary device. |
| Brand | Text | AU_{Br} | | Manufacturer of the auxiliary device. |
| Model | Text | AU_{Mo} | | Model of the auxiliary device. |
| Power | Numeric | AU_{KW} | kW | It instructs the system of the present |
| | | | | disclosure about the power |
| | | | | requirements of the auxiliary device |
| | | | | expressed in kW. |
| | | | | In most cases, this value appears in |
| | | | | metallic plates on any of the sides of the |
| | | | | auxiliary device. |
| Type | Text/ | AU_{Ty} | | This field can be filled by a drop-down |
| | Numeric | | | menu or linked to the ID of a specific |
| | | | | table in order to establish the type of |
| | | | | auxiliary device used (e.g., Smart tFoam |
| | | | | Machine, Nebulizing system, Ozone |
| | | | | generator) |
| Liters per | Numeric | AU_{FR} | L/min | If the auxiliary device adds water to the |
| minute | | | | washing machine, then the flow rate, |
| | | | | expressed in liters per minute, can be |
| | | | | specified in this field. |
| | | | | This ensures that the systems of the |
| | | | | present disclosure can consider the |
| | | | | additional contribution of water |
| | | | | provided by the auxiliary device. |
| | | | | A user may also input the total amount |
| | | | | of liters of water added in the washing |
| | | | | machine directly into the systems of the |
| | | | | present disclosure |
| Year | Numeric | AU_{Y} | | Year of production of the auxiliary |
| | | | | device. |
| Country of | Numeric | AU_{Cou} | | Where the auxiliary device machine was |
| Manufacture. | | | | produced. |
| Cost | Currency | AU_{Cost} | $ | Purchasing price of the auxiliary device. |
| Depreciation | Numeric | AU_{DT} | | Depreciation time of the auxiliary |
| Time | | | | device, expressed in years. |
| Weight | Numeric | AU_{W} | kg | Weight of the auxiliary device expressed |
| | | | | in Kg. |
| Main material | Text/ | AU_{Mat} | | See also the last row of Table 3 |
| | Numeric | | | regarding the potential use of this field. |

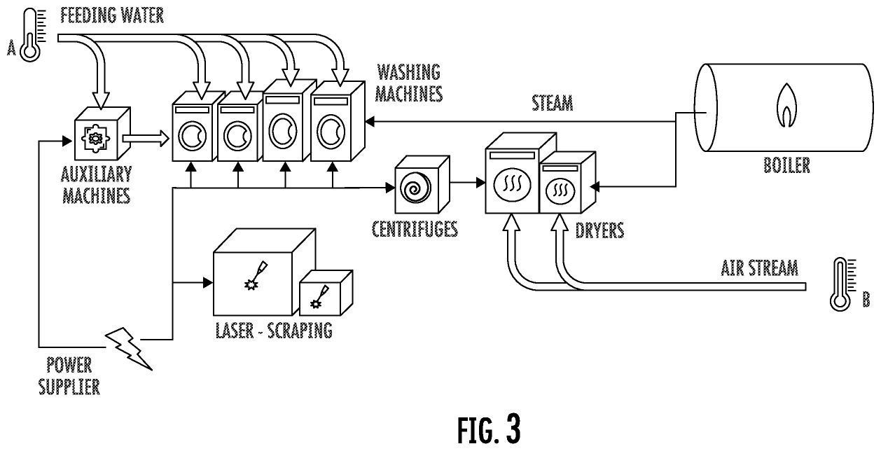

Once a virtual laundry is created, it is still needed to specify what is the average temperature of the feed water (See FIG. 3 at “A”) and the environment temperature (FIG. 3 at “B”). These figures can be set or dynamically adjusted based on one or more temperature sensors spaced in the feed water and/or the environment of the systems being analyzed and reviewed/modified in the virtual overall systems of the present disclosure. Depending on these temperatures, which become an unmaterial part of the laundry, the amount of fuel needed to heat water and air to the target values can vary. For instance, if the feeding water temperature is 25° C., the laundry will need lower volumes of fuel to heat water to 50° C. compared to another laundry that sources water with an average temperature of 15° C. The cost of water per cubic meter needs to be defined to calculate its contribution to the overall cost of the treatment.

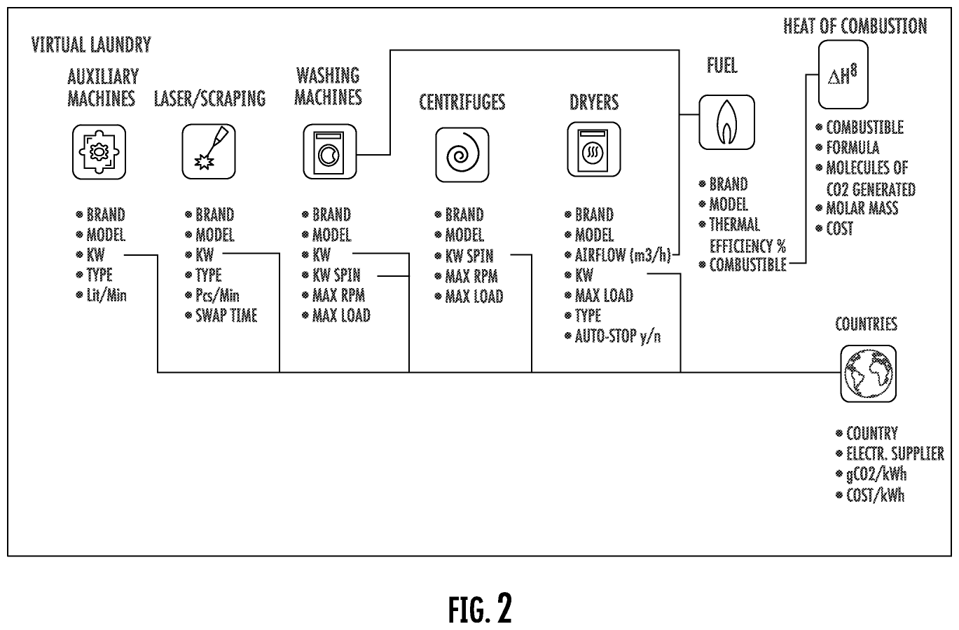

FIG. 2 is a graphical representation of an exemplary virtual laundry that might be created using the systems and methods of the present disclosure. The various parameters below will be discussed herein:
T_{H20}=temperature of the feeding water, which can be also inputted as an average value over a specific period (e.g., yearly, monthly, weekly, daily, or real-time).
H2O_{Price}=price of the water per cubic meter expressed as USD/m³. The price of water per cubic meter may be adjusted based on information dynamically or periodically provided from a third party or parties via a network of computer systems into the systems of the present disclosure. Other currencies can be used as well with the support of currency exchange values.
T_{Air}=environmental temperature, which can be also inputted as an average value over a specific time (e.g., yearly, monthly, weekly, daily, or real-time).

### Chemical Warehouse

Table 9 generally shows information regarding various “chemicals” that may be used to create a virtual repository of chemicals used to perform textile treatments in a virtual laundry according to an aspect of the present disclosure. The table below is representative of the information that is necessary to instruct the system of the present disclosure about the kind of chemicals stored in the virtual warehouse.

TABLE 9

| Name of the | Type of | Variable | | |
|---|---|---|---|---|
| field | field | name | Units | Notes |
| Identification of | Index | CH_{ID} | | Replicates are not allowed. It unequivocally |
| Chemical | | | | identifies a record for each type of chemical |
| Brand | Text | CH_{Br} | | Manufacturer of the chemical product (e.g., |
| | | | | Kemin). |
| Commercial name | Text | CH_{CN} | | Commercial name of the chemical product |
| | | | | (e.g., KEMZYME ™ KS20). |
| Cost per Kg | Currency | CH_{Price} | $ | It instructs the system of the present |
| | | | | disclosure about the cost of the chemical. This |
| | | | | data is used by the system of the present |
| | | | | disclosure to calculate the cost of the |
| | | | | treatment. |
| Solid content | Percentage | CH_{SC} | | Solid content, expressed in %, is an optional |
| | | | | datum that can help the system of the |
| | | | | present disclosure to calculate the overall |
| | | | | amount of solids downloaded in the whole |
| | | | | washing process. |
| COD | Numeric | CH_{COD} | mg/L | The chemical oxygen demand (COD) can be |
| | | | | optionally specified in this field. Value is |
| | | | | expressed in mg/L. If all the chemicals used in |
| | | | | the recipes have COD values specified, then |
| | | | | the system of the present disclosure will be |
| | | | | able to estimate the approximate COD value |
| | | | | for the overall treatment as a sum of water |
| | | | | and chemicals downloaded. |
| BOD5 | Numeric | CH_{BOD} | mg/L | Similar to the previous field, BOD5 (five-days |
| | | | | biochemical oxygen demand) values can be |
| | | | | specified. |
| Non-ionic | Numeric | CH_{NISu} | % | Concentration of anionic surfactants in % w/w |
| surfactants | | | | |
| Anionic surfactants | Currency | CH_{ASu} | % | Concentration of anionic surfactants in % w/w |
| Cationic surfactants | Numeric | CH_{CSu} | % | Concentration of anionic surfactants in % w/w |
| Packaging | Text/ | CH_{Pack} | | It specifies the type of packaging (e.g., plastic |
| | Numeric | | | drum, Intermediate Bulk Containers (IBC) |
| | | | | caged with stainless steel, Kraft drums) |
| ZDHC Level | Numeric | CH_{ZDHC} | | 0 = not in the ZDHC platform |
| | | | | 1 = ZDHC level 1 |
| | | | | 2 = ZDHC level 2 |
| | | | | 3 = ZDHC level 3 |
| | | | | https://www.zdhc-gateway.com/ |
| GOTS | Yes/No | CH_{GOTS} | | This element tells the systems of the present |
| | | | | disclosure if the chemical is certified GOTS |
| | | | | https://global-standard.org/ |
| BLUESIGN ® | Yes/No | CH_{BSig} | | It tells the systems of the present disclosure if |
| | | | | the chemical is certified BLUESIGN ® |
| | | | | https://www.bluesign.com |
| OEKO-TEX ® | Yes/No | CH_{Oeko} | | It tells the system of the present disclosure if |
| | | | | the chemical is certified OEKO-TEX ® |
| | | | | https://www.oeko-tex.com/en/ |
| Contaminants | Numeric | CH_{Cont(x)} | ppm | These fields can consist of any restricted |
| (x = 1, 2, | | | | substance list listed by ZDHC, GOTS, |
| 3 . . . n) | | | | BLUESIGN ®, OEKO-TEX ® or other certification |
| | | | | bodies. |
| | | | | The fields will identify a specific restricted |
| | | | | substance and the value, expressed in ppm, |
| | | | | will express the maximum concentration |
| | | | | allowed according to the MRSL (Material |
| | | | | Restricted Substance List) of a specific |
| | | | | organization. |
| | | | | Examples: |
| | | | | CrVI (Chromium hexavalent): 10 ppm |
| | | | | As: 50 ppm |
| | | | | NPEO: 100 ppm |
| CO₂ Impact | | | | An assessment of the impact of a given |
| | | | | chemical product on the product life cycle |

The virtual chemical warehouse can be built by selecting recorded chemicals from an internal or external database. Of course, an existing database of chemicals or multiple databases of chemicals may be incorporated into the systems of the present disclosure. A significant feature of some embodiments of the systems of the present disclosure includes the incorporation of one or more certifications of the various chemicals in the virtual chemical warehouse of the systems of the present disclosure. Yet another significant feature of the system of the present disclosure that may or may not be incorporated, but most typically would be included are the concentrations of contaminants of one or all of the chemicals, molecules, and/or raw materials that may be included in the virtual laundry systems of the present disclosure. Typically, the chemicals used may include one or more and sometimes up to dozens (36 or more) raw materials or molecules. The inclusion of each of these features allows for significantly improved flexibility in the systems and tools of the present disclosure by facilitating the future integration of the systems of the present disclosure with external databases. For example, virtual laundry systems of the present disclosure may be constructed to be able to “communicate” with databases related to Manufacturing Restricted Substance List (MRSL) of brands of certification bodies, thus predicting potential issues deriving from the use of chemical products above specific thresholds.

Certifications of the chemicals used may include, but are not limited to: the Global Organic Textile Standard (GOTS); BLUESIGN® by Bluesign Technologies of Switzerland is a sustainability standard that especially considers chemical composition of textile products to ensure healthy and safe materials; and ZDHC is a multi-stakeholder organization tyhat includes over 150 contributors from across the industry including Brands, Suppliers and Chemical Suppliers that has developed the “Roadmap to Zero,” which is a program that focuses on three areas interlinked to provided improved chemical management, namely, input, process and output.

Another factor that is typically included in the systems of the present disclosure includes the category of the chemical being used such as an enzyme or a finishing agent.

Yet another factor typically included in the virtual laundry analysis factors that is considered in the various analysis done using the systems of the present disclosure relates to the chemical oxygen demand (COD) of one or more, but more typically each chemical of the virtual laundry. The chemical oxygen demand of a chemical is an indicative measure of the amount of oxygen that can be consumed by reactions in a measured solution. Similarly, the BOD5, which indicates how much dissolved oxygen (mg/L) is needed in a given time (five days for BOD5) for the biological degradation of the organic wastewater constituents is another parameter that may be used in the systems of the present disclosure and is typically used for the assessment of the degree of pollution that wastewater represents for the environment (receiving water).

While all or any subset of the elements discussed above of ingredients/components of the virtual laundry systems/tools of the present disclosure may be and are typically includes in the systems and database used in connection with the virtual laundry systems. Inclusion of all of the above factors within the data analyzed by the systems of the present disclosure when making comparisons between existing laundry systems and a virtual laundry system will provide the most accurate and comprehensive evaluation of the comparison between the existing laundry of a user and a comparative virtual laundry system through the use of a virtual laundry system of the present disclosure, typically a mobile computing application/tool of the present disclosure. However, a subset of the components may be utilized instead of each and every one of the above factors and still provide some benefits to a user. When a subset of factors or type of data analyzed is incorporated those categories used typically include the following:
A) The air temperature (or average ambient temperature);
B) The feed water temperature (average or real-time data) and cost per cubic meter;
C) The overall weight of the garments treated;
D) The type of washing machines, including brand, model, weight, maximum rpm speed, capacity, and power consumption;
E) The type of tumble driers, including at least the following factors for the driers: capacity, air flow rate, type of energy used, and electrical power consumption;
F) The type of spinners or centrifuges, including at least the following factors: capacity, and power consumption;
G) The auxiliary machines (e.g. nebulizing systems, foam generators), including at least the following factors: water added into the system/process being evaluated, volume of water generated, flow rate, and power consumption;
H) The scraping machines, laser machines, or other discontinuous devices, such as mannequins;
I) The boilers or heaters, including the type of fuel used, and thermal efficiency;
J) The fuels that are used to heat air and water, including molecules with a precisely defined heat of combustion (kJ/mol) or materials without a precise composition but with published heat of combustion (KJ/Kg);
K) If the combustible has a precise composition, identifiable by a single molecule, then at least the following information is typically provided: chemical formula, molar mass, and moles of CO₂ generated by the combustion of one mole of combustible;
L) The cost per Kg of the used fuel;
M) The geographical area where the industrial plant is located;
N) The carbon intensity of electricity per country or power suppliers (gCO₂/kWh);
O) The cost of the electricity (Currency (Typically dollars)/kWh);
P) The amount, typically liters, of water needed in each washing cycle for each kilogram of garments (bath ratio);
Q) The temperature of the bath in each washing cycle;
R) The duration of each cycle in minutes;
S) The particular chemical or chemicals involved in each washing cycle;
T) The dose of the chemicals used, expressed in grams/L, grams/Kg, grams/pieces (pcs), percentage on the weight of fabrics; and
U) The monetary cost per kg of the chemicals.

The systems and data analyzed using the virtual laundry systems of the present disclosure not only consider and analyze the equipment and materials used in the virtual laundry analysis systems of the present disclosure, but also consider various treatment processes as well. For example, in the context of other textile processing facilities other than a laundry, other types of machinery can be analyzed including: woolen mill machines, thread machines, carding machines, spinning machines (yarns), weaving machines, dyeing machines, finishing machines, tufting machines, cutting machines, sewing machines, knitting machines, measuring machines, and many more. Thus, the machines described herein should be considered purely as examples and should be not considered exhaustive of all possible textile applications.

The systems of the present disclosure typically request that the user provide the system with at least the name of a proposed treatment and a treatment code. Other non-mandatory information related to the treatment (e.g., pictures/photographs of machines, batch number, QR code) can be included in the systems of the present disclosure as well including the mobile application tool.

Once a virtual laundry of the present disclosure is defined by the user, the systems of the present disclosure will automatically know the kind of equipment available as well as a quantity thereof. Also, the system of the present disclosure will automatically know in which environment the virtual laundry operates, including the temperature of the air, feeding water, and carbon intensity of electricity. At this point, the system of the present disclosure is ready to accept an alternative proposed process defined by the user to compare against the established existing laundry that approximates the existing laundry system employed by the user in the physical world and recreated in the virtual laundry system of the present disclosure. In the laundry industry, the textile process is sometimes referred to as “recipe” or “washing”. The process may consist of multiple sequential cycles.

A non-exhaustive list of cycles considered in a virtual laundry typically includes:
A) Desizing (a cycle that aims to remove starch from raw garments);
B) Scouring (removal of impurities from the fabric substrate);
C) Stonewashing (aging of garments, generally denim, performed with pumice stones, enzymes, or a combination of the two);
D) Biopolishing (fuzz removal aimed to confer the fabric a new and brighter look);
E) Scraping (localized abrasion performed manually or by means of automated machines);
F) Laser (used to mimic localized abrasions or to create virtual “whiskers”;
G) Bleaching (localized or in whole garments, which can be performed in a bath or by spraying chemicals);
H) Finishing (e.g., softeners, hand feel modifiers, resins, etc.);
I) Three Dimensional effects application (application of special resins to create three-dimensional effects;
J) Curing (treatment in ovens);
K) Sandblasting (abrasions obtained by mechanical action);
L) Cleaning (e.g., cycles to enhance contrast or to remove the effect of back-staining on denim);
M) Hydro extraction (removal of water in excess to facilitate the subsequent drying process);
N) Drying (cycle to remove moisture from garments);
O) Rinse (cycle performed with water only in order to remove traces of chemicals from previous cycles;
P) Neutralization (cycle aimed to neutralize chemicals present on garments);
Q) De-fibrillation (cycle aimed to create a fuzzy surface on garments); and
R) Nebulization (cycle where blends water-chemicals are applied on garments through devices that produce aerosols or small droplets of solutions).

In order to perform most of the calculations, the system of the present disclosure, typically the mobile application tool, typically requires the definition of at least two of the following three parameters:
1) Wg=Weight of a garment expressed in grams or other units with appropriate conversions made.
2) W_{gtot}=Overall weight of garments involved in the process, typically this is expressed in kilograms or other unit of measure. W_{gtot} is the total weight of garments loaded in the washing machine expressed in kg.
3) NG=The number of garments involved in the process.

By inputting two of the three parameters, the systems of the present disclosure may automatically calculate the third.

### Example

Input #1: W_{gtot}=60 Kilograms.

Input #2: NG=100 pcs

The system of the present disclosure will execute the following calculation:

Wg(grams)=(1000*W_{gtot})/NG.

For ease to use, the system of the present disclosure can accept a generic description of the garments before defining each treatment. Although not mandatory, the systems of the present application including the mobile computer application can source the data from a dedicated table. The non-exhaustive table below is provided as an example:

TABLE 10

| Name of the | Type of | Variable | | |
|---|---|---|---|---|
| field | field | name | Units | Notes |
| Identification | Index | GA_{ID} | | Replicates are not allowed. It |
| of the_Garment | | | | unequivocally identifies a record for |
| | | | | each type of garment. |
| Manufacturer | Text | GA_{Br} | | Manufacturer of the garment. |
| Model | Text | GA_{Mo} | | Model of the garment. |
| Code | Text | GA_{Cod} | | Manufacturer code. |
| Cost per pcs | Currency | GA_{Cost} | $/pcs | It instructs the system of the |
| | | | | present disclosure about the cost of |
| | | | | each raw garment (untreated). |
| Weight | Numeric | GA_{W} | gr | It tells the system of the present |
| | | | | disclosure what is the weight of |
| | | | | each garment. The value is |
| | | | | expressed in grams. |
| Composition | Text | GA_{Comp} | | It tells the system of the present |
| | | | | disclosure what is the composition |
| | | | | of the fabric (e.g., 97% cotton, 2% |
| | | | | elastane, 1% polyester). |
| Notes | Text | GA_{Note} | | Any descriptive data that can help |
| | | | | to understand the kind of dyeing |
| | | | | process used, models (e.g., child, |
| | | | | woman, shirt, jacket, weaving |
| | | | | system, etc.) |
| Breaking force - | Numeric | GA_{Weft} | N | Breaking force expressed in |
| Weft | | | | Newtons to break weft yarns |
| | | | | according to any standardized |
| | | | | regulations. |
| Breaking force - | Numeric | GA_{Warp} | N | Breaking force expressed in |
| Warp | | | | Newtons to break warp yarns |
| | | | | according to any standardized |
| | | | | regulations. |
| Rivets | Yes/No | GA_{Riv} | | It tells the system of the present |
| | | | | disclosure if the garments include |
| | | | | metallic parts such as rivets or zips. |

A user of the mobile application or other user interface of the present application can create, insert, edit, cut, copy, paste or delete real or hypothetical laundry cycles that are part of a treatment. Of course, one or two or more cycles may be used to create a given product. Each cycle for a particular user is typically identified by a sequential number automatically assigned by the systems of the present disclosure and ordered according to the sequence effectively adopted in the laundry system analysis tool.

The minimum number of cycles to create a treatment is one. However, there are no limits to the number of cycles that can constitute a treatment. Typically, a given treatment is one that the user creates based on either a current “real” treatment process being employed by a laundry or a proposed virtual treatment process generated by the application or the user through the application's processes. A proposed treatment process of the present disclosure typically includes between three (3) and fifteen (15) processing steps in the actual laundry replicated by the systems of the present disclosure or a virtually using the systems of the present disclosure.

If a cycle involves the use of a chemical in a washing machine or in any other device that can handle solutions of chemicals, a user of the systems of the present disclosure can select the chemical from a drop-down menu linked to the “Identification of Chemical” field of Table 9. In the computer application, typically a mobile computing device application, an interface of the systems of the present disclosure may be a drop-down menu that can be limited to only the chemicals inputted into the systems of the present disclosure by an individual user or a group of users associated with a single entity or from a collection of all of the various users who make up users of the systems of the present disclosure such that they group of chemicals that may be selected provides a greater number of selectable chemicals thereby not requiring more input from a subsequent user.

More than one chemical product can be selected in a given cycle as well. Generally, no more than four products are used simultaneously in a process, but the systems provide limitless flexibility in the number of products and process steps and cycles that may be emulated/simulated in connection with the use of the systems of the present disclosure.

Examples of possible cycles include, but are not limited to, any of the following:
1) A desizing cycle may include an enzyme (alpha-amylase), an anti-backstaining product, and an anti-crease agent.
2) A stonewashing cycle may include an enzyme (cellulase), an anti-backstaining product, and pumice stones.
3) A biopolishing cycle may include only an enzyme to remove fuzziness.

Laundries can use different methods to define, measure or state the dosage or concentration of a chemical. The systems of the present disclosure can also use different methods to define, measure, or state the dosage or concentration of a chemical ingredient in a process of the present disclosure. Some of the more typically used methods for defining, measuring, or stating the dosage or concentration include the following:
1) Grams/liters (it defines the concentration of the chemical in the liquor).
2) Grams/Kg (it specifies how many grams are used for each kilogram of fabric).
3) owf (%)—owf refers to “on the weight of fabric” and specifies the dosage in the percentage of the chemical on the weight of the fabric. For example, 3% owf means that 30 grams of chemicals are used for each kilogram of fabric.
4) Grams/pcs (it specifies how many grams of chemicals are applied on every single garment).

Table 11 below shows four examples of products with the dosage expressed according to the above-mentioned methods.

| | | |
|---|---|---|
| Chemicals | Dose | Units |

| | | | |
|---|---|---|---|
| DW 16 LT | 3 | gr/ | Kg |
| FORTRES FLEX | 2 | gr/ | Lt |
| LAGAFINISH LSP | 5 | gr/ | Pcs |
| EASYFOAM | 3 | owf | % |

Whenever a washing machine is involved in the cycle, the bath ratio must be specified. It is typically expressed as the weight of water loaded in the washing machine divided by the total weight of garments involved in the cycle. This can be expressed by the following formula:

$$BR = {W}_{H 2 O} [ kg ] / {W}_{Gtot} [ kg ]$$

It is possible that some users may wish to use the inverse ratio, the ratio of the weight of fabric divided by the weight of the water.

BR is the bath ratio; W_{H2O} is the weight of the water loaded in the washing machine expressed in kg (or other unit of weight measure so long as the unit is consistent throughout); W_{Gtot} is the total weight of garments loaded in the washing machine expressed in kg. It is reasonable to approximate the value of the density of water to 1 kg/Lit.

$${δ}_{H 2 O} [ kg / L ] = 1$$

Thus, the user can input the BR value simply by stating how many liters of water are loaded for each kg of fabric treated. According to this approximation, the formula can be rewritten as follow:

$$BR = {V}_{H 2 O} [ L ] / {W}_{Gtot} [ kg ]$$

BR is the bath ratio and V_{H2O} is the volume (typically liters) of the water loaded in the washing machine.

Formulas to calculate the overall weight of the chemical used can be the following:

Case 1) If the dose/concentration of the chemical “x” used in the cycle “y” is expressed in grams/Liters, then:

W(x)_{Chtot(y)}[gr]=W(x)_{Ch(y)}[gr]/[L]*W_{Gtot}[kg]*RB(y)[L]/[kg]

Where:
W(x)_{Chtot(y)} is the total weight of the chemical “x”, expressed in grams, used in the cycle “y”;
W(x)_{Ch(y)} is the concentration of the chemical “x”, expressed in gr/L, used in the cycle “y”;
W_{Gtot} is the total weight of garments loaded in the washing machine expressed in kg; and
BR_{(y)} is the bath ratio adopted in the cycle “y”.

### Example

Input #1 (dosage of the chemical “15”(15 is the identification number of the chemical selected) in the second cycle): W(15)_{Ch(2)}=2 gr/L;

Input #2 (overall weight of garments): W_{Gtot}=100 kg;

Input #3 (bath ratio of the second cycle): BR₍₂₎=8 liters of water for each kg of garment;

The system of the present disclosure will execute the following calculation:

W(15)_{Chtot(2)}=2*100*8=1,600 grams.

Case 2) If the dose is expressed in grams/Kg (fabric), then:

W(x)_{Chtot(y)}[gr]=W(x)_{Ch(y)}[gr]/[kg]*W_{Gtot}[kg]

### Where:

W(x)_{Chtot(y)} is the total weight of the chemical “x”, expressed in grams, used in the cycle “y”;
W(x)_{Ch(y)} is the dose of the chemical “x”, expressed in gr per kg of fabric, used in the cycle “y”; and
W_{Gtot} is the total weight of garments loaded in the washing machine expressed in kg.

### Example

Input #1 (dosage of the chemical “42” (42 is the identification number of the chemical selected) in the first cycle): W(42)_{Ch(1)}=5 gr for each kg of garment;

Input #2 (overall weight of garments): W_{Gtot}=100 kg; and

The system of the present disclosure will execute the following calculation:

W(42)_{Chtot(1)}=5*100=500 grams.

Case 3) If the dose of the chemical “x” used in the cycle “y” is expressed in grams/garment, then:

W(x)_{Chtot(y)}[gr]=W_{Ch(y)}[gr]/[pcs]*NG[pcs]

### Where:

W(x)_{Chtot(y)} is the total weight of the chemical “x”, expressed in grams, used in the cycle “y”;
W(x)_{Ch(y)} is the number of grams of the chemical “x” applied on each garment in the cycle “y”; and
NG is the number of garments involved in the process.

### Example

Input #1 (dosage of the chemical “81” (81 is the identification number of the chemical selected) used in the third cycle: W(81)_{Ch(3)}=3 grams/garment.

Input #2 (number of garments): NG=100 garments.

The system of the present disclosure will execute the following calculation:

W(81)_{Chtot(3)}=3*100=300 grams.

Case 4) If the dose of the chemical “x” used in the cycle “y” is expressed in percentage of chemicals on the weight of the fabric:

W(x)_{Chtot(y)}[gr]=W(x)_{Ch(y)}[%]*W_{Gtot}[kg]*10

### Where:

W(x)_{Chtot(y)} is the total weight of the chemical “x”, expressed in grams, used in the cycle “y”;
W(x)_{Ch(y)} is the inputted value of the percentage of the chemical “x” applied over the whole amount of garments during the cycle “y”. This percentage is often indicated with the acronyms “owf” or “owg”, which stand respectively for “on the weight of fabric” and “on the weight of garments”; and
W_{Gtot} is the total weight of garments loaded in the washing machine expressed in kg.

### Example

Input #1 (dosage of the chemical “4” during the fourth cycle): W(4)_{Ch(4)}=3% owf.

Input #2 (overall weight of garments treated): W_{Got}=100 kg.

The system of the present disclosure will execute the following calculation:

W(4)_{Chtot(4)}=3*100*10=3,000 grams.

Eventually, the system of the present disclosure can calculate the total amount of a given chemical throughout the whole treatment.

For the chemical “x”, its total amount expressed in grams will be calculated by the following formula:

$${W ( x )}_{Chtot} = {\sum }_{y = 1}^{n} {W ( x )}_{CHtot ( y )}$$

Where:
N is the number of cycles included in the treatment.
Y is the id number of the cycle.
W(x)_{Chtot(y)} is the total weight of the chemical “x”, expressed in grams, used in the cycle “y”.

Once the amount of a given chemical product is calculated as discussed immediately above, the system of the present disclosure can execute a cost contribution calculation according to the following formula:

$${CH ( x )}_{Cost ( y )} = {W ( x )}_{Chtot ( y )} [ g r ] * {CH ( x )}_{Price} [ USD / kg ] / 1000$$

### Where:

CH(x)_{Cost(y)} is the cost contribution of the chemical “x” used in the cycle “y” expressed in USD;
W(x)_{Chtot(y)} is the total weight of the chemical “x” used in the cycle “y” expressed in grams; and
CH(x)_{Price} is the purchasing price of the chemical “x” expressed in USD/kg.

Since every cycle can involve more than just one chemical product, the overall contribution of chemicals used in the cycle “y” can be determined as follow:

$${CH}_{Cost ( y )} = {\sum }_{x = 1}^{n} {CH ( x )}_{Cost ( y )}$$

### Example

If in the third cycle two chemicals are used as follows:

Chemical 1: 1,600 grams, with a purchasing price of 2.11 USD/Kg.

Chemical 2: 800 grams, with a purchasing price of 1.00 USD/kg.

The cost contribution of that chemical for the third cycle will be:

$${CH ( 1 )}_{Cost ( 3 )} = 2.11 * 1 , 600 / 1000 = 3.376 USD .$$

$${CH ( 2 )}_{Cost ( 3 )} = 1. * 800 / 1000 = 0.8 USD .$$

$${CH}_{Cost ( 3 )} = 3.376 + 0.8 = 4.176 USD .$$

Similarly, more than just one cycle can constitute a treatment. Thus, the total contribution of all the chemicals used within a treatment can be calculated as follow:

$${CH}_{Cost} = {\sum }_{y = 1}^{n} {CH}_{Cost ( y )}$$

### Example

If the treatment is composed of three cycles with the following cost due to chemicals:
CH_{Cost(1)}=2.00 United States Dollars (USD).
CH_{Cost(2)}=1.50 USD.
CH_{Cost(3)}=4.176 USD.

Then the total cost due to chemicals used for the treatment is:

$${CH}_{Cost} = 2. + 1.5 + 4.176 = 7.676 USD .$$

With algorithms similar to those described above, COD and BOD5 contributions of a chemical in each cycle can be estimated.

The duration of each cycle, expressed in minutes, also typically needs to be specified. This datum is used by the system of the present disclosure in combination with other parameters to calculate various aspects of sustainability. For example, the time multiplied by the power of the electric devices involved will determine the amount of energy employed, which is also the basis to calculate contributions to the carbon footprint. The time needed for a washing machine to perform a cycle is directly specified by the user and it represents a key parameter in all washing recipes.

Herein this parameter is indicated as t_{WM(y)}, where y identifies the ID number of the cycle.

### Examples

t_{WM (1)}=25′ indicates that the selected washing machine operates for 25 minutes in the first cycle;

t_{WM (2)}=50′ indicates that the selected washing machine operates for 50 minutes in the second cycle;

t_{WM (3)}=15′ indicates that the selected washing machine operates for 15 minutes in the third cycle.

If the treatment consists only of the three cycles above-mentioned, then the total time of the treatment will be t_{WM (tot)}=25′+50′+15′=90 minutes. It should be emphasized that sometimes users consider certain actions as part of a unique or original cycle only known to themselves or their organization or original to the systems of the present disclosure that the user designed therein. For example, a user may include a centrifuge step within a cycle instead of considering it as a separate cycle. For the same reason, the user may consider rinses or the use of particular equipment, such as laser machines, auxiliary devices, or dryers, as integrating parts of a cycle.

In all these cases, the system of the present disclosure may evaluate and typically always evaluates the time needed for each activity, which can be highly impactful especially for processes that require sequential maneuvers. Thus, the system of the present disclosure will also consider the following times:
1) Total time needed for rinses during the cycle “y”:
2) t_{Rin(y)} [min]=NR_{(y)}*t_{R(y)} [min]
   Where: NR_{(y)} is the number of the rinses used in the cycle “y” and t_{R(y)} is the time defined for each rinse within the cycle “y”.
3) Any time needed for drying during the cycle “y” is defined directly by the user and from now onward will be indicated as t_{Dry(y)} [min].
4) Any time needed for auxiliary machines during the cycle “y” is defined directly by the user and from now onward will be indicated as t_{Aux(y)} [min].
5) Any time needed for equipment used to perform a centrifuge or hydro extraction during the cycle “y” is defined directly by the user and from now onward will be indicated as t_{Cen(y)} [min].

If any device requires sequential treatment of the garments involved (e.g., one garment each time), then the time needed to treat all the garments in the cycle “y” will be calculated as follow:

t_{LS(y)}[min]={(t_{LSOp(y)}[sec]+LS_{SWt}[sec])*NG/60}/LS_{PPt}

### Where:

t_{LSOp(y)} is the time, expressed in seconds, effectively necessary to the device/operator to perform the task (e.g., time needed by the laser beam to complete a drawing on a garment or time needed by an operator to perform a manual scraping);
LS_{SWt} is the dead time defined as the seconds that are needed for the device to remove the treated garment with the next queued in the process;
NG is the number of garments involved in the process; and
LS_{PPt} is the number of garments that can be treated simultaneously by the selected device. This parameter is inherited from Table 7 above.

Statistically, these devices, which are typically the devices that provide sequential treatment of the garments involved in the process, consist of mannequins for manual scraping, the application of polymeric coatings, lasers, or spraying cabins. Some systems allow performing simultaneous treatments of more than one garment, thus reducing the time needed for the application. For instance, if the treatment involves 100 garments (NG=100), but a mannequin (or a scraping device, or a laser machine) can treat only 2 garments sequentially, then it would take 50 sequential cycles to complete the step. Also, some devices implement automation that can reduce drastically the dead time needed to replace garments.

Eventually, the overall time for the cycle “y”, expressed in minutes, can be calculated as a sum of all contributions as follow:

t_{(y)}=t_{WM(y)}+t_{Rin(y)}+t_{Dry(y)}+t_{Aux(y)}+t_{Cen(y)}+t_{LS(y)}

The overall time needed for a treatment that involves n cycles can be therefore calculated as follow:

$$t = {\sum }_{y = 1}^{n} {t}_{y}$$

The system of the present disclosure can also calculate the overall time needed for each device or equipment to perform further calculations related to energy:

Overall use time expressed in minutes, including the time needed for rinses, for washing machines:

$${t}_{WM} = {\sum }_{y = 1}^{n} {t}_{WM ( y )} + {t}_{Rin ( y )}$$

Overall use time, expressed in minutes, for dryers:

$${t}_{Dry} = {\sum }_{y = 1}^{n} {t}_{Dry ( y )}$$

Overall use time, expressed in minutes, for auxiliary equipment:

$${t}_{Aux} = {\sum }_{y = 1}^{n} {t}_{Aux ( y )}$$

Overall use time, expressed in minutes, for centrifuges:

$${t}_{Cen} = {\sum }_{y = 1}^{n} {t}_{Cen ( y )}$$

Overall use time, expressed in minutes, for laser machines or equipment that involve sequential processing of garments:

$${t}_{LS} = {\sum }_{y = 1}^{n} {t}_{LS ( y )}$$

Differently from other time-related parameters, tis cannot be used directly to calculate the energy consumed by equipment since it should be considered only the time effectively used by the equipment, t_{LSOp(y)}, to perform the task for what is intended for its use.

The temperature of the water used in each cycle, expressed in Celsius degrees or other temperature units, typically needs to be specified. This data is essential to calculate various aspects of sustainability. For instance, the energy, or the volume of fuels, needed to reach the targeted temperature value depends on various parameters, including the temperature of the feeding water and the volumes of water to be heated.

In order to calculate the cost contribution due to water, the systems of the present disclosure typically calculate the volumes of water involved in each step or cycle. For washing machines, this calculation can be performed knowing the bath ratio, which is a parameter widely used in the industry.

$${V}_{H 2 O ( y )} [ L ] = {W}_{gtot} [ kg ] * {BR}_{( y )}$$

### Where:

V_{H2O(y)} is the weight or volume of the water loaded in the washing machine during the cycle “y”;
W_{gtot} is the total weight of garments loaded in the washing machine expressed in kg; and
BR_{(y)} is the bath ratio adopted in the cycle “y”.

Rinses, where no chemical products are added, can integrate the recipe or treatment. In such a case, rinses could be considered independent cycles with their names. Alternatively, rinses could be considered part of a cycle. In the latter case, the indication “rinse” means that the bath with chemicals is downloaded and new fresh water is used to perform the rinse. In this case, the time and bath ratio for the rinse needs to be specified.

### Example

Cycle number two (2) involves 100 kg of garments with a bath ratio=5. Garments are treated with some chemicals for 20 minutes. At the end of the specified duration, the bath is downloaded and two rinses, 2 minutes each, are performed using a bath ratio=3.

Then, the volume of water used is calculated as follows:

$${V}_{H 2 O ( 2 )} = ( 100 * 5 ) + 2 * ( 100 * 3 ) = 1 , 100 liters$$

Additional water could be added to the washing machine by auxiliary equipment as described herein. In this case, the additional contribution of water due to an auxiliary machine used in the cycle “y” can be calculated as follow:

$${V}_{H 2 OAux ( y )} [ L ] = {AU}_{FR} [ L / min ] * {AU}_{t ( y )} [ min ]$$

### Where:

AU_{FR} is the flow rate declared for the equipment expressed in liters of water per minute, (see Table 8).
AU_{t(y)} is the activation time of the machine during the cycle “y”.

### Example

Cycle number two (2) involves the use of a nebulizing machine that adds to the washing machine water with a flow rate of 2 liters per minute. This auxiliary machine is activated for 5 minutes within the cycle.

Then, the volume of water used is calculated as follows:

$${V}_{H 2 OAux ( 2 )} = 2 * 5 = 10 liters of water added during the cycle number 2$$

The total volume of water involved in the treatment, comprehensive of all cycles, can be calculated as follow:

$${V}_{H 2 Otot} = {\sum }_{y = 1}^{n} {V}_{H 2 O ( y )} + {V}_{H 2 OAux ( y )}$$

### Where:

N is the number of cycles included in the treatment;
Y is the id number of the cycle;
V_{H2O(y)} is the weight or volume of the water loaded in the washing machine during the cycle “y”; and
V_{H2OAux(y)} is the additional weight or volume of water due to an auxiliary machine.

Eventually, when the volumes of water involved in a cycle or the whole treatment are known, the systems of the present disclosure can calculate the cost contribution to the treatment due to water.

$${H}_{2} {O}_{Cost} [ USD ] = ( {V}_{H 2 Otot} [ L ] / 1 , 000 ) * {H}_{2} {O}_{Price} [ USD / {m}^{3} ]$$

### Where:

V_{H2Otot} is the total volume of water involved in the treatment, comprehensive of all cycles;
H_{2OPrice} is the purchasing price of the water.

Since the number of garments (NG) is known, the system can also evaluate the water footprint in terms of liters of water needed for each garment.

$${H}_{2} {O}_{Gar} [ L ] = {V}_{H 2 Otot} [ L ] / NG$$

Generally, users of the systems of the present disclosure will indicate the target temperature for each cycle whenever a washing machine is involved. The selected value has a crucial effect on the amount of energy necessary to reach the desired temperature. This amount will depend predominantly on the following factors:
The difference between the desired temperature of the cycle and the temperature of the feeding water.
The volume of the water involved in the cycle.
Presence of rinses and volumes of water involved.
The number of rinses.
The desired temperature for rinses.

The systems of the present disclosure typically use kJ (kilojoules) to calculate the energy, but other units of measure could be adopted as well by adopting/implementing the correct conversion factors. For the cycle “y”, the energy expressed in kilojoules required to heat the water host in a washing machine during the cycle “y” can be calculated as follow:

$${KJ}_{H 2 O ( y )} [ kJ ] = \{ ( {T}_{( y )} [ ° C . ] - {T}_{H 2 O} [ ° C . ] ) * BR * {W}_{Gtot} [ kg ] * 4186 [ J / {kg}^{*} ° C . ] \} / 1000$$

### Where:

T_{H2O} is the temperature of the feed water-typically either average or a period of time or real time temperature based on readings from one or more temperature sensors in the water;
T_{(y)} is the targeted temperature, expressed in Celsius degrees, for the cycle “y”;
BR is the bath ratio—typically this is expressed as a weight (kg) of water divided by the weight (kg) of fabrics to be treated;
W_{Gtot} is the total weight of garments loaded in the washing machine expressed in kg;
4186 is the specific heat capacity of water at 20° C. expressed in J/kg° C. Although different values could be set for other temperatures, for simplicity this value will be kept constant throughout the simulations.

If rinses are part of the cycle, and the desired temperature is higher than that of the feed water, the same formula can be used to evaluate the requirements in terms of kilojoules. Thus, the overall energy required to heat water in a treatment that involves y cycles can be calculated as follow:

$${KJ}_{H 2 O} = {\sum }_{y = 1}^{n} {KJ}_{H 2 O ( y )}$$

Energy needed to heat air in dryers.

Generally, users indicate the target temperature of dryers during the drying process. High flow rates of air through dryers can have a dramatic effect on the energy required to dry wet or moist garments. The energy will mainly depend on:
The difference between the desired temperature of the cycle and the temperature of the environment;
The volume of air to be heated, which also depends on the airflow rate;
Presence of devices in the dryer that can optimize the airflow and stop the system whenever they detect that moisture has decreased under a pre-set value.

A specific field may be included at the end of each washing cycle as well for the number of washing cycles to facilitate the determination of the bath ratio.

### For Example:

If one wants to perform a drying step after the washing cycle number four (4), which includes a short centrifuge, a field may be provided to state that the bath ratio after the fourth washing cycle (and the centrifuge) is 2:1. Assuming that the weight of the garments treated is 50 Kg, this means there is 100 Kg of water to eliminate using the dryer.

Similar to the previous case, the systems of the present disclosure use kJ (kilojoules) to calculate the energy, but other units of measure can be adopted as well by utilizing the correct conversion factors. First, the system of the present disclosure calculates the overall amount of air to heat during the cycle “y”:

$${V}_{Air ( y )} [ {m}^{3} ] = {t}_{Dry ( y )} [ min ] * {DR}_{FR} [ {m}^{3} / min ]$$

### Where:

t_{Dry(y)} is the time set for the dryer during the cycle “y”.
DR_{FR} is the air flow rate of the used dryer. This parameter is linked to the selected dryer and it is inherited by Table 6 above.

Next, the system of the present disclosure calculates the energy, expressed in kilojoules, necessary to heat the volume V_{Air(y)} from the ambient to the targeted temperature:

$${KJ}_{Air ( y )} [ kJ ] = ( {T}_{Dry ( y )} [ ° C . ] - {T}_{Air} [ ° C . ] ) * {V}_{Air ( y )} [ {m}^{3} ] * 1005 [ J / kg ° C . ] * 1.2754 [ kg / {m}^{3} ] / 1000$$

### Where:

t_{Dry(y)} is the time set for the dryer during the cycle “y”.
T_{Dry(y)} is the selected drying temperature.
1005 is the approximated pre-selected value for the specific heat capacity of air. The value could be refined or calculated depending on other factors, including, for example, the geographical altitude.
1.2754 is the approximated density value of air, expressed in kg/m3, at 0° C. and 100 kPa. The value could be calculated more precisely depending on other factors, including the ambient temperature and geographical altitude.

### Example

A dryer with an airflow rate of 33 m3/min is used to dry garments in cycle number three (3) at 70° C. as in the examples immediately below. The dryer runs for 10 minutes and the ambient air is 28° C.

Then, the volume of air involved is:

$${V}_{Air ( 3 )} = 10 * 33 = 330 {m}^{3}$$

While the energy required is:

$${KJ}_{Air ( 3 )} = ( 70 - 28 ) * 330 * 1005 * 1.2754 / 1000 = 17 , 756 kJ$$

Thus, the overall energy required to heat air in the whole treatment can be calculated as follow:

$${KJ}_{Air} = {\sum }_{y = 1}^{n} {KJ}_{AIR ( y )}$$

Fuel needed to heat water and air used in the laundry has a significant impact on the energy and environmental impact of a laundry system. The computing systems and mobile application tools that create, evaluate, and compare actual and one or more virtual laundry systems or virtual textile processing systems of the present disclosure also typically consider if the fuel used in boilers can be identified by a single molecule, with its heat of combustion (e.g., methane, butane), or if the fuel is rather constituted by a material without a specific composition (e.g., diesel, wood). It has been found that the energy and systems employed in the drying steps of an actual or virtual laundry have a significant impact on the overall energy efficiency of the overall process and the laundry as a whole and, as a result, has a significant impact on the sustainability of the laundry. This factor is typically the most influential factor in the sustainability evaluation and the energy efficiency evaluation of the laundry system(s) being evaluated and compared using the tools and systems of the present disclosure to drive toward a more economically and environmentally sustainable laundry system. This task is performed after the user has selected the boiler in its virtual laundry according to Table 3. Through the parameter BO_{Fuel} of Table 3, which is linked to the parameter FU_{ID}, the system of the present disclosure identifies which kind of fuel is used according to Table 1. Through the value of the field HOC_{Un}, the system of the present disclosure will execute two different calculations to determine the theoretical amount of fuel needed to provide the requested energy.

Heat of combustion (HOC) is the heat of combustion of the molecule typically expressed in kJ/mol. In most instances, HOC is associated with a lower heating value (LHV). Sometimes LHV values are reported in the various literature or handbooks expressed as net calorific value (NCV). The systems of the present disclosure utilize the same criteria for the HOC. The system uses heat of combustion data provided adopting the same criterium. For instance, some combustion heat values for fuels can be found in handbooks tables expressed as HHV, known as higher heating value or gross calorific value (GCV). Heating values (LHV or HHV) are equal to the enthalpy of combustion ΔHcomb but with an opposite sign. The difference between LHV and HHV is the heat of vaporization of water. Since, after the combustion, the products are above the boiling point of water, LHV values are preferably used in the systems of the present disclosure as indicators of a fuel's useful heat.

For example, the LHV of methane is approximately 802 kJ/mol at 298.15 K (25° C., 77° F.), while HHV for the same molecule is approximately 890 kJ/mol. The difference (88 kJ) is the heat of vaporization of 2 moles of water according to the reaction CH₄(g)+2O₂ (g)→CO₂ (g)+2H₂O(g).

Case A) Fuel has a defined composition and is constituted by a single molecule.

In this case, HOC_{Un} of Table 1 is set to “kJ/mol”, which are the units assigned to the parameter HOC of Table 1. Then, the system of the present disclosure will determine how many moles of fuel are necessary for the cycle “y” according to the following formula:

FUm_{(y)}[mol]=(KJ_{H2O(y)}[kJ]+KJ_{Air(y)}[kJ])/HOC[kJ/mol]

### Where:

KJ_{H2O(y)} is the energy required to heat water in the cycle y;
KJ_{Air(y)} is the energy required to heat air in the cycle y;
HOC is the heat of combustion of the molecule expressed in kJ/mol for cycle y in this example.

The amount of the fuel expressed in grams can be calculated in the following manner:

FUw_{(y)}[gr]=FUm_{(y)}[mol]*FU_{Mm}[gr/mol]/BO_{Eff}

### Where:

FU_{Mm} is the molar mass of the molecule used as fuel expressed in gr/mol.
BO_{Eff} is the thermal efficiency of the boiler, as stated in Table 3.

If the amount of fuel is not declared by the manufacturer of the equipment used, the systems of the present disclosure may use one of the following:
1) A default value linked to a generic version of the equipment, in this case a boiler; or
2) A calculated figured based on the real consumption of fuel and theoretical consumption. For example, if the real consumption of fuel is double the theoretical value, then the systems of the present disclosure estimate a value of 50% of BO_{Eff}.

### Example

20,930 kJ are necessary to heat water during the second cycle, while 17,765 kJ are required in the same cycle to dry the garments. The selected boiler uses methane, which has a heat of combustion (expressed in LHV) equal to 802.34 kJ/mol and a molar mass of 16.04 gr/mol. The thermal efficiency of the boiler is 90%.

Then, the number of moles of methane necessary to satisfy the energy needs of the second cycle, cycle number 2, is:

$${FUm}_{( 2 ) =} ( 20 , 930 + 17 , 765 ) / 802.34 = 48.23 moles of methane \\ {FUw}_{( 2 ) =} 48.23 * 16.04 / 0.9 = 860 grams of methane$$

Case B) The fuel is not constituted by a single molecule. In this case, HOC_{Un} of Table 1 is set to “kJ/kg”, which are the units assigned to the parameter HOC in the same table. Then, the system of the present disclosure will determine how many grams of fuel are necessary according to the following formula:

$${FUw}_{( y )} [ gr ] = 1000 * ( {KJ}_{H 2 O ( y )} [ kJ ] + {KJ}_{Air ( y )} [ kJ ] ) / HOC [ kJ / kg ] / {BO}_{Eff}$$

### Example

20,930 kJ are necessary to heat water during cycle number two (2), while 17,765 kJ are required in the same cycle to dry the garments. The selected boiler uses diesel as fuel, which has an approximate heat of combustion (expressed as LHV) equal to 44,000 kJ/kg. The thermal efficiency of the boiler is 90%.

Then, the amount of diesel necessary to satisfy the energy needs of the cycle number two (2) is:

$${FUw}_{( 2 ) =} 1000 * ( 20 , 930 + 17 , 765 ) / 44 , 000 / 0.9 = 977 grams of diesel$$

In both cases presented above, the theoretical amount of fuel necessary to accomplish a task would be true only for boilers with a thermal efficiency of 100%, which would convert all the chemical energy into usable heat. For an accurate simulation of a real world physical scenario, the thermal efficiency of boilers is less than 100%. This is taken into account by the systems of the present disclosure by the parameter BO_{Eff} shown and discussed above. If this data is not declared by a manufacturer of a piece of equipment, the systems of the present disclosure may provide this information by providing a default value or one based on a calculation of the real consumption of fuel and theoretical consumption of fuel. For instance, if the real consumption of fuel is double the theoretical value, then the systems of the present disclosure can estimate a value of 50% for BO_{Eff} Thus, the thermal efficiency of boilers will have a significant impact on the amount of fuel needed, related costs, and carbon emissions as well.

Similar to other cases presented in this document, the overall amount of fuel can be calculated for each garment, divided by NG (number of garments) or for the whole treatment according to the formula:

$${FU}_{W} = {\sum }_{y = 1}^{n} {FU}_{W ( y )}$$

Carbon emissions due to fuel are also typically considered in connection with the use of the mobile application and systems of the present disclosure. Carbon emissions due to fuel can be theoretically calculated in two different manners. First, the systems of the present disclosure examine if the fuel used in boilers can be identified by a single molecule, with its heat of combustion (e.g., methane, butane), or if the fuel is rather constituted by a material without a specific composition (e.g., diesel, wood). The method of detection is the same as presented above.

Case A) Fuel has a defined composition and is constituted by a single molecule. In this case, the system of the present disclosure examines what is the molar mass ratio between carbon dioxide (CO₂) and the molecule that is used as fuel:

$$MMR = 44.01 [ gr / mol ] / {FU}_{Mm} [ gr / mol ]$$

### Where:

44.01 is the molar mass of CO₂;
FU_{Mm} is the molar mass of the fuel.

Next, the systems of the present disclosure calculate how many grams of carbon dioxide, CO₂, are theoretically generated in a cycle by the combustion of a given amount of fuel. The exact amount of fuel involved is calculated according to the formulas presented above. The formula used to calculate the theoretical amount of CO₂, expressed in grams, emitted during the combustion of the fuel during the cycle “y” is:

COF_{W(y)}[gr]=FUw_{(y)}[gr]*FU_{MCO}*MMR

### Where:

FUw_{(y)} is the amount of fuel, expressed in grams, needed to heat water and air in the cycle “y”, as specified above;
FU_{MCO} is the number of moles of CO₂ generated by one mole of fuel according to the content of the corresponding field in table 1.

Case B) Fuel is not constituted by a single molecule. In this case, the systems of the present disclosure examine what is the weight of the fuel needed according to calculations presented in the previous paragraph and multiplies it by the recorded amount of CO₂ emitted per gram. In this case, the formula used to calculate the theoretical amount of CO₂ emitted by the combustion of the fuel for cycle y is:

COF_{W(y)}[gr]=FUw_{(y)}[gr]*FU_{GrC}[gr/gr]

### Where:

FUw_{(y)} is the amount of fuel, expressed in grams, needed to heat water and air in the cycle “y”, as specified earlier;
FU_{GrC} are the grams of CO₂ generated by the combustion of one gram of fuel according to the content of the corresponding field in table 1; and
These values can be derived from literature or handbook sources and are typically expressed as ratio of the grams of CO₂/grams of fuel.

With the same method presented in other paragraphs, one can calculate the carbon footprint due to fuel combustion, expressed in grams, for each cycle, for the garment, and/or the entire treatment process or any combination thereof. Examples include the following:
Grams of CO₂ due to combustion of fuel emitted during the whole treatment:

$${COF}_{W} = {\sum }_{y = 1}^{n} {COF}_{W ( y )}$$

Grams of CO₂ per garment due to combustion of fuel emitted during the whole treatment:

COFG_{W}=COF_{W}/NG
Grams of CO₂ per garment due to combustion of fuel emitted during the cycle “y”:

COFG_{W(y)}=COF_{W(y)}/NG

Once the amount of fuel involved in each cycle is known, the software systems of the present disclosure can calculate the cost contributions according to the following formulas:

Cost of fuel for the whole treatment:

$${FU}_{Cost} [ USD ] = ( {FU}_{W} [ gr ] / 1000 ) * {FU}_{Price} [ USD / kg ]$$

Cost of fuel for the cycle “y”:

$${FU}_{Cost ( y )} [ USD ] = ( {FU}_{W ( y )} [ gr ] / 1000 ) * {FU}_{Price} [ USD / kg ]$$

Energy requirements, typically electrical energy for the washing machine during the cycle “y” is calculated by the systems of the present disclosure through the formula:

$${EN}_{WM ( y )} [ kWh ] = ( {t}_{WM ( y )} [ min ] + {t}_{Rin ( y )} [ min ] ) * {WA}_{KW} [ kW ] / 60$$

### Where:

t_{WM(y)} is the time, expressed in minutes, needed by the washing machine to perform a washing in the cycle “y”;
t_{Rin(y)} is the time, expressed in minutes, needed by the washing machine to perform rinses in the cycle “y”;
WA_{KW} is the power, expressed in kW, of the washing machine according to the corresponding field of Table 4.

Energy requirements for the centrifuge used during the cycle “y” are calculated by the systems of the present disclosure through the formula:

$${EN}_{Cen ( y )} [ kWh ] = {t}_{Cen ( y )} [ min ] * {CE}_{KW} [ kW ] / 60$$

### Where:

t_{Cen(y)} is the time, expressed in minutes, needed by the centrifuge to perform a hydro extraction in the cycle “y”;
CE_{KW} is the power, expressed in kW, of the centrifuge according to the corresponding field of Table 5.

Energy requirements for the dryer used during the cycle “y” are calculated by the systems of the present disclosure through the formula:

$${EN}_{Dry ( y )} [ kWh ] = {t}_{Dry ( y )} [ min ] * {DR}_{KW} [ kW ] / 60$$

### Where:

t_{Dry(y)} is the time, expressed in minutes, needed to dry garments in the cycle “y”;
DR_{KW} is the power, expressed in kW, of the dryer according to the corresponding field of Table 6.

To calculate the energy requirements for laser equipment, mannequins, cabin spray, or other equipment that operate sequentially on garments on the cycle “y”, the system of the present disclosure needs firstly to calculate how much time, typically how many minutes, the equipment is active. This time can be calculated with the formula:

$${t}_{LSAct ( y )} [ min ] = {t}_{LSOp ( y )} [ sec ] * NG / 60 / {LS}_{PPt}$$

### Where:

t_{LSOp(y)} is the time, expressed in seconds, effectively necessary to the device/operator to perform the task (e.g., time needed by the laser beam to complete a drawing on a garment or time needed by an operator to perform a manual scraping on a single garment);
NG is the number of garments involved in the process;
LS_{PPt} is the number of garments that can be treated simultaneously by the selected device. This parameter is inherited from Table 7.

The systems of the present disclosure typically will calculate the energy requirements with the following formula:

$${EN}_{LS ( y )} [ kWh ] = {t}_{LSAct ( y )} [ min ] * {LS}_{KW} [ kW ] / 60$$

Energy requirements for the auxiliary equipment used during the cycle “y” are calculated by the system of the present disclosure through the formula:

$${EN}_{Aux ( y )} [ kWh ] = {t}_{Aux ( y )} [ min ] * {AU}_{KW} [ kW ] / 60$$

### Where:

t_{Aux(y)} is the time, expressed in minutes, needed to auxiliary equipment to perform a task in the cycle “y”;
AU_{KW} is the power, expressed in kW, of the auxiliary equipment according to the corresponding field of Table 8.

Finally, the total amount of energy expressed in kWh required in the cycle “y” is calculated by summing the various contributions:

EN_{(y)}=EN_{WM(y)}+EN_{Cen(y)}+EN_{Dry(y)}+EN_{LS(y)}+EN_{Aux(y)}

While the total amount of energy, expressed in kWh needed for the whole treatment will be given by the formula:

$$EN = {\sum }_{y = 1}^{n} {EN}_{y}$$

As discussed elsewhere herein, the systems of the present disclosure may also consider the amount of energy self-produced. For example, a solar-cell plant installed on the roof of the facility may reduce costs, amount of energy needed and increase avoided CO₂ emissions/decrease the CO₂ emissions. Other potential sources of energy that may be considered in the systems of the present disclosure include, as non-exhaustive examples, eolic/wind plant power, generators that use the sea currents, generators powered by rivers or channels, geothermal sources, batteries recharged with any renewable sources, etc.

The systems of the present disclosure are also typically able to calculate the cost of the energy for each cycle or the whole treatment by multiplying the values of the parameters shown above by the cost of the energy expressed in United States Dollars (USD) or other currency/kWh. The value is explicated by the field EN_{Price} listed in Table 2.

Thus, the total cost of energy needed to complete the cycle “y” will be given by the formula:

EN_{Cost(y)}[USD]=EN_{(y)}[kWh]*EN_{Price}[USD/kWh]

### Where:

EN_{(y)} is the energy, expressed in kWh, used to complete the cycle “y”;
EN_{Price} is the cost of the energy, expressed in USD/kWh, for the selected Country or power supplier.

Again, the total cost of the energy needed to complete the treatment is typically given by the formula:

$${EN}_{Cost} = {\sum }_{y = 1}^{n} {EN}_{Cost ( y )}$$

As discussed above, the EN_{Cost} may also consist of two contributions, not just costs, but also potential energy costs savings due to energy produced in situ by the system such as a result of the implementation of solar power, for example. This can also take into account cost savings due carbon credits according to national and/or regional regulations and typically quantify the same for third parties.

The systems of the present disclosure also can calculate the carbon emissions due to the energy sourced from electricity suppliers that also generates carbon emissions, which may vary depending on how the energy is obtained. For instance, power plants based on coal will generate significantly higher emissions compared to plants based on solar cells or wind energy. The mobile application and other systems of the present disclosure may calculate the theoretical carbon footprint by considering the amount of CO₂ emitted per kWh (carbon intensity of electricity). Data referring to specific Countries (as average values) or electricity suppliers are collected in Table 2 and used for this calculation. Consequently, the amount of CO₂, expressed in grams, released to the atmosphere due to the use of energy during the cycle “y” can be calculated as follow:

COE_{W(y)}[gr]=EN_{(y)}[kWh]*CIN[gr/kWh]

### Where:

EN_{(y)} is the amount of energy, expressed in kWh, as specified above;
CIN is the carbon intensity of electricity, as specified in Table 2.

Then, other calculations can be performed as shown below:

Grams of CO₂ emitted due to electricity during the whole treatment:

$${COE}_{W} = {\sum }_{y = 1}^{n} {COE}_{W ( y )}$$

Grams of CO₂ per garment emitted due to electricity during the whole treatment:

COEG_{W}=COE_{W}/NG

Grams of CO₂ per garment emitted due to electricity during the cycle “y”:

COEG_{W(y)}=COE_{W(y)}/NG

Data and the formula(s) presented in the carbon emissions due to fuel and carbon emissions due to electricity discussions above for determining the amount of CO₂ emitted due to fuel and electricity, can be summed to determine what are the amounts of carbon dioxide emitted for the whole treatment, for each garment, for each cycle, or other combinations.

Examples are given below:

Total grams of CO₂ emitted during the cycle “y”:

CO_{W(y)}[gr]=COF_{W(y)}[gr]+COE_{W(y)}[gr]

Total grams of CO₂ emitted for the whole treatment:

CO_{W}[gr]=COF_{W}[gr]+COE_{W}[gr]

Total grams of CO₂ per garment emitted during the cycle “y”:

COG_{W(y)}[gr]=COEG_{W(y)}[gr]+COFG_{W(y)}[gr]

Total grams of CO₂ per garment emitted for the whole treatment:

COG_{W}[gr]=COEG_{W}[gr]+COFG_{W}[gr]

For the definitions of the parameters, please refer to the carbon emissions due to fuel and carbon emissions due to electricity discussions above.

Total cost of the treatment.

The estimated total cost of a given treatment, which is typically a very accurate estimate, in particular an accurate estimate of the costs of chemical products and costs related to water intake) may be determined Using the data and formula(s) presented above regarding the cost contribution of the chemicals, the cost contribution due to water, the cost contribution due to fuel, and the cost contribution due to electricity, can be combined to determine the total cost of the treatment as follows:

Cost=CH_{Cost}+H2O_{Cost}+FU_{Cost}+EN_{Cost}

The cost can be easily analyzed on a cycle basis to understand which cycle is the most impactful in terms of cost:

Cost_{(y)}=CH_{Cost}(y)+H2O_{Cost(y)}+FU_{Cost}(y)+EN_{Cost(y)}

As used herein, the following parameters are defined as below unless otherwise noted:
T_{H2O}=temperature of the feeding water, which can be also input as an average value over a specific time (e.g., yearly, monthly, weekly, daily, or real-time).
H₂O_{Cost}=cost of the water per cubic meter expressed as USD/m3. Other currencies can be used as well with the support of currency exchange values.
T_{Air}=environmental temperature, which can be also inputted as an average value over a specific time (e.g., yearly, monthly, weekly, daily, or real-time).

Significantly, the mobile application and systems of the present disclosure allow the creation of standard or reference treatments to perform real-time comparisons between references and alternatives. The systems may also proactively make suggestions as to the changes to a laundry system created through the virtual laundry systems of the present disclosure that will create the greatest environmental impact in the most economical fashion. The systems can do so based on established industrial factors or based on factors prioritized by the user such as prioritizing long-term economical sustainability or perhaps environmental sustainability. Conceivably, the user can provide a prioritization between both considerations on a graphical user interface where the user moves a sliding scale indicator between both extremes of suggestions that will make the biggest impact for economic sustainability vs. environmental sustainability. It may also be possible to list or filter recipes and washing plants according to their main features and/or common elements. These filters would help a user prioritize their actions. For example, if the systems of the present disclosure identify one washing machine is driving high emission of carbon dioxide, the system can create an alert and give suggested alternatives and/or list the recipes most likely to be improved by changing this hardware used in the laundry recipe/process.

Key parameters for comparisons are related to energy, fuel, water used, carbon dioxide emitted, time, and cost. Additional parameters that are also typically key parameters evaluated using the systems of the present disclosure include, but are not limited to the level of contaminants as well as the use and/or level of hazardous or dangerous chemicals.

Therefore, the system of the present disclosure constitutes a precious instrument to simulate the complex events that are involved in textile processes, in particular laundry processes, thus visualizing the potential benefits in terms of return on investment, productivity, and sustainability, including aspects related to carbon and water footprints without having to actually implement the changes.

Moreover, the system may proactively suggest improvements or changes to the user to make the system more sustainable for the environment and/or financially sustainable for the owner of the facility being analyzed. These proposals may include push notifications in dynamic real time based on new input or based on artificial intelligence analysis of possible replacement equipment or chemicals or changed processing steps, for example, not currently available within the real world facility of the user conducting the analysis of the real world physical plant. The system is also able to send those notifications based on estimated actual difference limit filters such that the notification is only provided if a threshold improvement to the currently implemented recipe in the physical processing facility is observed by the systems of the present disclosure. The estimated quantification of the proposed change or changes may be displayed to the user as well and possibly provided to certification entities and/or regulatory authorities if necessary (or any third party if the user wishes).

The systems of the present disclosure may also accept a single version of a treatment recipe and autonomously propose an improvement of the process based on one or more priorities of the user. For example, if the user sets H₂O footprint reduction as the top priority, the tool may suggest proposing a recipe that uses lower bath ratios in some cycles thereby lowering the water usage/water footprint.

Moreover, the systems of the present disclosure enable a user to accurately estimate the likely carbon credits achieved by making changes to the recipe currently employed if a change consistent with a virtual recipe is actually employed.

The systems of the present disclosure may also optionally provide a scaled ranking of an actual or proposed recipe being employed or actually being employed to provide the user with a benchmarking of the sustainability of their current system or a possible virtual system if the recipe is changed for a given facility. It is also contemplated that they detailed reports regarding the details of a virtual recipe and/or the quantitative details of any comparison produced by the systems of the present disclosure between the actual recipe currently employed and a virtual recipe may be shared with one or more sustainability certification entities to determine the accreditation or certification of a virtual recipe from the one or more sustainability certification entities prior to it being implemented in a given actual physical facility. Exemplary certification entities include: The data provided by the systems of the present disclosure may be provided to regulatory authorities before or after changes are made to the system to determine if sustainability thresholds established by a given jurisdictions are met or not and, if met, the quantification of any carbon credits or carbon offsets available due to the actually implemented or proposed virtual recipe.

Additionally, the systems of the present disclosure can automatically and dynamically change one or a plurality of parameters of a currently implemented recipe being employed based on data received from any physical equipment in signal communication with the systems of the present disclosure and/or sensors related to input of processing materials such as a temperature sensor in the water intake or quantity sensors for or automatic dispensing systems of any chemical holding tank associated with the system. Any automatic chemical dispensing systems, for example, may dispense more or less chemical or do so at different stages in a given process if the systems of the present disclosure observe that increased sustainability and/or cost savings can be achieved, typically cost savings without impacting sustainability or when also improving sustainability. By way of another example of an input that may be automatically changed or changed upon the approval of a user and thereafter automatically implemented by the systems of the present disclosure in signal communication with processing equipment in a physical textile processing facility include the following. First, if the systems of the present disclosure determine that preheating water used in the physical facility will help with enzymatic treatment of the textile being treated the system may, upon approval of the change by a user or automatically, change the temperature of or the amount of water used/input at any given stage in a processing recipe being employed. The system may also automatically adjust the exhaust system of the dryer, for example, to provide added heat to another part of the physical processing facility and do so in real time to provide this heat.

The systems of the present disclosure may autonomously make decisions and implement changes at different levels of complexity. For example: if a user has set CO₂ reduction as a priority within the system of the present disclosure, the systems of the present disclosure, when integrated and in signal communication with the various physical pieces of equipment via a wireless or wired networking system such as a WIFI® or cellular signal system, may instruct a pumping dosing system to feed washing machines with a product that performs stonewashing at 30° C. instead of 50° C. By way of yet another example, the systems of the present disclosure may extend a centrifuge by a time period such as five (5) minutes if it calculates that the extra energy and time are largely compensated by shorter time and much less fuel/energy required by the driers that appear at a later stage in the recipe.

The virtual laundry systems 10 of the present disclosure are typically accessed by a plurality of users 1 using a computer system, typically a touch screen containing mobile computer system such as a mobile phone typically having wireless communication ability or abilities to access one or more remotely located virtual laundry generating computer server systems 2. The exemplary virtual laundry generating computer systems 2 are shown in FIG. 1 and they typically include one or more processors 3 configured to execute instructions and to carry out operations associated with the computer system 2 as well as one or more memory devices 4. The virtual laundry generating computer server systems of the present disclosure also typically utilize one or more than one display 5 and various user input devices including, for example, a keyboard 6. The systems 2 of the present disclosure also may communicate with one or more third party sustainable laundry related servers or other laundry data containing servers to enable benchmarking and data importation from a variety of third party sources if a user does not wish to simply rely on their own data for use in connection with the virtual laundry systems of the present disclosure. Data, as discussed elsewhere herein as well, may include details about equipment currently owned or being purchased or potentially purchased by a user to add to their virtual laundry and their actual laundry. Using instructions retrieved for example from memory devices 4, the processor may control the reception and manipulation of input and output data between components of the computing system. The processor can be implemented on a single-chip, multiple chips or multiple electrical components. For example, various architectures can be used for the processor, including dedicated or embedded processor, single purpose processor, controller, ASIC, and so forth. In most cases, the processor together with an operating system operates to execute computer code and produce and use data.

Similar to the virtual laundry generating computer server systems of the present disclosure, the users that access the virtual laundry generating computer server systems of the present disclosure do so with a computer system that is typically remotely located (not in the same geographic area or visible by someone at the location of the virtual laundry generating computer server systems. Typically, the users will utilize a mobile computing device such as a mobile personal computer, but more typically they will utilize a mobile phone or tablet computing device using an operating system. The operating systems are generally well known and will not be described in greater detail. By way of example, the operating system may correspond to OS/2, DOS, Unix, Linux, Palm OS, ANDROID® and the like. The operating system can also be a special purpose operating system, such as may be used for limited purpose appliance-type computing devices. The operating system, other computer code and data may reside within a memory block that is operatively coupled to the processor. Memory block generally provides a place to store computer code and data that are used by the computer system. By way of example, the memory block may include Read-Only Memory (ROM), Random-Access Memory (RAM), hard disk drive and/or the like. The information could also reside on a removable storage medium and loaded or installed onto the computer system when needed. Removable storage mediums include, for example, CD-ROM, PC-CARD, memory card, floppy disk, magnetic tape, and a network component.

The computer systems used by users to access the remotely located virtual laundry generating computer server systems also includes a display device that is operatively coupled to the processor. The display device may be a liquid crystal display (LCD) (e.g., active matrix, passive matrix and the like) or LED or OLED display. Alternatively, the display device 68 may be a monitor such as a monochrome display, color graphics adapter (CGA) display, enhanced graphics adapter (EGA) display, variable-graphics-array (VGA) display, super VGA display, cathode ray tube (CRT), and the like. The display device may also correspond to a plasma display or a display implemented with electronic inks. The display is typically a touch sensitive display that also functions as an input device as discussed herein.

The display device is generally configured to display a graphical user interface (GUI) that provides an easy to use interface between a user of the computer system and the operating system or application running thereon. Generally speaking, the GUI represents, programs, files and operational options with graphical images. The graphical images may include windows, fields, dialog boxes, menus, icons, buttons, cursors, scroll bars, etc. Such images may be arranged in predefined layouts, or may be created dynamically to serve the specific actions being taken by a user. During operation, the user can select and activate various graphical images in order to initiate functions and tasks associated therewith. By way of example, a user may select a button that opens, closes, minimizes, or maximizes a window, or an icon that launches a particular program. The GUI can additionally or alternatively display information, such as non-interactive text and graphics, for the user on the display device.

As discussed above, the computer system used by a user to create and compare existing and proposed more sustainable laundry systems also typically includes an input device that is operatively coupled to the processor. The input device is typically configured to transfer data from the user into the computer system. The input device may, for example, be used to perform tracking and to make selections with respect to the GUI on the display. The input device may also be used to issue commands in the computer system. The input device typically includes a touch sensing device configured to receive input from a user's touch and to send this information to the processor. By way of example, the touch-sensing device may correspond to a touchpad or a touch screen. In many cases, the touch-sensing device recognizes touches, as well as the position and magnitude of touches on a touch sensitive surface. The touch sensing hardware systems report the touches to the processor and the processor interprets the touches in accordance with its programming. For example, the processor may initiate a task in accordance with a particular touch. A dedicated processor can be used to process touches locally and reduce demand for the main processor of the computer system. The touch sensing device may be based on sensing technologies including but not limited to capacitive sensing, resistive sensing, surface acoustic wave sensing, pressure sensing, optical sensing, and/or the like. Furthermore, the touch sensing means may be based on single point sensing or multipoint sensing. Single point sensing is capable of only distinguishing a single touch, while multipoint sensing is capable of distinguishing multiple touches that occur at the same time.

The input device may be a touch screen that is positioned over or in front of the display. The touch screen may be integrated with the display device or it may be a separate component. The touch screen has several advantages over other input technologies such as touchpads, mice, etc. For one, the touch screen is positioned in front of the display and therefore the user can manipulate the GUI directly. For example, the user can simply place their finger over an object to be controlled. In touch pads, there is no one-to-one relationship such as this. With touchpads, the touchpad is placed away from the display typically in a different plane. For example, the display is typically located in a vertical plane and the touchpad is typically located in a horizontal plane. This makes its use less intuitive, and therefore more difficult when compared to touch screens. In addition to being a touch screen, the input device can be a multipoint input device. Multipoint input devices have advantages over conventional single point devices in that they can distinguish more than one object (finger). Single point devices are incapable of distinguishing multiple objects. By way of example, a multipoint touch screen.

The computer systems of the present disclosure also typically include capabilities for coupling to one or more input/output (I/O) devices. By way of example, the I/O devices may correspond to keyboards, printers, scanners, cameras, speakers, and/or the like. The I/O devices may be integrated with the computer system used by the user or they may be separate components (e.g., peripheral devices). In some cases, the I/O devices 80 may be connected to the computer system through wired connections (e.g., cables/ports). In other cases, the I/O devices may be connected to the computer system 80 through wireless connections. By way of example, the data link may correspond to PS/2, USB, IR, RF, BLUETOOTH® or the like.

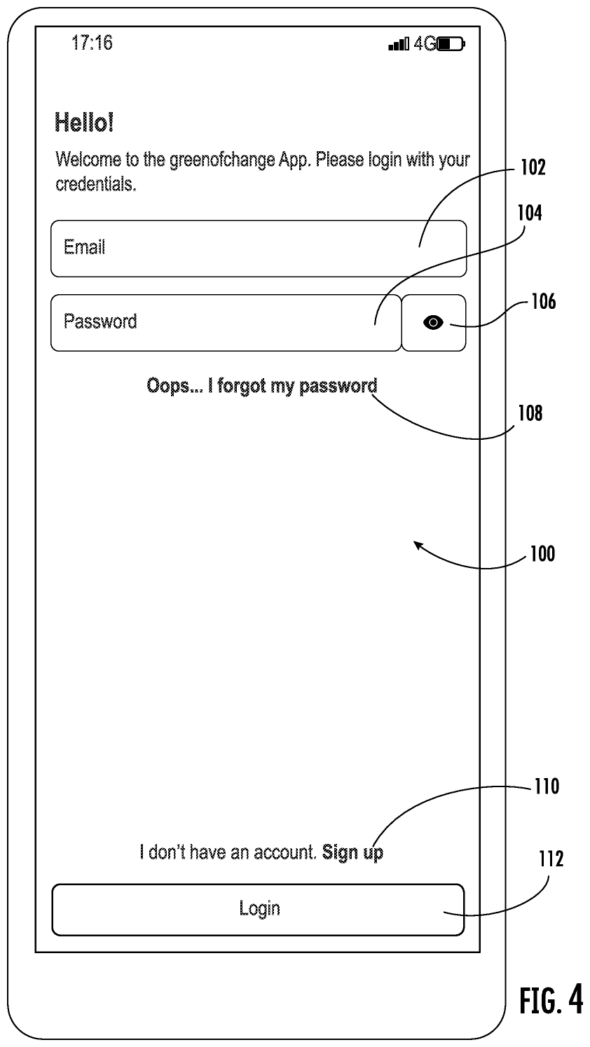

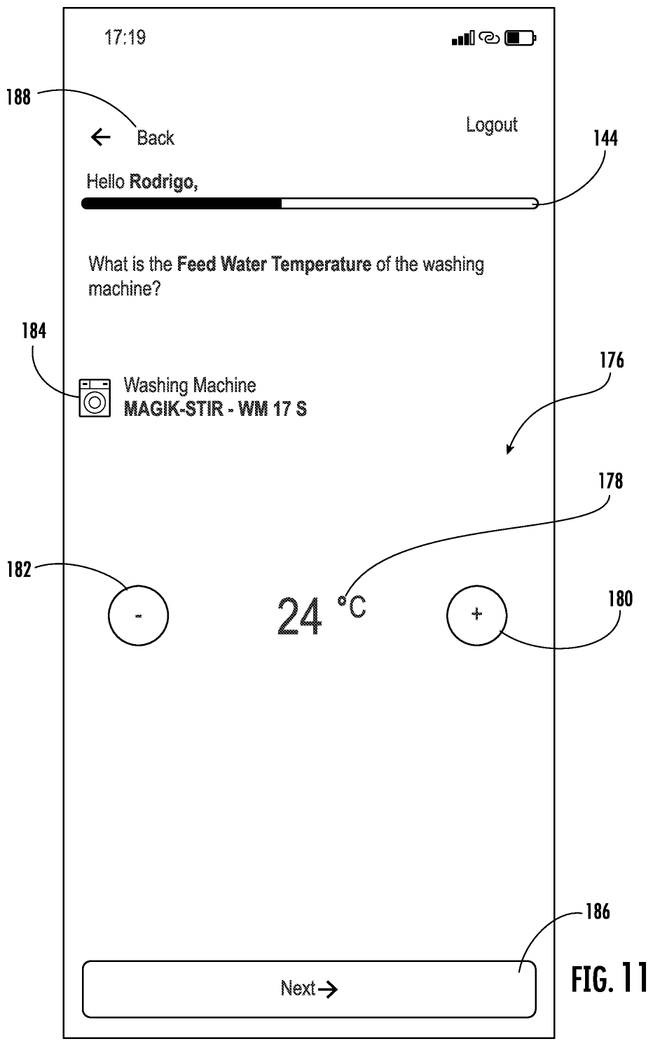

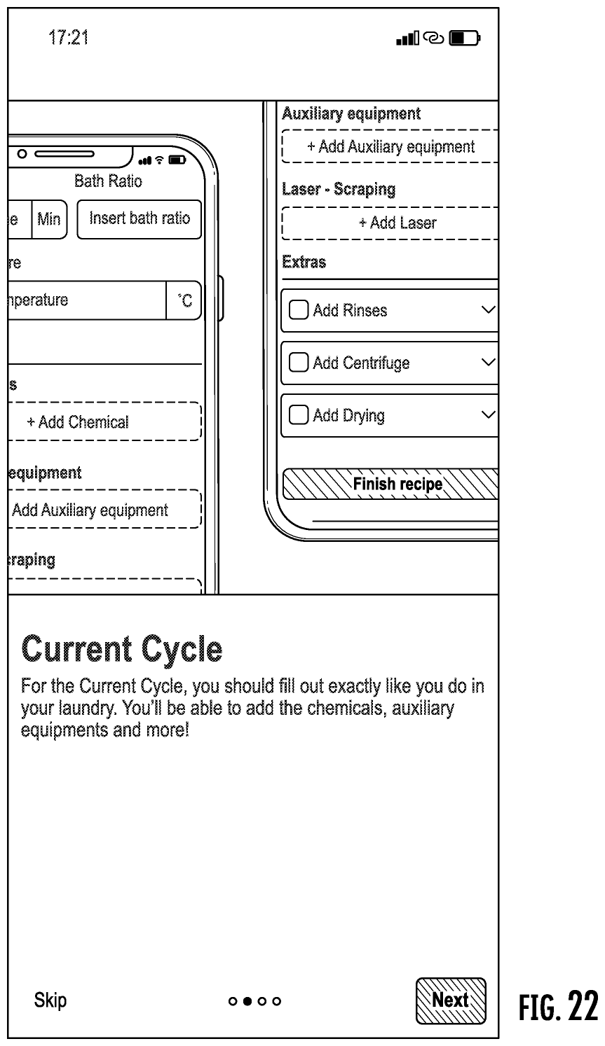

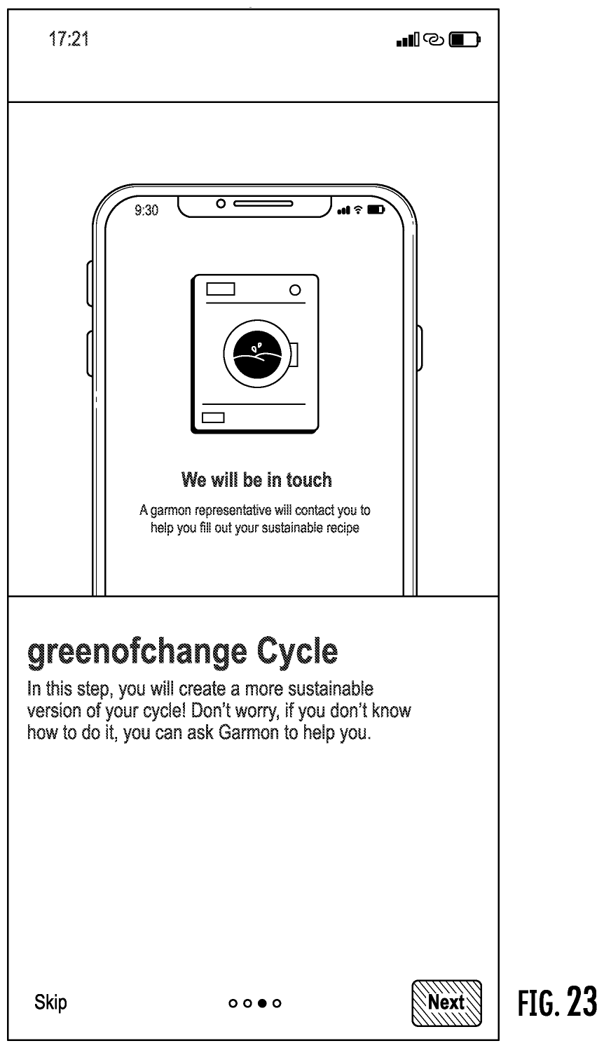

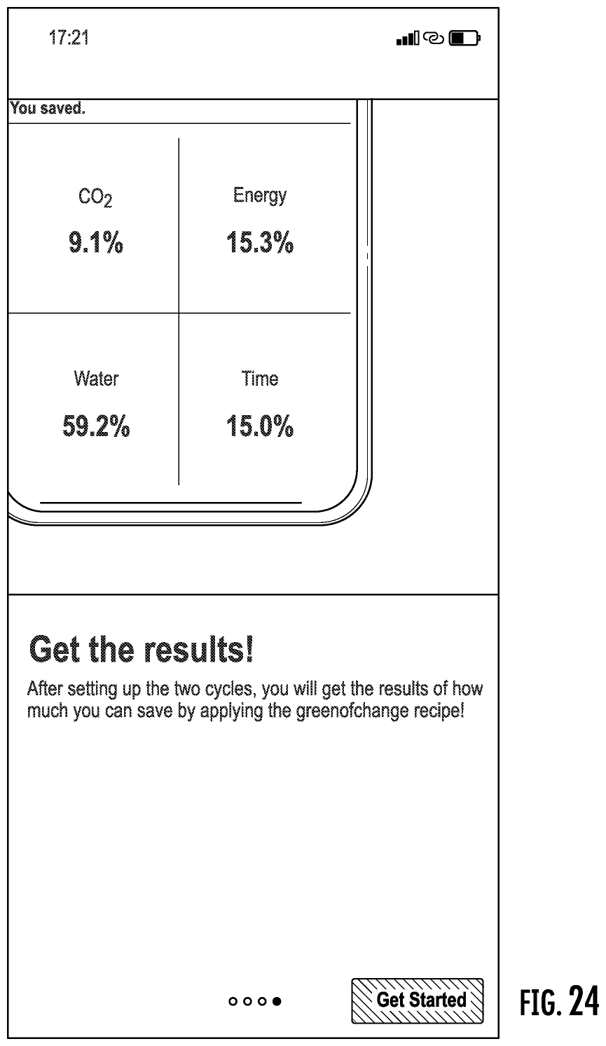

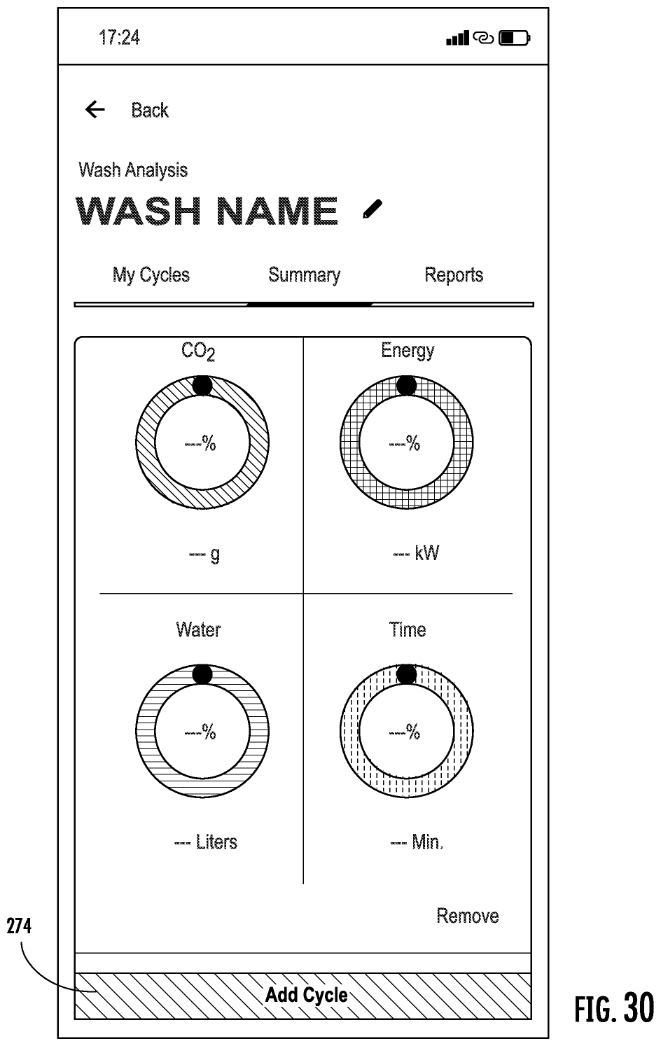

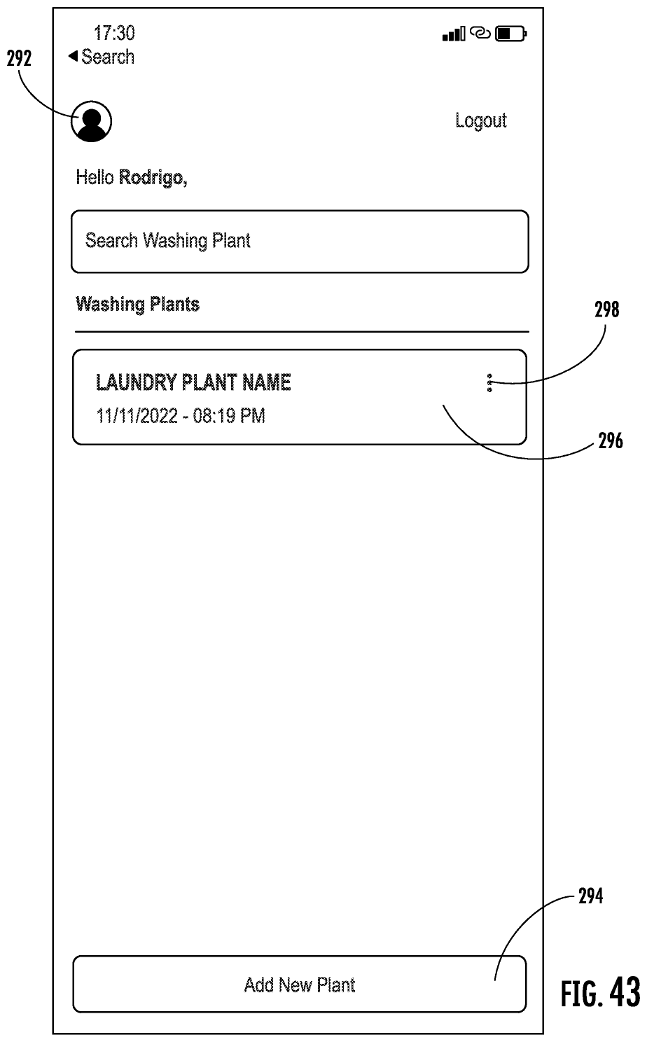

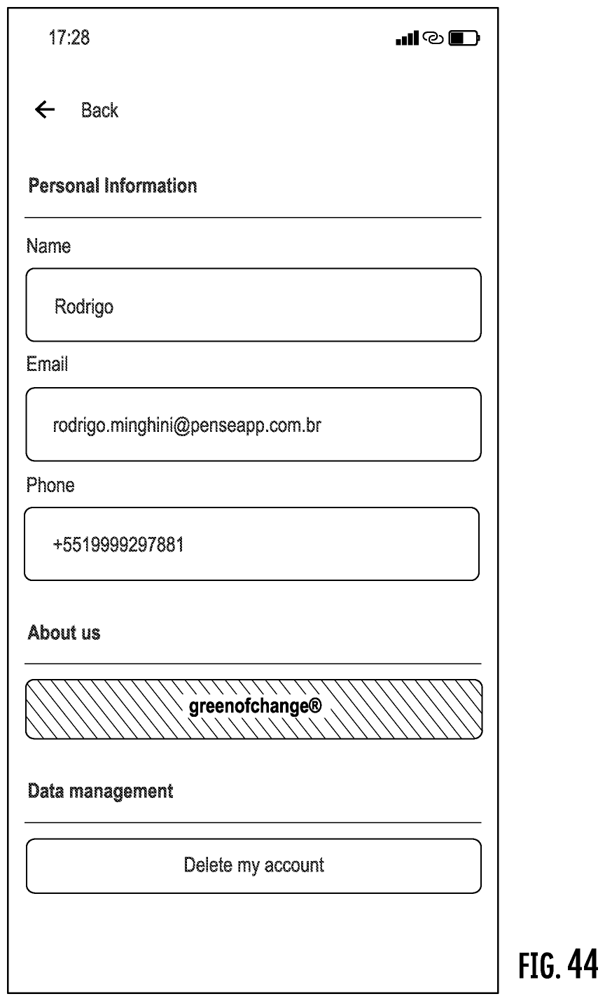

FIGS. 4-47 show various graphic user interface displays of an exemplary mobile computing application that facilitates the creation of personalized virtual laundry systems to accurately represent existing and proposed laundry systems, typically each containing multiple cycles that are also easily display comparisons between virtual laundry systems to allow a user to more easily ascertain changes that may be made to their particular laundry system in the real world and create a sustainable changes to improve the environment without actually making a high capital investment and significant changes in the real world systems. The systems of the present disclosure allow users to accurately predict the environmental and financial impact to a laundry system without making costly changes and/or changes to current systems requiring large amounts of downtime to current laundry systems to actually measure effects of such changes in the real world. The significant uncertainty of changing a laundry system currently being utilized significantly deters and, in most instances, outright prevents changes to existing laundry systems. This deterrent effect prevents changes that would impact financial costs and environmental impact in a positive way simple due to the potential loss or negative impact of the changes instead of the predictive positive impact one would otherwise hope a change might affect.

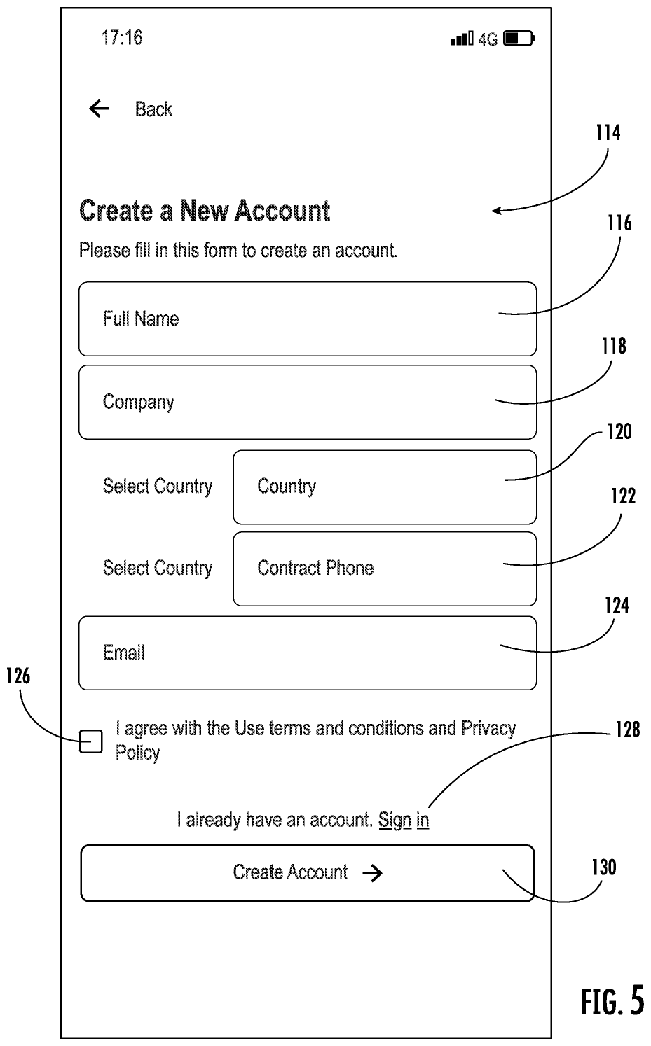

FIG. 4, shows an initial login display screen 100. The login screen will have a username or email data input field 102, a password input receiving field 104, which typically obscures the password as it is entered unless the password revealing user input link 106 is activated. The display also has a forgot password link, which initiates a password recovery or replacement process as is typically used in connection with mobile applications where an electronic mail message is provided to the user's electronic mail address on record. The electronic mail message has a link to replace the password. The initial login display screen 100 also typically has a login activation link 112 and a “sign up” link 110, which would cause the mobile computing device to display the graphical user interface shown in FIG. 5.

FIG. 5 is the user account creation display page 114. The data fields that are typically included and utilized to create an account include the user's full name 116, the user's company name 118, the user's country of residence 120, the user's phone number 122, and the user's email address. The display also typically includes a “create account” activation link 130 and a “sign in” link 128 that, when activated, reverts the mobile application back to the login screen shown in FIG. 4.

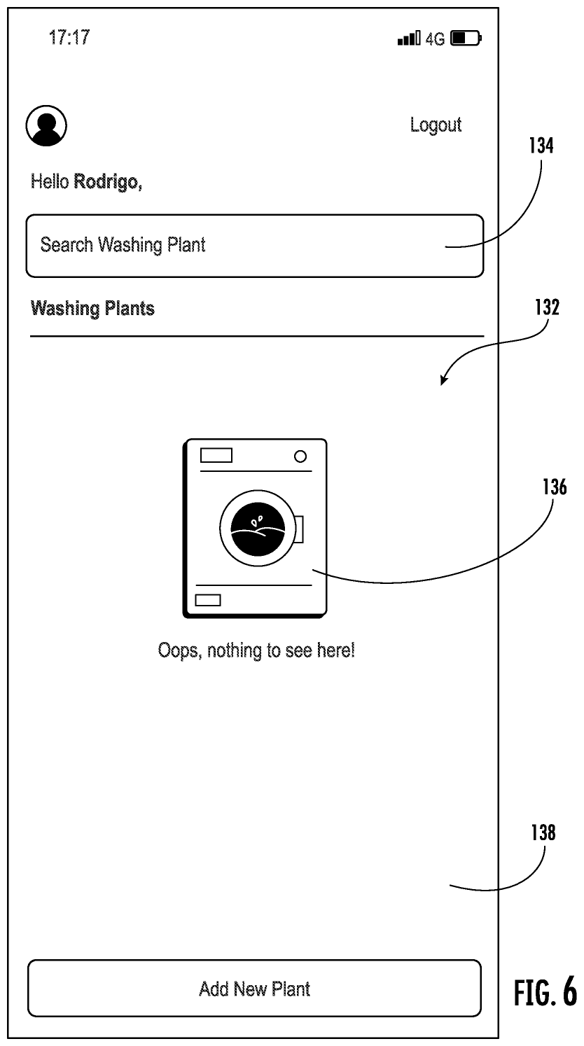

Once a user has created an account and logged into the mobile application, the main washing plant listing display is shown to the user as shown in FIG. 6. The main washing plant listing display 132 allows the user, in the case of the hypothetical shown in the Figures of the present application, Rodrigo, to search previously created washing plant systems using the search field 134. As shown in FIG. 6, the display will initially indicate that there are not previously established washing plants within the virtual laundry systems of the current user. This is done typically by the display of a graphic and/or textual indication 136. If the user would like to add a new virtual laundry washing plant that is either entirely hypothetical or a virtual approximate or replica of a current existing washing plant in the real world, the user would activate the “Add New Plan” link 138 typically located at the bottom of the main washing plant listing page of the mobile application shown in FIG. 6.

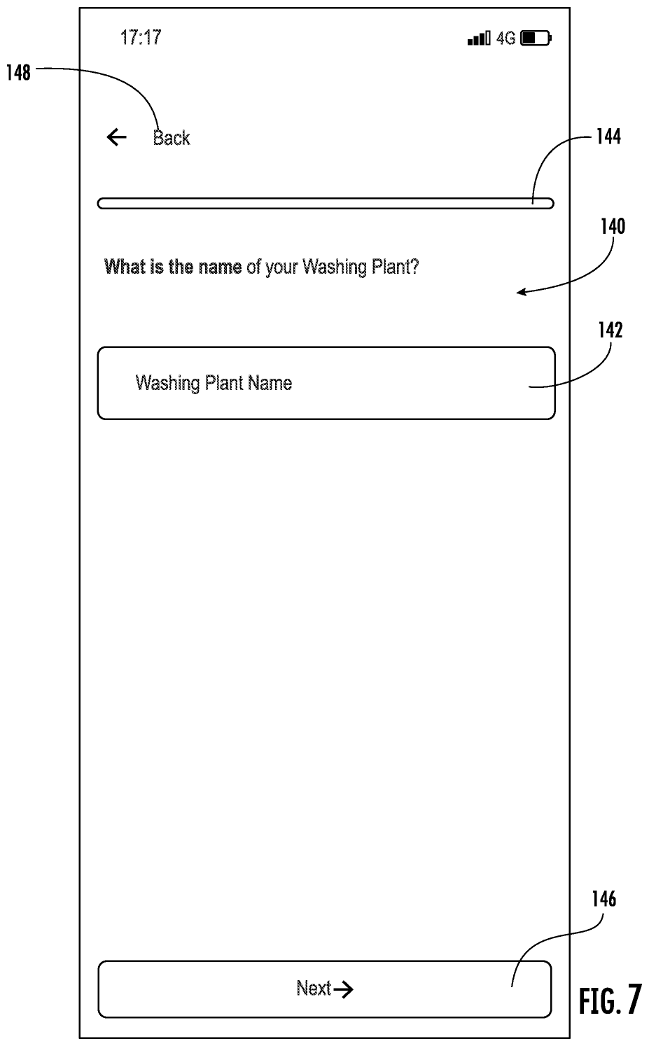

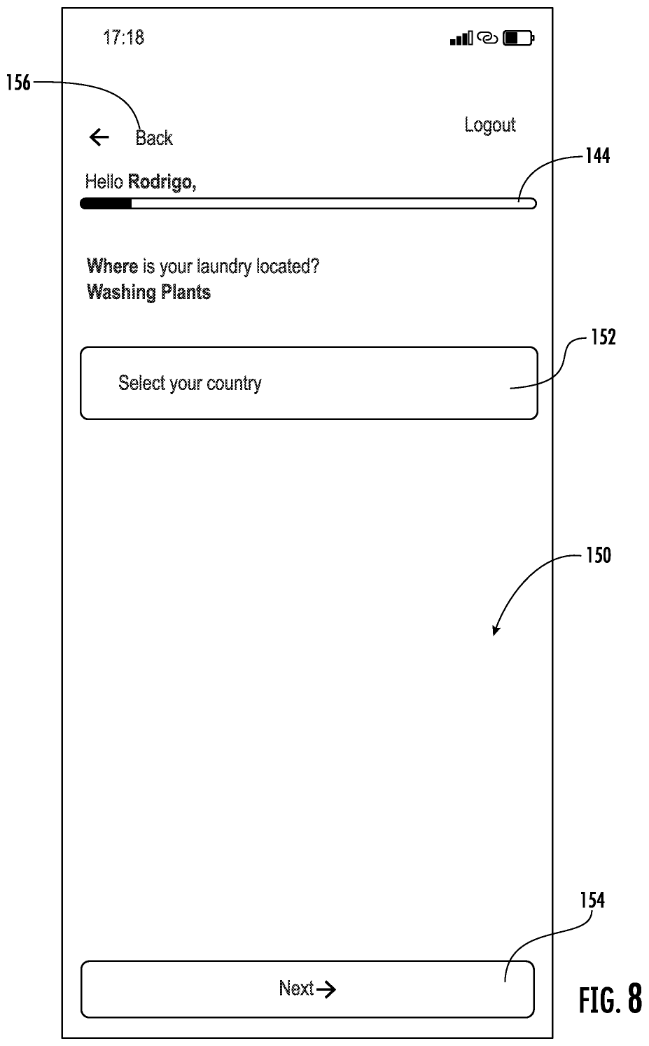

Activating the link 138 causes the systems of the present disclosure to display the washing plant creation naming user interface display 140 such as shown in FIG. 7. This is the first stage in establishing a new washing plant within the virtual laundry systems of the present disclosure. A user can enter a user-defined name within the naming field 142. The process of establishing the virtual washing plant is shown in the progress bar 144. Once a name for the washing plant is entered by the user into the field 142, the user can proceed to the next step in the process, the washing plant creation location input display shown in FIG. 8, by activating the “Next” link 146. Alternatively, there is a back link 148 to take one back to the previous display of the systems.

Once the washing plant creation location input display 150 of FIG. 8 is displayed, the user may enter the country where the washing plant will exist in the field 152. This may be a typed input field but for accuracy of data is more typically a selectable field of a predetermined set of countries, typically the countries where utility and other data used in the systems of the present disclosure and discussed above are readily accessible. Once the country is selected, the user activates the link 154 to move to the next step. If the user would like to move back a step, the user activates the “back” link 156.

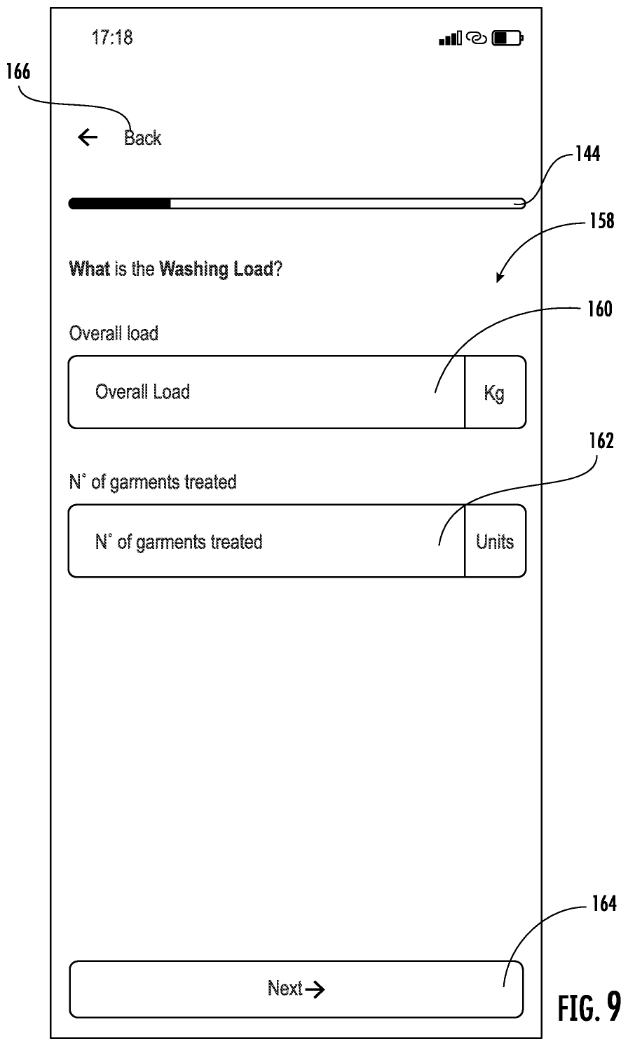

Once the country for the washing plant is entered and the link 154 activated, the systems of the present disclosure display the washing plant creation washing load data entry graphical user interface 158 shown in FIG. 9. On this screen, the user inserts the overall weight, typically in metric units, but any unit so long as it is standardized within the systems of the present disclosure may be user. The user inserts the weight into field 160. The user also typically inserts the number of garments that can be processed by the washing plant in the Number of garments treated field 162. As with other user interfaces in this process, the user may move to the next stage by activating the link 164 or moving to the previous display by activating the “Back” link 166.

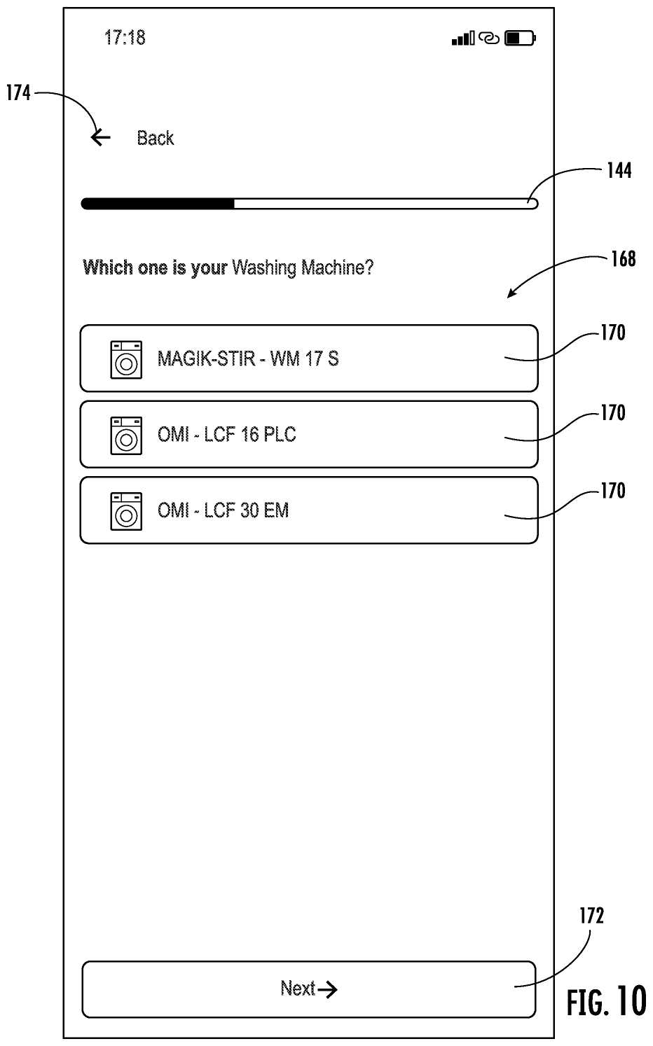

FIG. 10 shows a washing plant creation washing machine selection graphical user interface 168 of the present disclosure. At this point, the user will select from a listing of the possible washing machines 170 that may be added to the washing plant. Conceivably, washing machines may be added at this stage using the mobile computing device's camera to image the machine(s) and access a database of possible machines to be used in a washing plant based on machine vision, a barcode, a QR code or another identifier. Most typically, the user will simply need to select a machine or machines from the listing displayed for ease of use. The listing is typically as comprehensive as possible. Despite the fact that FIG. 10 shows three entries only, many more may be and are often displayed. Once the user selection has been made, the user will activate the link 172 to move to the next stage in the washing plant setup process. Again, the user may move back in the process by activating the “Back” link 174.

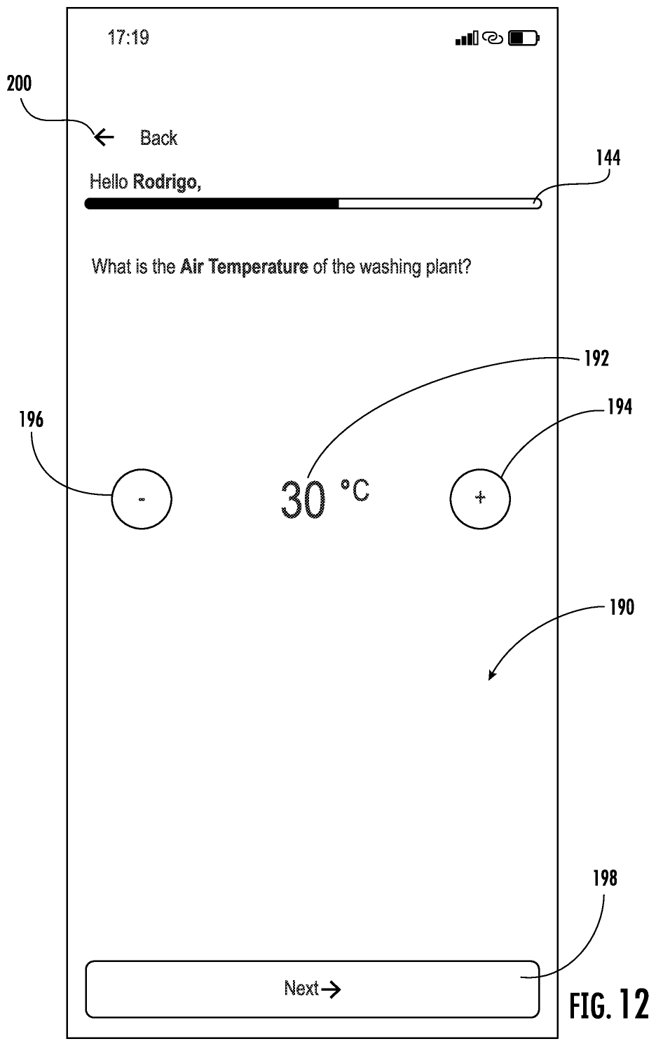

Once the link 172 is activated, the systems of the present disclosure will typically display the washing plant creation feed water temperature input graphical user interface 176 for a selected washing machine on the previous display of the present disclosure. In the example shown, the selected washing machine 184 is the MAGIK-STIR—WM 17 S. The input received by the user is the temperature of the feed water 178. The figure may be adjusted using the increasing input location 180 and the decreasing input location 182 to raise and lower the set temperature for the feed water temperature. Once the feed water temperature is set, the user of the systems of the present disclosure activates the link 186 to cause the air temperature input page, FIG. 12, to be displayed. As was the case with other interfaces, a user can also move backward in the setup process by activating the link 188.

FIG. 12 shows the washing plant creation air temperature input graphical user interface 190. Using this interface, a user sets the air temperature 192 of the washing plant. The air temperature 192 may be set using the positive link 194 to increase the air temperature 192 and/or the negative link 196 to decrease the air temperature. Once the correct air temperature is set, the user moves to the next step in the process by activating the link 198 or may move backward using link 200.

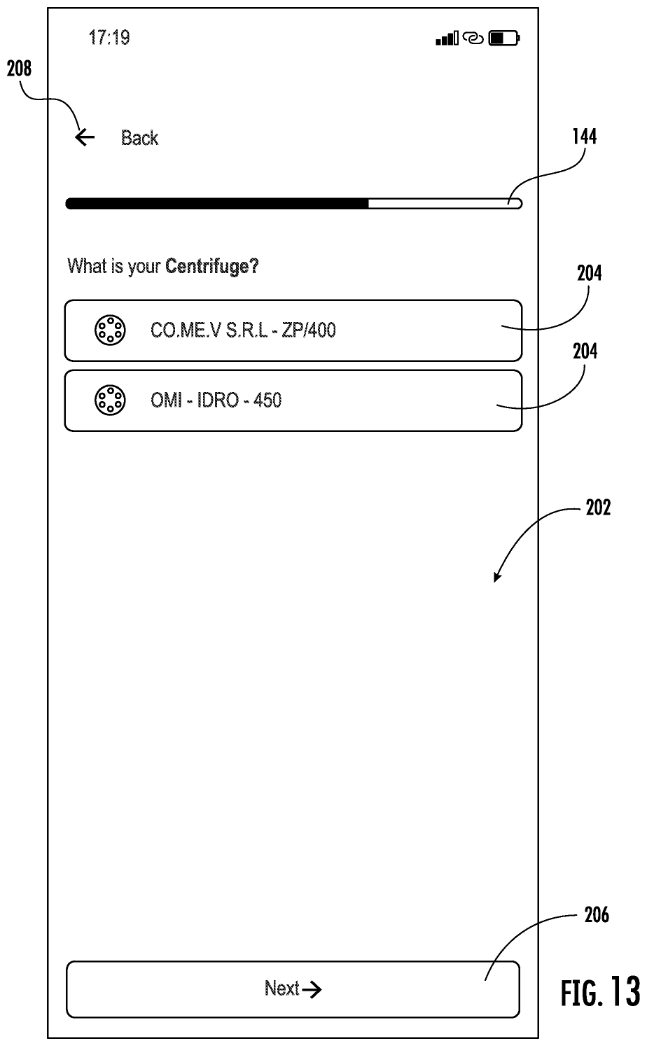

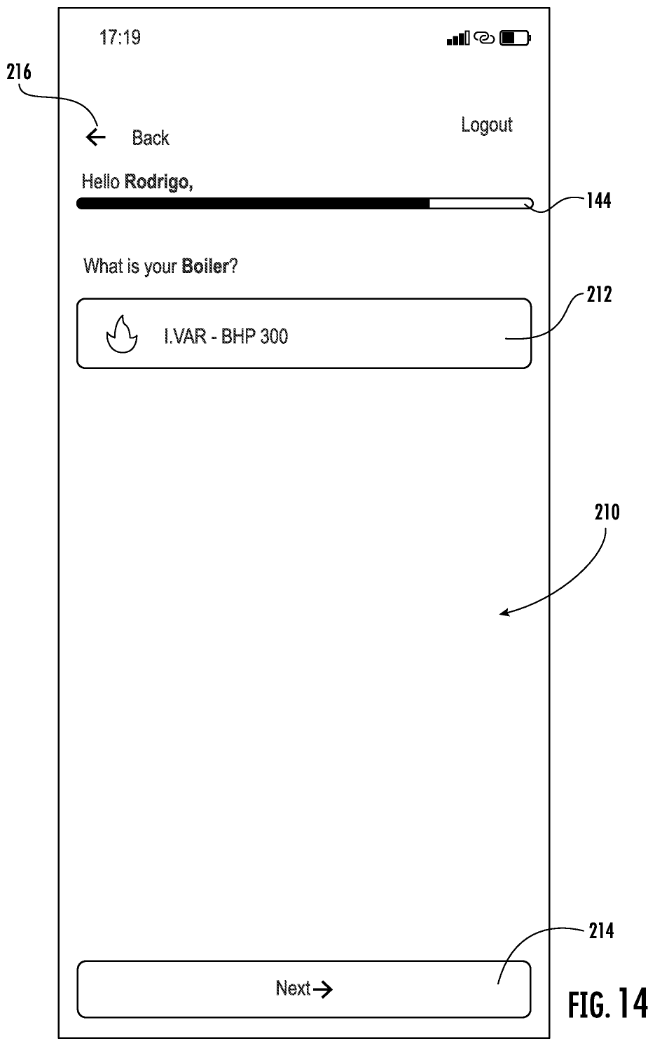

Once link 198 is activated after the air temperature of the washing plant is set, the systems of the present disclosure display the centrifuge selection graphical user interface 202, FIG. 13. The user may then select the centrifuge(s) 204 used in the washing plant being created. Once the user selects the centrifuge(s) to be included in the washing plant, the user moves to the next stage by activating the link 206, which causes the boiler selection display 210 of FIG. 14 to be displayed to the user. The user may move backward in the process by selecting the link 208 to return to the display shown in FIG. 12.

Once the user arrives at the boiler selection screen 210 of FIG. 14, the user selects from a list of boilers to be added to the washing plant being created. While a single boiler is shown in FIG. 14, a plurality of possible boilers may be selected. The listing of possible boilers as well as the possible washing machines, centrifuges and other hardware are typically limited to only those already owned by or accessible or use or purchase by the user in an actual real world laundry, but could be conceivably any possible boiler that might be implemented. Once the boiler 212 is selected, the user may move to the next stage by activating the link 214 or moving backward in the process by activating the link 216.

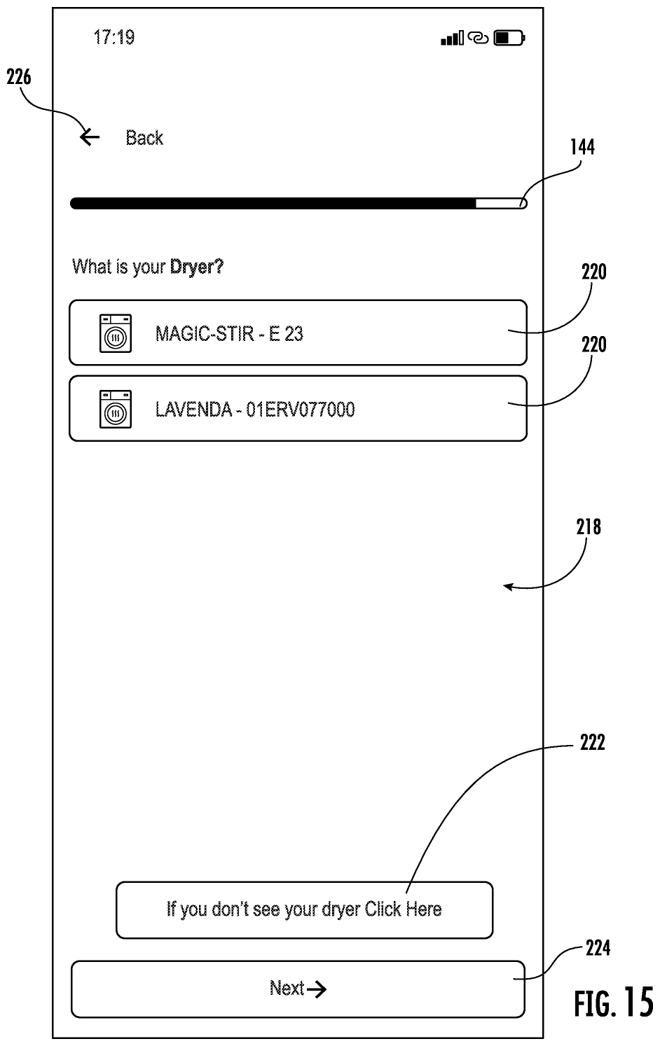

FIG. 15 shows a graphic user interface for the selection of a dryer for the washing plant being created by the user within the virtual laundry. This provides the user with the ability to select the dryer 220 of the virtual laundry from a list. If the dryer is not shown, there may be a link that allows one to add a drying for selection to the listing. That link 22 may be labeled something like “if you don't see your dryer click here”. Activation of the link may access a self-contained or external database listing of possible dryers. Once the dryer to be added to the system is selected by the user, the user may select the link 224 to proceed to the next stage or the link 226 to proceed back to the interface shown in FIG. 14.

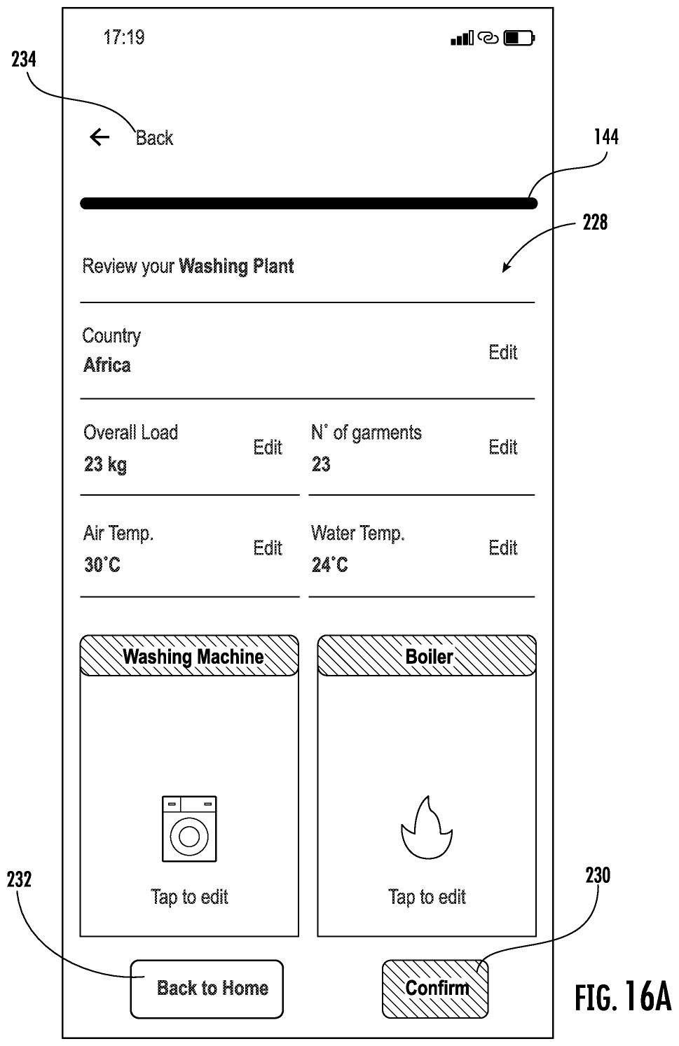

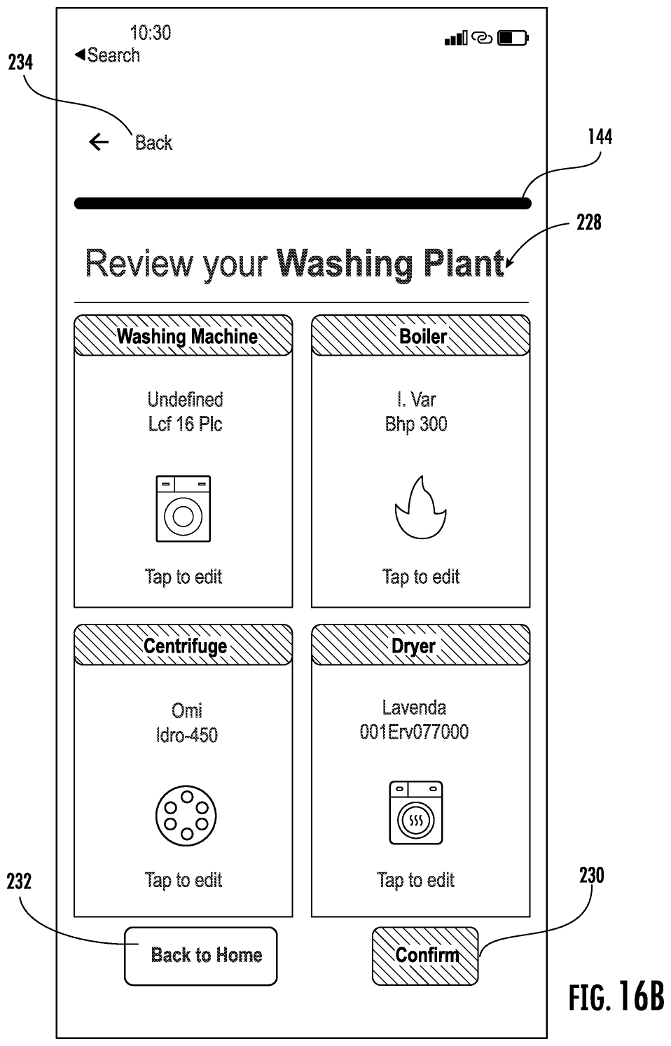

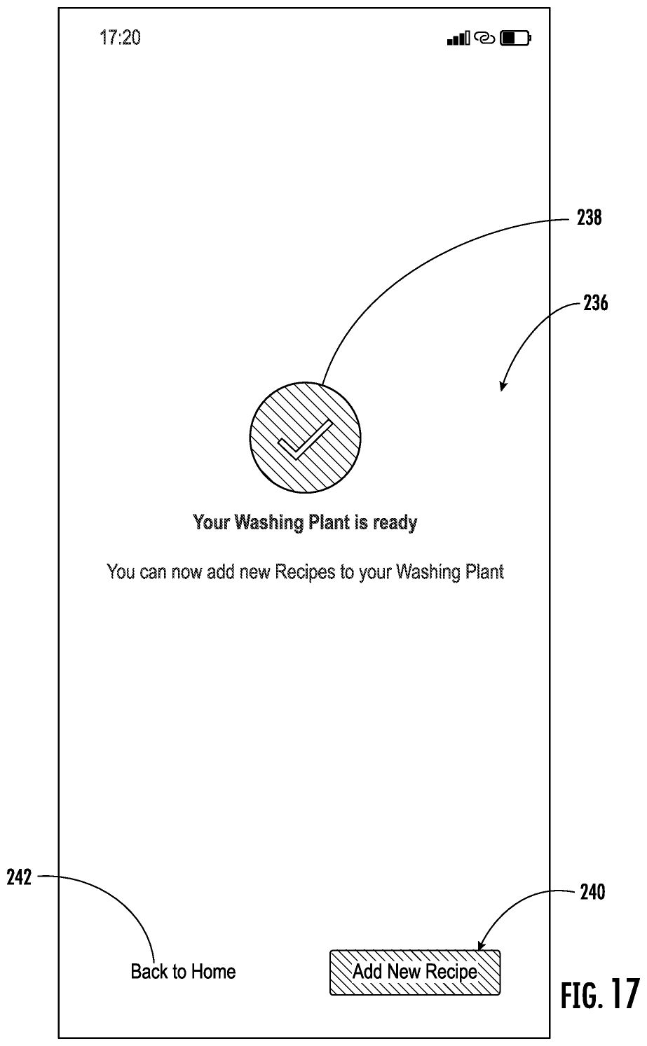

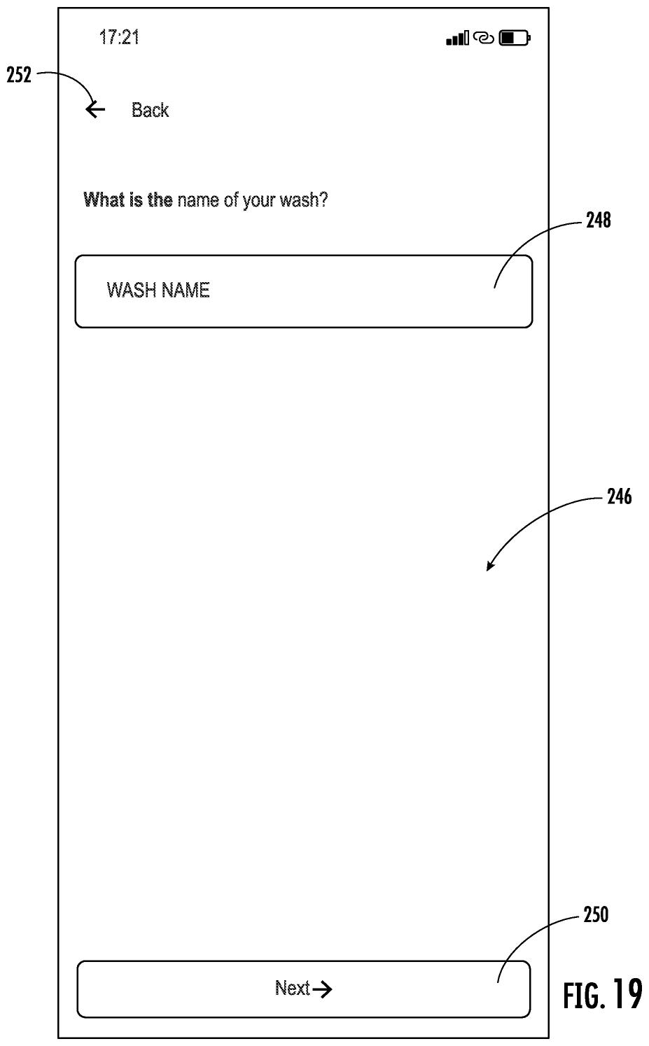

FIG. 16 shows a typical graphical user interface of a final overview of the washing plant 228. This review display will provide each of the pieces of data provided by the user through the washing plant setup process. If the user doesn't find the right parameters for its plant (ex: the right machine), the user of the systems of the present disclosure may have the possibility to ask (through the activation of a link in the mobile application) for the inclusion of a plant machine, which would launch one or more input screens to be displayed to offer a selection of machines for possible inclusion and/or the manual addition of the machine and typically also including the performance features of the machine to allow for robust review of the machine's impact when it is included in any future recipe/process within the textile processing/virtual laundry simulator systems of the present disclosure. If the information displayed related the location, load, number of garments, air temperature, water temperature of the intake water, the washing machine, the centrifuge, the dryer, the boiler, and any other equipment or information provided by the user is verified, the user may select and activate the “confirm” link 230 to finish the process or the “Back to Home” link 234 to start the entire process over again. Of course, the user may select link 234 to move one screen backward in the process to the dryer selection interface. Once the confirmation has been made by the user in activating the link 230, the user is brought to the finishing page 236 shown in FIG. 17. The finishing page 236 will typically contain a prominent display of successful completion of the washing plant setup process 238, which is shown in FIG. 17 as a large check mark, but other confirmation display could conceivably be used. At this stage, the user may return to the home screen display by activating link 242 or proceed to add a recipe to the virtual laundry being set up by the user for the washing plant created by activating link 240, which causes the mobile computing systems of the present disclosure to display the graphical user interface shown in FIG. 19.

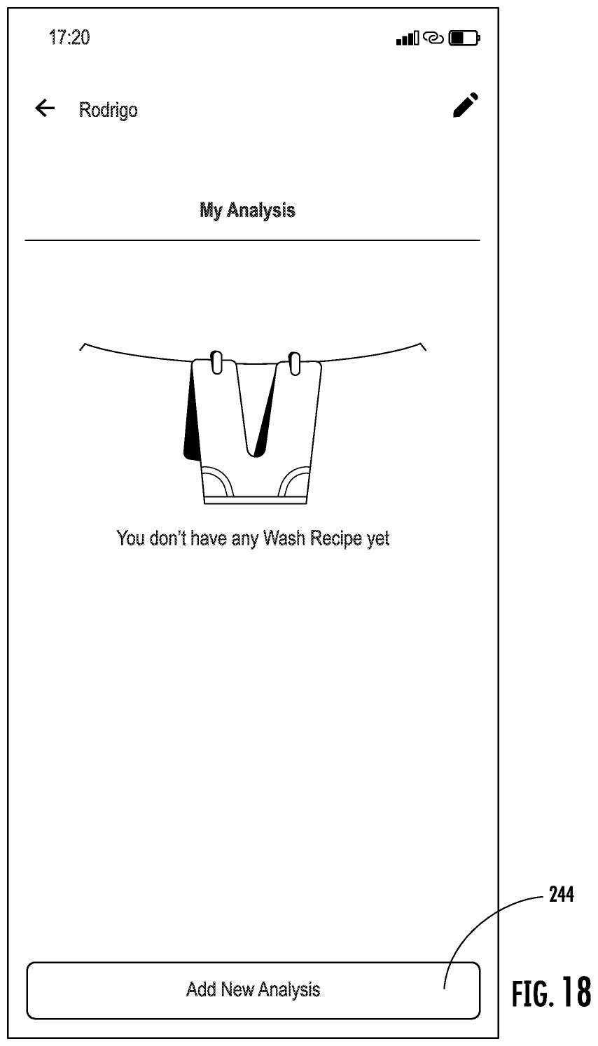

The systems of the present disclosure also typically have the ability to analyze the washing plants and recipes, but a recipe must be created before it may be analyzed. The lack of a recipe may be shown to the user in a graphical user interface such as that shown in the initial recipe setup display in FIG. 18.

Once the user activates the link 244 the system will prompt the user to input the name of the wash cycle/recipe being created using the recipe naming display interface 246, FIG. 19. This interface typically has a user input naming field 248 where the user may type or otherwise enter the name of the recipe or the wash being created. Once the name has been entered into the field 248, the user may proceed by activating link 250 or proceeding backward using the link 252.

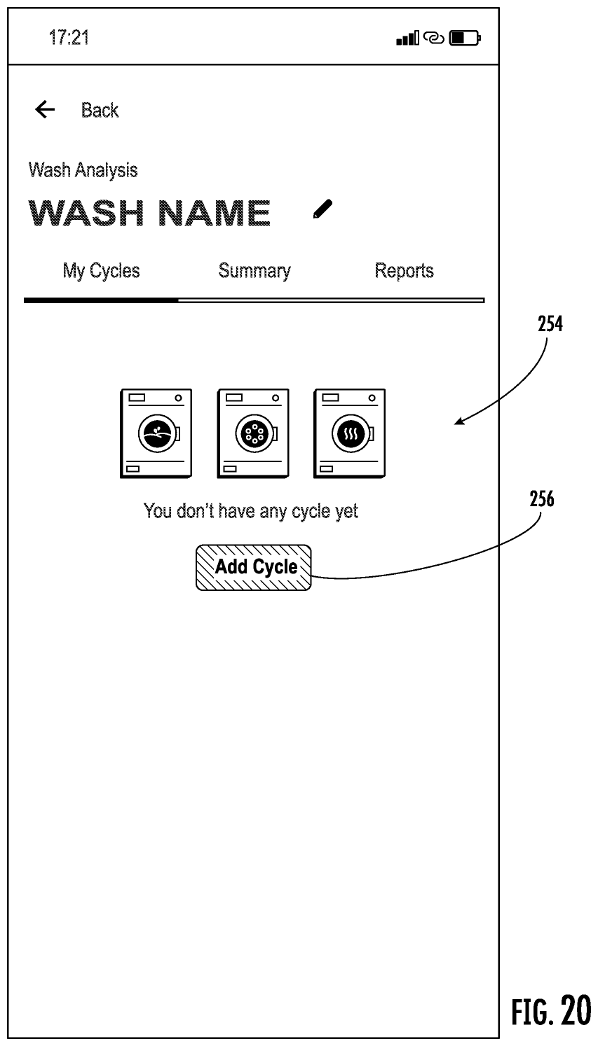

The next step in the process is shown in the wash recipe cycle selection and review display and interface 254 shown in FIG. 20. This page is the initial display after naming the wash recipe being created. By swiping right, a summary may be viewed, or reports generated as well. At this initial stage, where no washing cycle recipes have been generated by the user, the system displays that status along with an “Add Cycle” link 256.

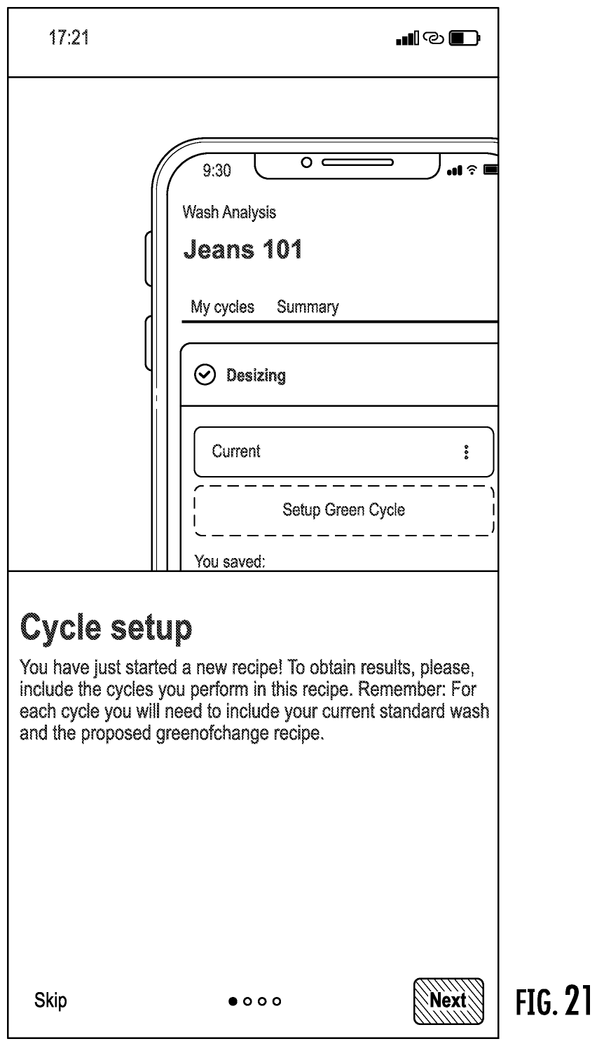

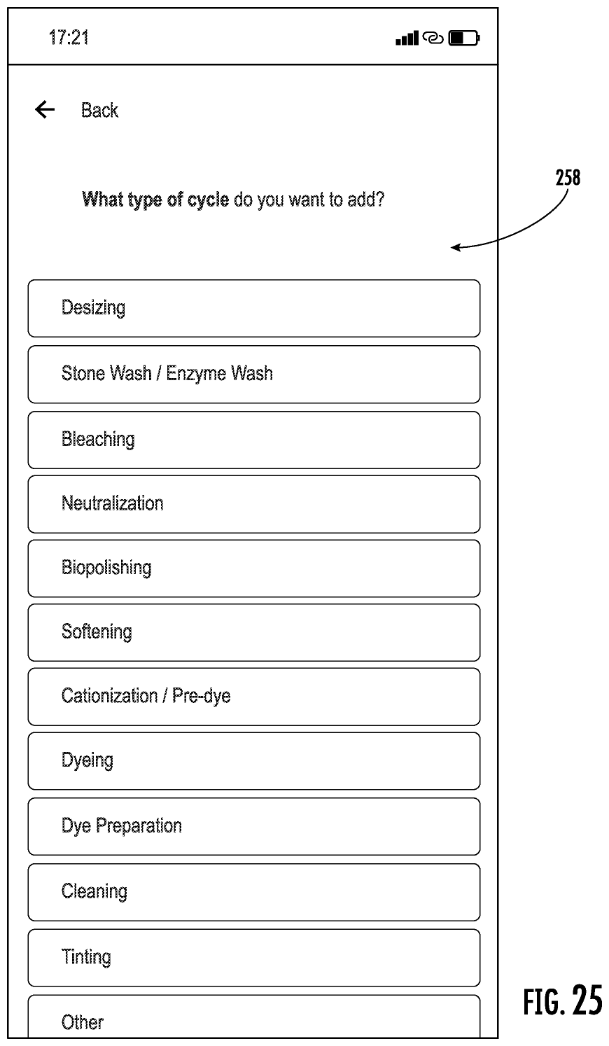

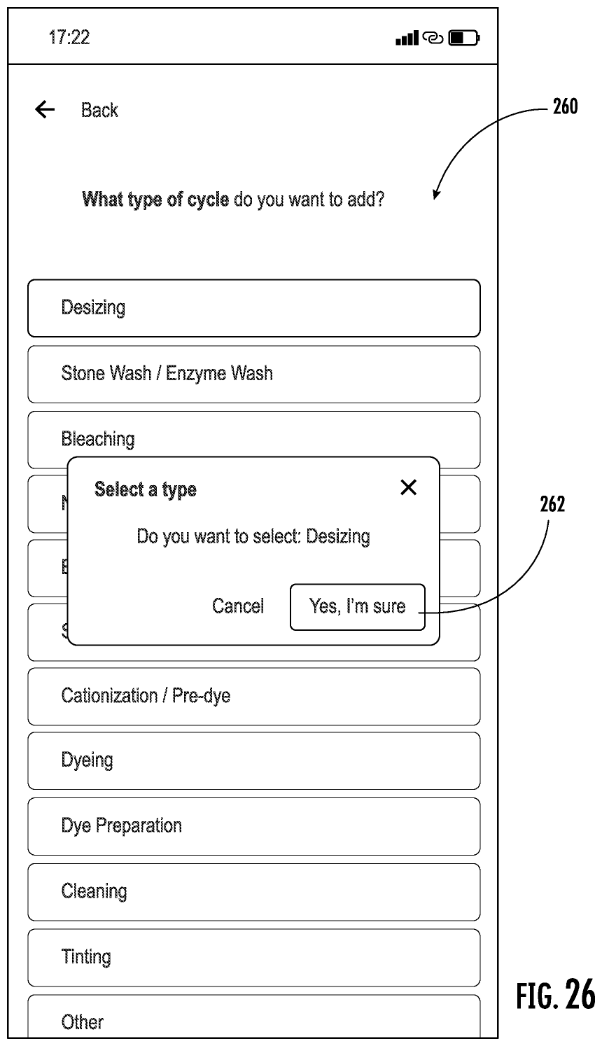

The activation of the “Add Cycle” link 256 will typically activate a tutorial for the cycle setup and creation process as shown in FIGS. 21-24. The user may skip this tutorial by activating the skip link in the initial stages of the process. Once skipped or completed, the display to select the type of cycle being created is provided to the user, see, for example, FIG. 25. The wash recipe cycle selection display 258 typically displays a plurality of different types of cycles. The user may select any one or them or create their own by selecting an “other” input if their desired cycle is not shown. In the example shown in the Figures, the user selects initially the cycle of desizing. Once selected, the system of the present disclosure typically asks the user for confirmation of the selection as shown in the confirmation of selection graphical user interface 260 of FIG. 26. The user may do so simply by activating the confirmation link 262.

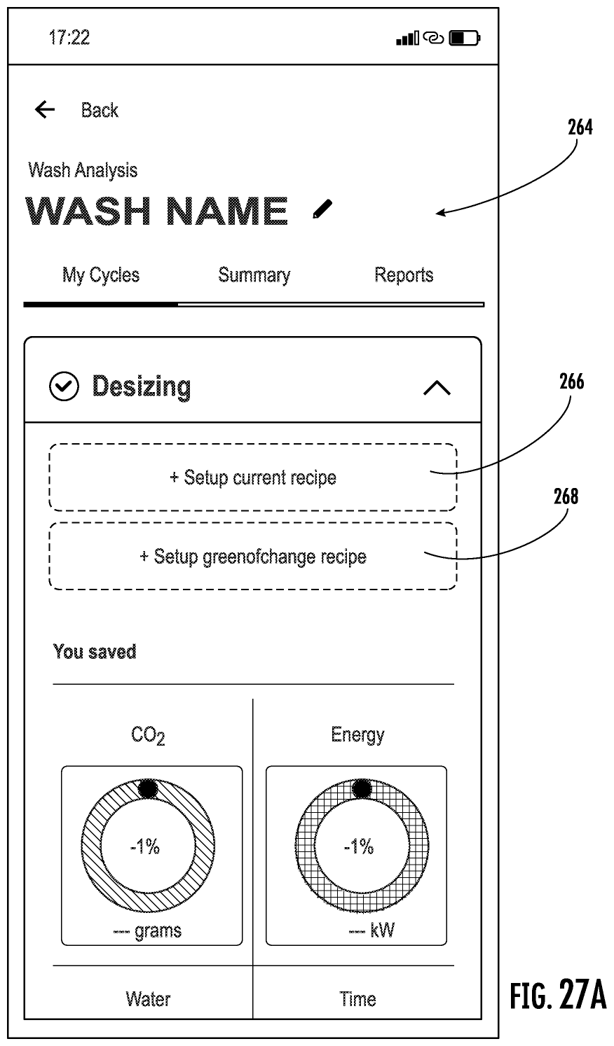

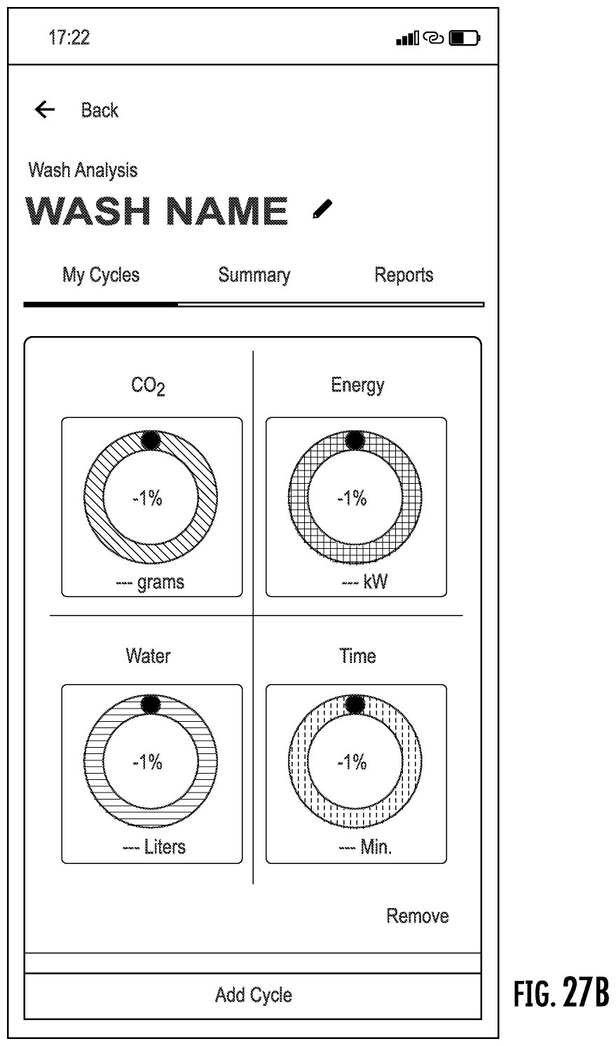

Once confirmed, the system displays an initial cycle summary page 264, FIG. 27A-27B. Here, the system displays the comparative results between a “current recipe” when it is created by activating the link 266 and when a different potentially more sustainable recipe is created by activating link 268. The various comparative results of the changes in the processes are summarized and provided in a variety of ways. On this summary display, the system typically shows the changes and benefits or detriments of the changes in at least the carbon dioxide consumption, the energy usage, water usage, and time. These results are typically displayed in a color coded manner with a circular graphical display of the changes in addition to the numerical information on the level of change. The carbon dioxide is typically displayed in a green color, the energy in yellow, the water usage in blue and time in purple, but any colors or user identifiable notations may be employed.

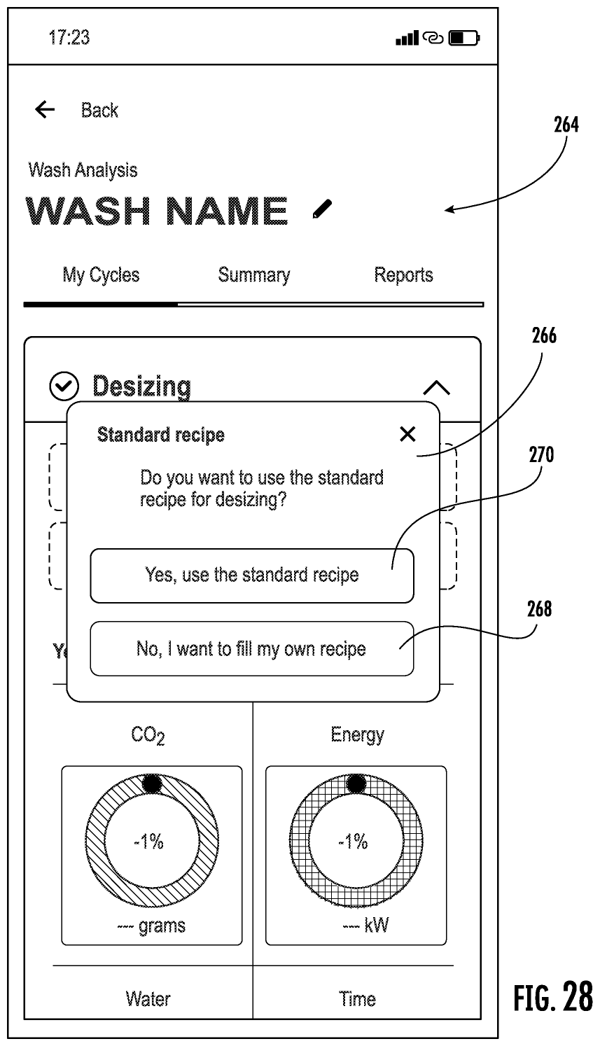

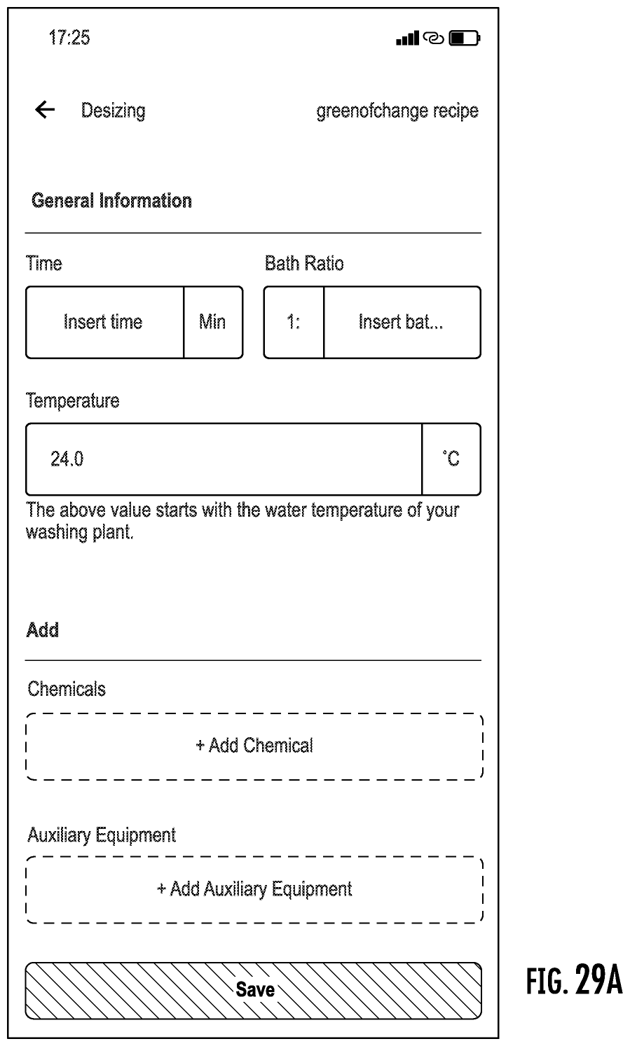

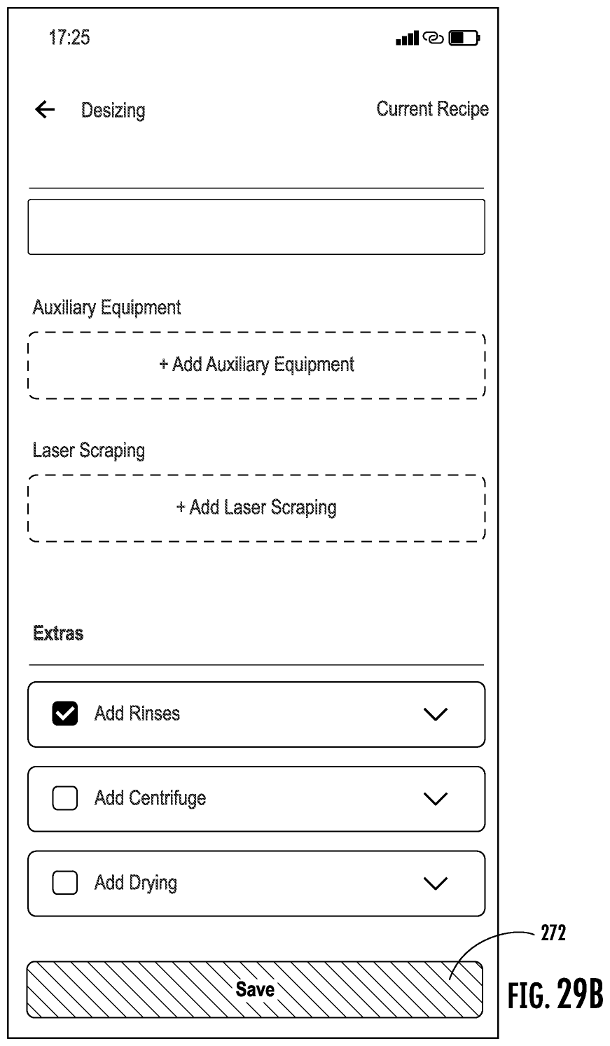

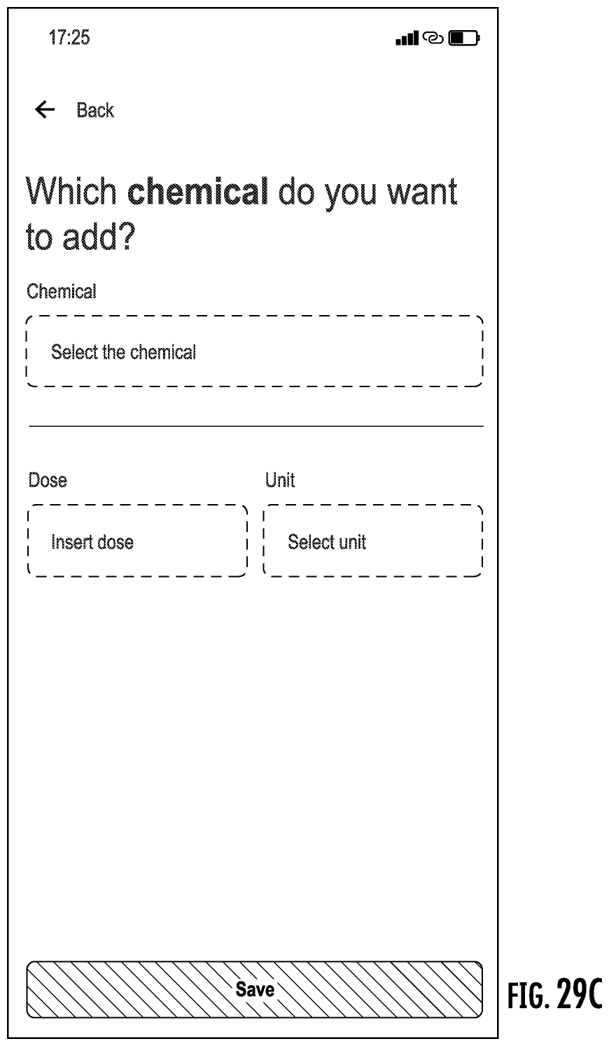

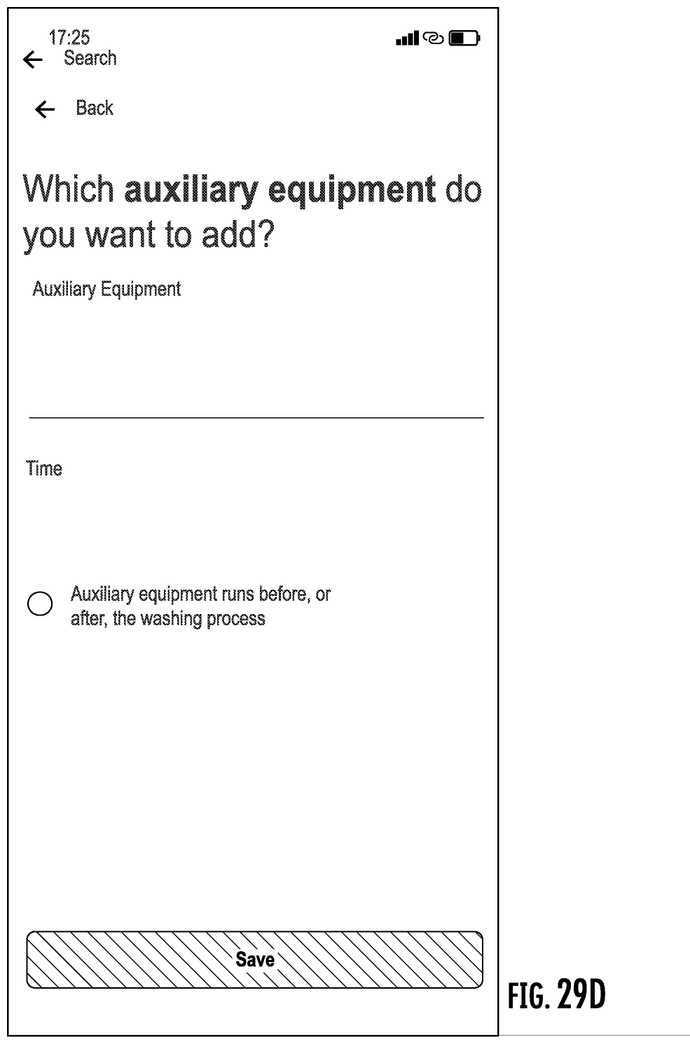

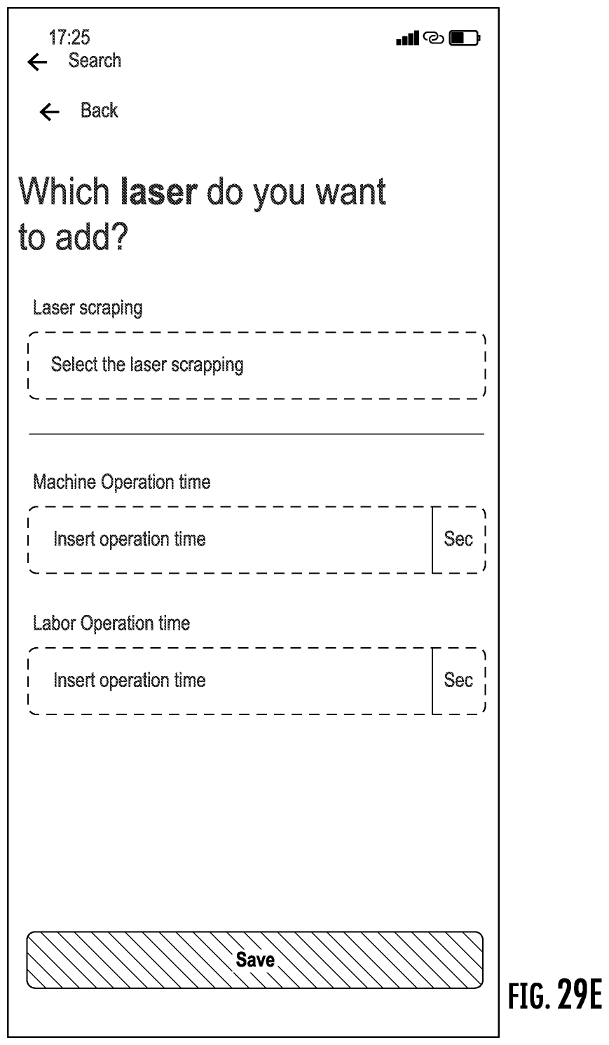

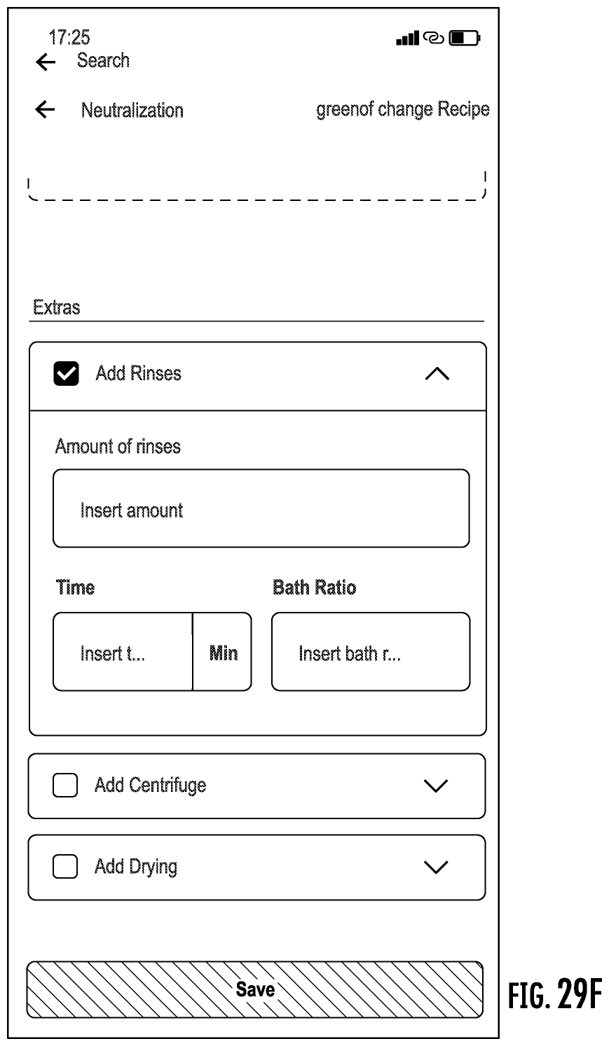

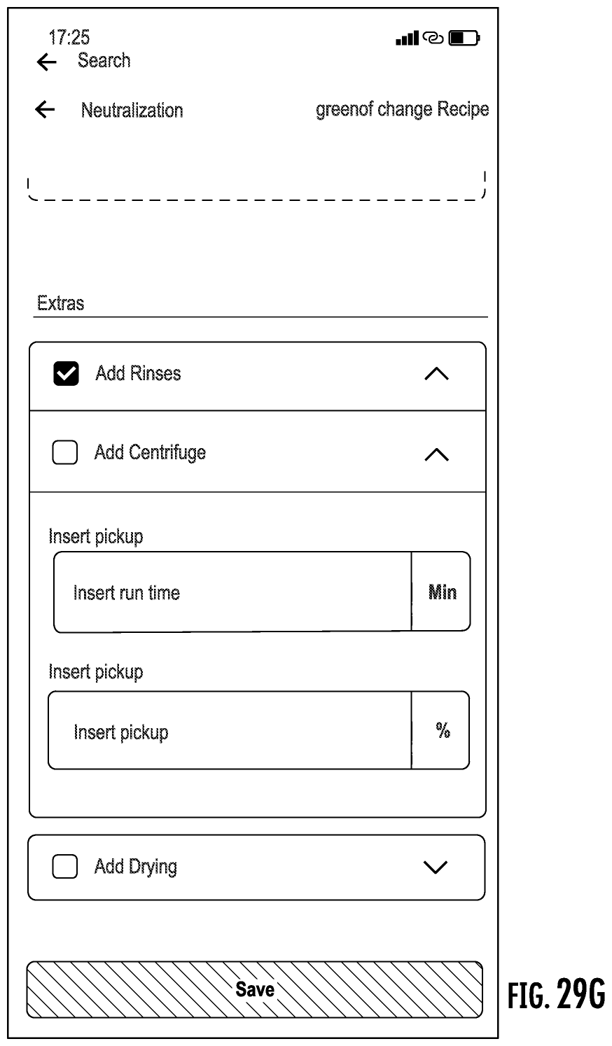

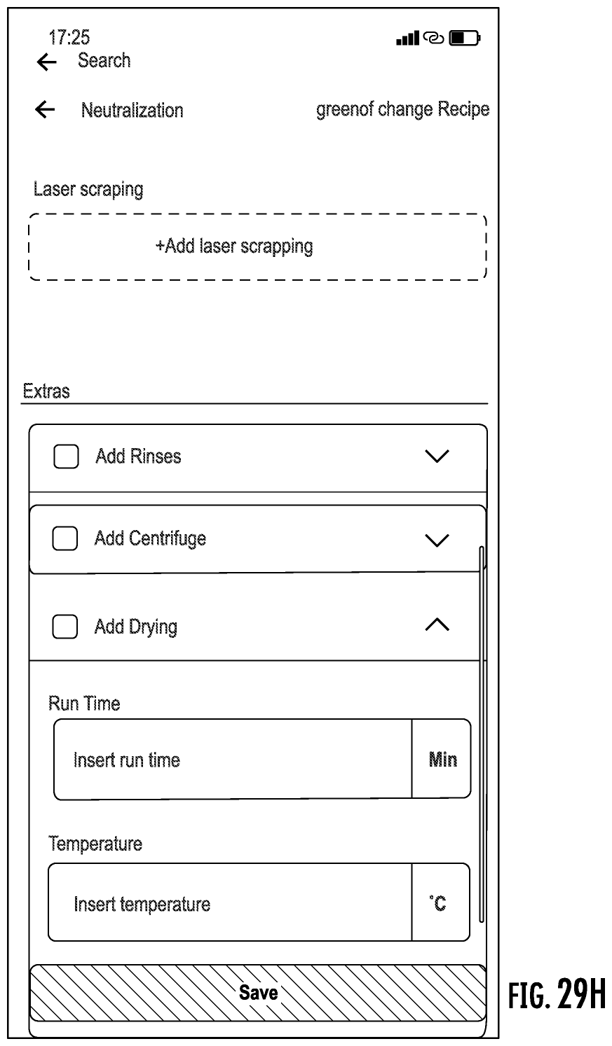

Activation of the link 266 prompts an initial user input request 266 shown in FIG. 28. This asks the user if the user would like to input the details of the particular recipe of their own that would typically be an image/replica in the virtual laundry of a real world laundry by activating the link 268 or use the data and details from an industry standard recipe for the cycle being constructed by activating the link 270. After activating the link 268, a general information data input page such as the one shown in FIGS. 29A-29B, is displayed to the user. The current recipe information related to time and bath ratio, in this example, or other data entry fields for general information, the nature of any chemical(s) used, any auxiliary equipment, laser scraping technology and systems, and other information related to the rinses, centrifuge, and drying employed in the cycle. Once all the relevant data for the cycle is added the user activates the link 272 to save the information in the databases of the computer server systems of the present disclosure.

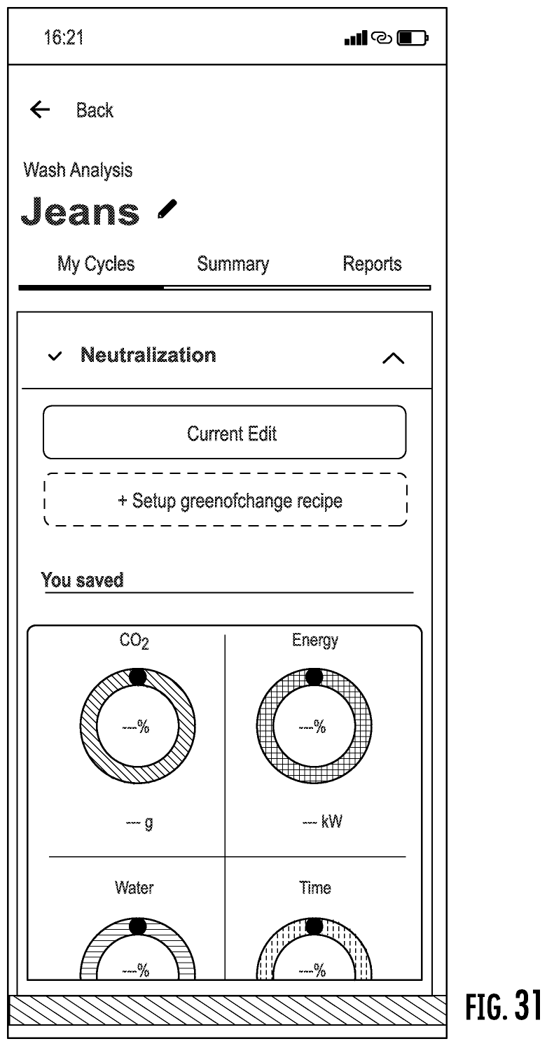

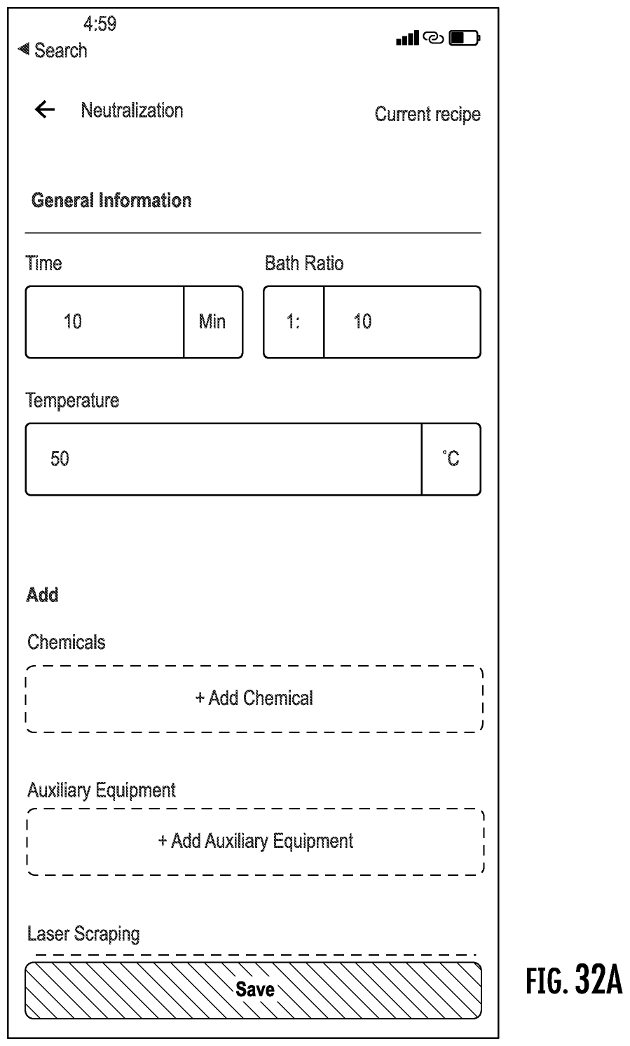

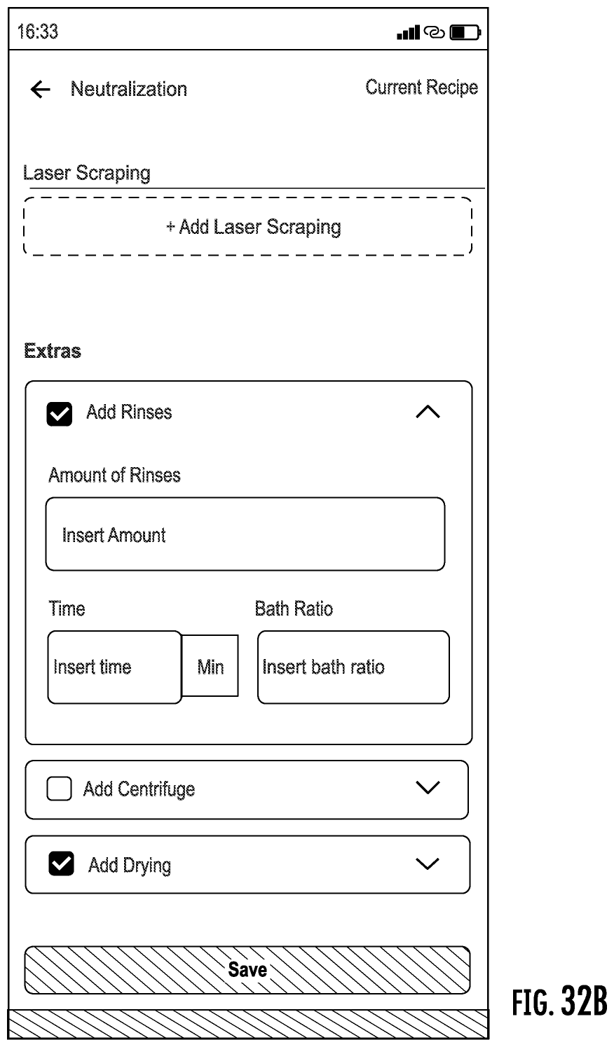

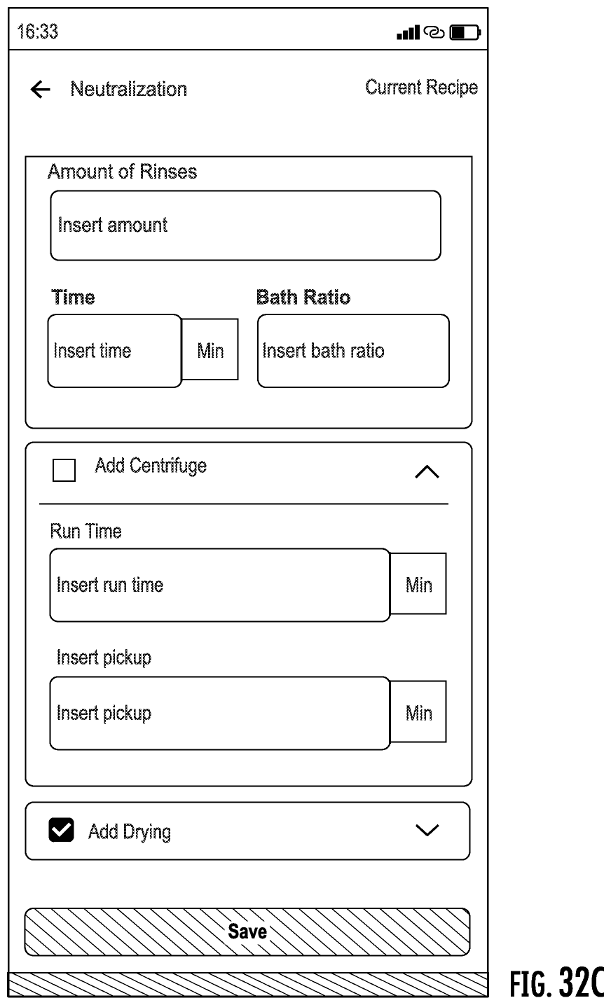

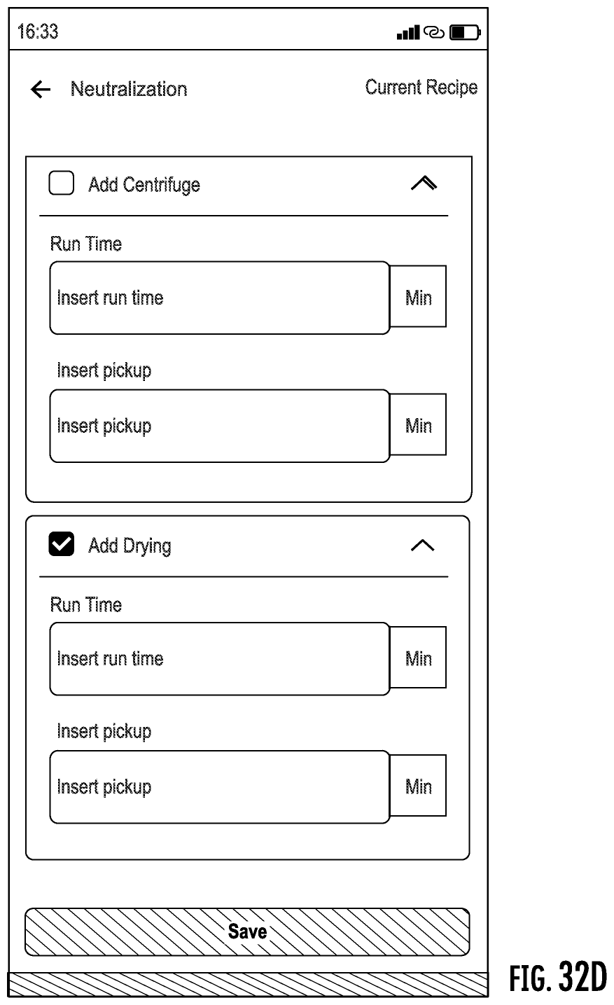

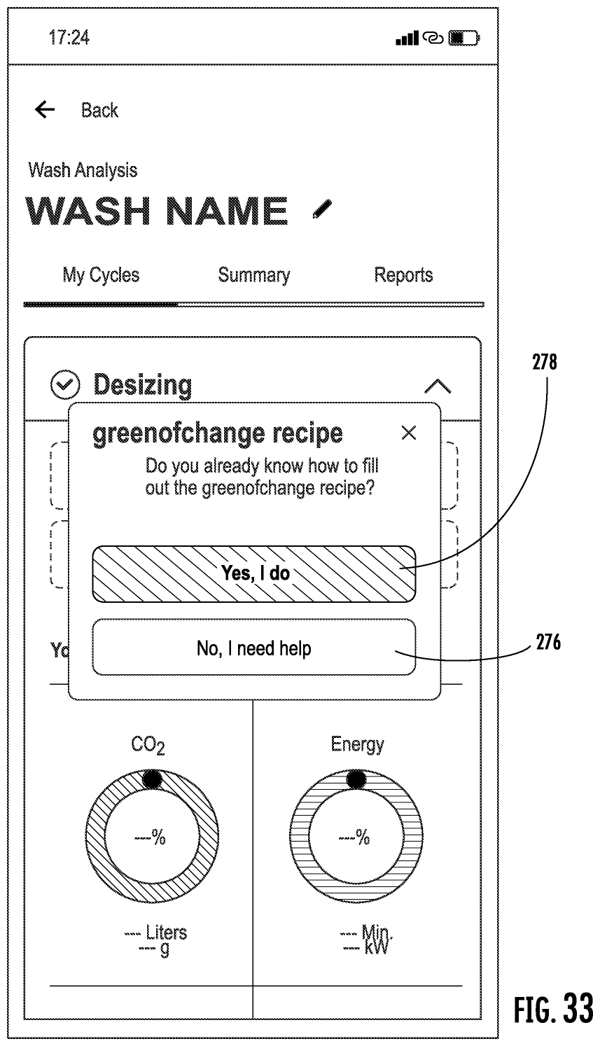

Once the data for the custom recipe is entered and saved, the user is brought back to a summary display that would eventually show the changes and comparative differences between the current recipe and the potentially more sustainable alternative once created. Activating the add cycle link 274 returns the user to the graphical user interface shown in FIG. 25. The user may then select another cycle such as that shown in FIGS. 31-32D, which is a neutralization cycle/recipe. Similar data entry opportunities are presented for the user, but the data requested is typically customized to the nature of the recipe for the cycle being employed such that specific data relevant to the cycle is requested. Once the data is entered and saved the user is again returned to a summary page such as that shown in FIG. 33. It may also be possible to show the results in a scale. For example, the system may display the results on a scale of results such as: A+++, A++, A+, B, C, D, E . . . or a color graded scale from red (bad) to green (good) for the results of the various recipes. The scale could also be a scale that is numeric with a number 0-10 scale (1=very harmful and unsustainable to 10=very sustainable).

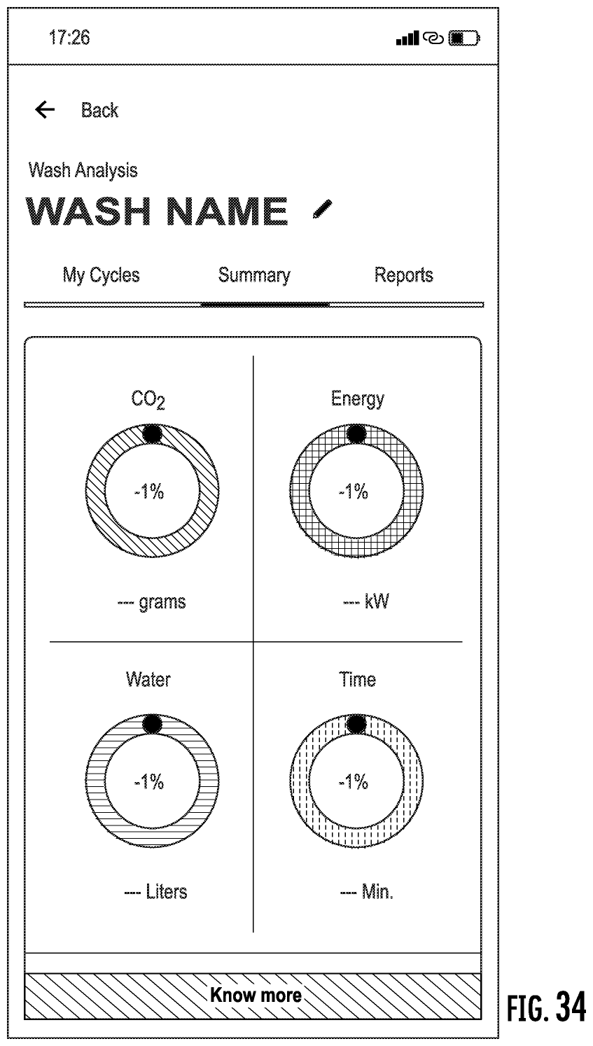

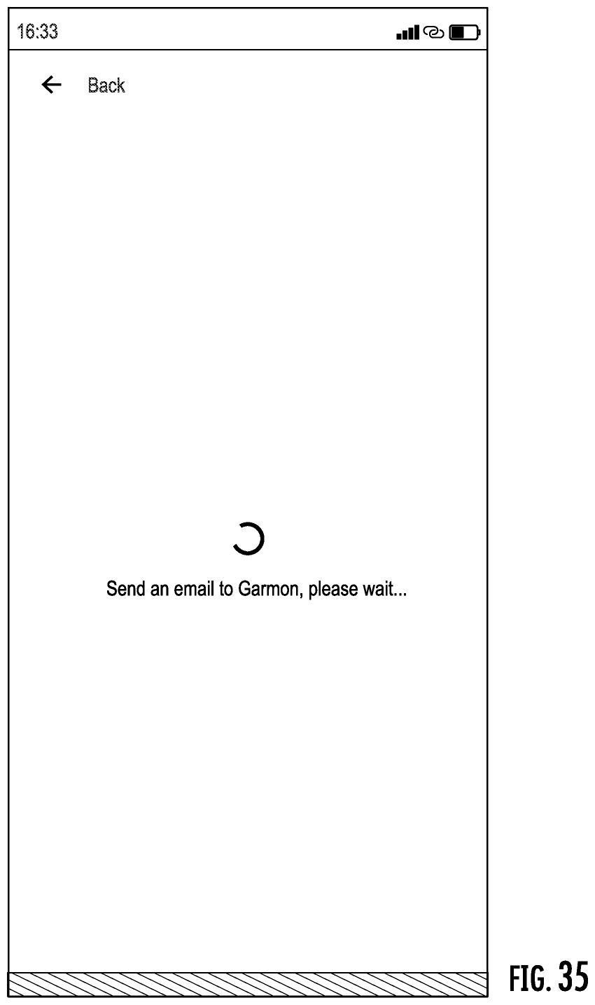

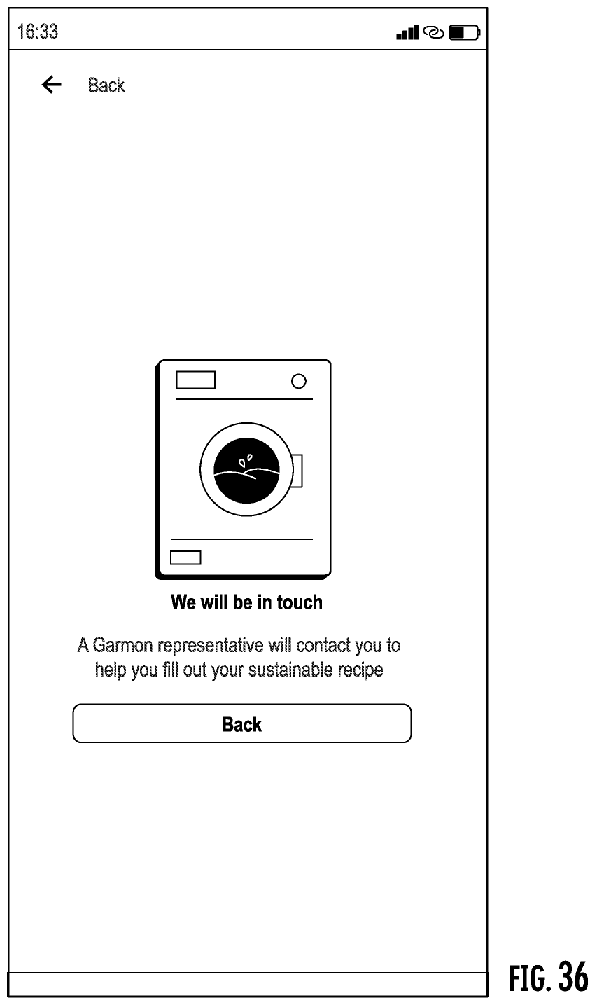

As shown in FIG. 34, to established a proposed and potentially more financially and/or environmentally friendly cycle recipe, the user will activate the link 268 of FIG. 27A. This presents the prompts shown in FIG. 34. As shown in the displays to the user in FIGS. 35-36, if the user indicates that they do not know how to fill out a proposed more financially and/or environmentally friendly cycle recipe by activating link 276, the systems of the present disclosure will automatically send an email to the administrator(s) of the virtual laundry computing systems of the present disclosure or complete a prompt to the administrators to contact the user based on the user data in the user's profile. Thereafter, the administrator(s) can proactively communication either via electronic mail correspondence, phone or other means of communication to teach the user how to complete a proposed and potentially more financially and/or environmentally friendly cycle recipe.

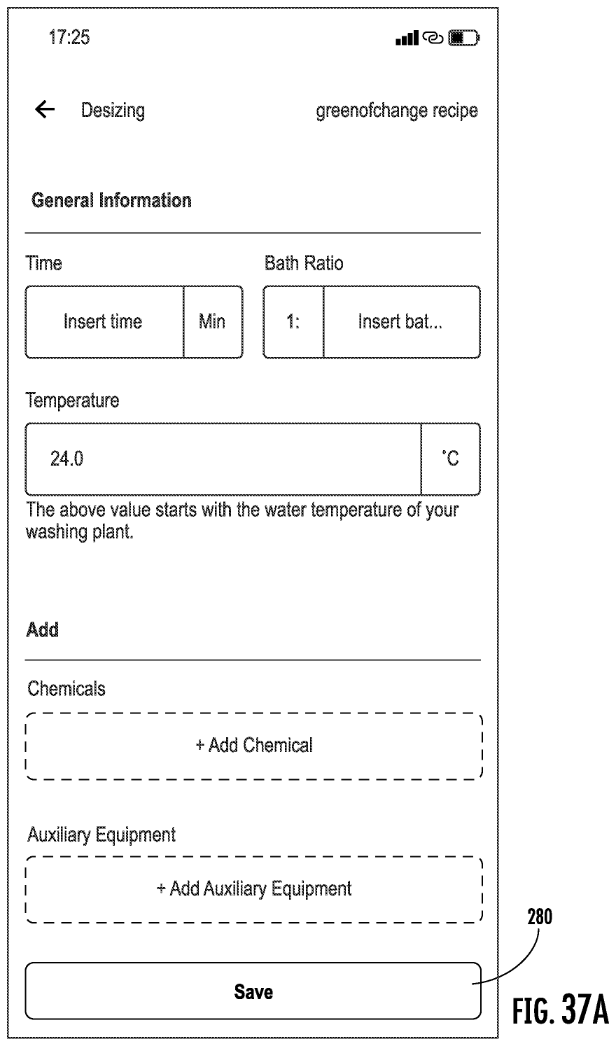

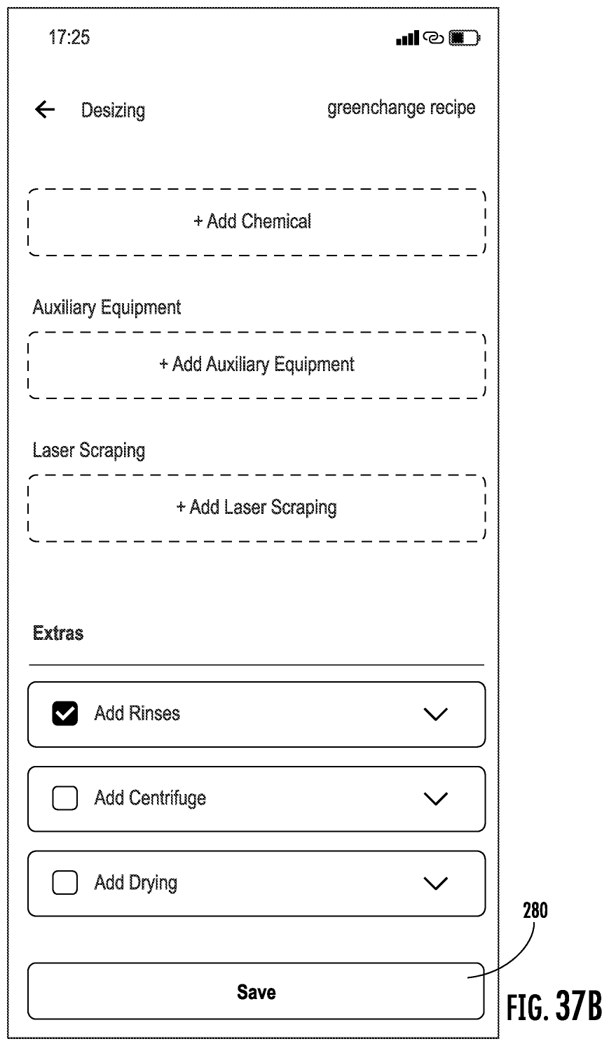

If instead the user activates link 278 in FIG. 34, the system will prompt the user to go through a series of graphical user interfaces to create the proposed and potentially more financially and/or environmentally friendly cycle recipe. As shown in FIGS. 37A-37B, the system will prompt the user for similar information as the current recipe, but for the proposed and potentially more financially and/or environmentally friendly cycle recipe. Once the data of the proposed and potentially more financially and/or environmentally friendly cycle recipe is provided by the user in the input fields shown in FIGS. 37A-37B, which are different sections of the same graphic user interface that are accessed typically by swiping downward on the touch sensitive display or otherwise scrolling down, the user activates the “Save” link 280.

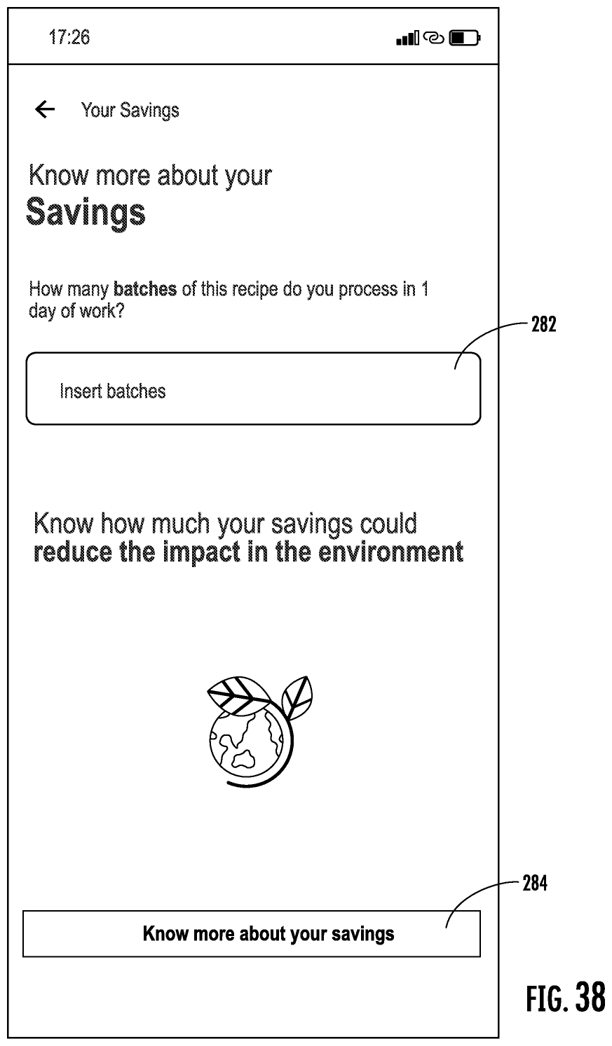

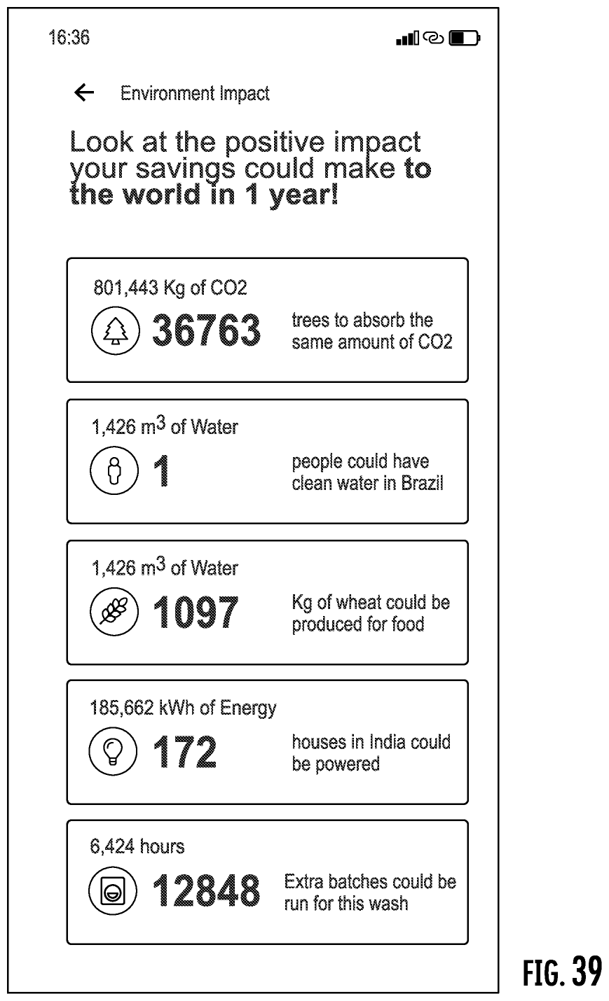

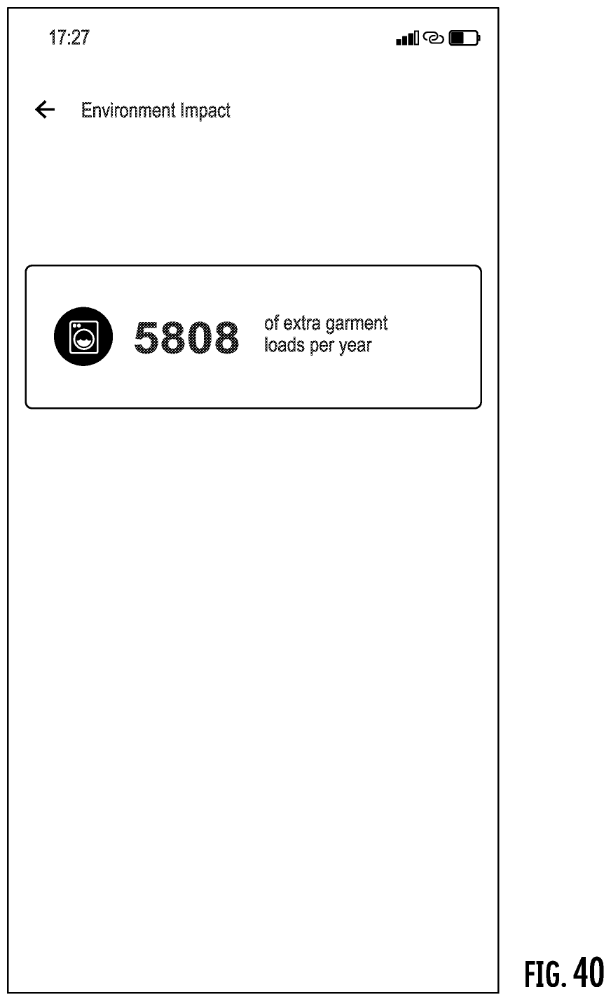

Next, to provide the user with more information about the savings they may see if the proposed and potentially more financially and/or environmentally friendly cycle recipe were to be implemented versus a current recipe being employed by the user in their real world laundry and replicated in the virtual laundry systems of the present disclosure, the system will inquire about the number of batches a given recipe is done in one day of work as shown in FIG. 38. This data is typically manually entered in a data entry field 282. Once this data is provided, the user may activate link 284, which shows detailed environmental impact of the changes, such as those shown in FIGS. 39-40.

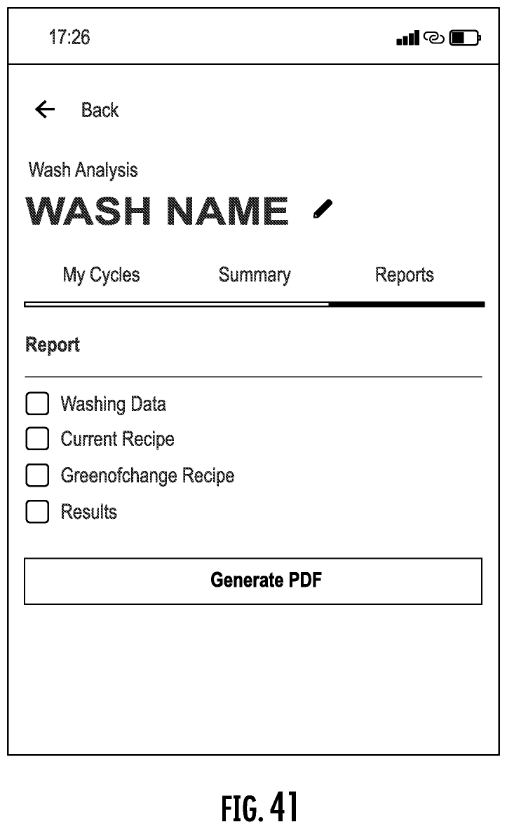

The systems of the present disclosure may also provide reports through the main summary page when the display is swiped or scrolled to the appropriate portion of the display such as shown in FIG. 41. The reports generate PDF documents related to the washing data, the current recipe inputted by the user, the proposed and potentially more financially and/or environmentally friendly cycle recipe, and/or the results of the comparison between the current recipe for the washing plant and the proposed and potentially more financially and/or environmentally friendly cycle recipe for the plant, typically the same plant. These PDF reports may be transmitted to third parties using text messaging, electronic mail messages and/or any other manner of transmitting the information.

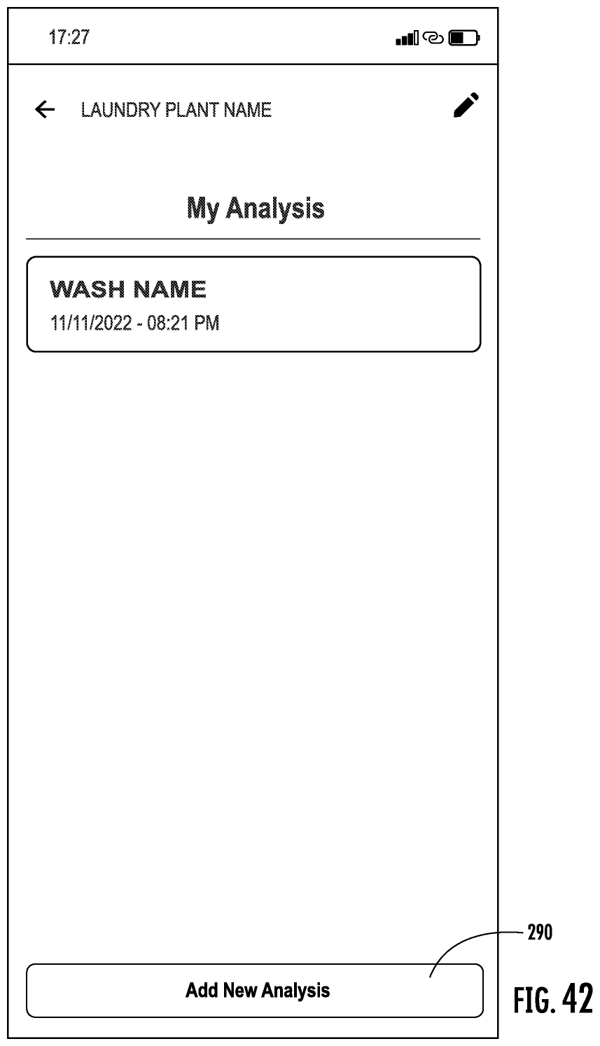

Once an analysis is conducted, the analysis, both past and present may be displayed in an analysis summary listing such as that shown in FIG. 42. By selecting the three vertical dots, the user can delete any analysis previously conducted. Typically, the systems of the present disclosure will have a confirmation prompt to help prevent the accidental deletion of the analysis or data. If a second or subsequent analysis is to be conducted, that process may be initiated by activating the link 290 in FIG. 42.

Upon activation of the login, the user is typically presented with a home page after the first login that shows the washing plants previously created in a graphical user interface such as the one shown in FIG. 46. If the user would like to edit any of the user's personal information or other user information, the user may activate the link of the image of the user or their avatar 292, which causes the graphical user interface of FIG. 47 to be displayed. The personal information of the account holder shown on the interface shown in FIG. 47 typically includes the user's name, electronic mail, and phone number. If a new plant is to be created to run comparisons related thereto, the user may activate the link 294. If the user would like to further evaluate the previously created washing plants, the user may activate the link 296 thereto that is displayed to the user. The three vertical dots 298 or other identifiable link may be used to provide the deletion of the previously inputted washing plant data, again, typically only after confirmation prompting.

What is claimed is:

1. A process for implementing changes to a textile processing facility that positively impact the environmental sustainability, the financial sustainability, or both the environmental sustainability and financial sustainability of the textile processing facility comprising the steps of:
defining a virtual wash plant having virtual pieces of equipment and virtual wash inputs with defined use parameters that include at least parameters related to energy, fuel, water used, carbon dioxide emitted, time, and cost where the use parameters correspond to physical pieces of equipment and physically available wash inputs at the textile processing facility;
defining a baseline recipe for the production of a textile using the virtual wash plant that at least substantially corresponds to a textile processing facility used recipe at the textile processing facility implemented by the physical pieces of equipment and physically available wash inputs at the textile processing facility;
defining an alternate recipe for the production of the textile that is different than the baseline recipe using the virtual wash plant;
determining quantifiable baseline recipe data related to at least: a baseline recipe cost, a baseline recipe energy usage, a baseline recipe water usage, a baseline recipe processing time, and a baseline recipe carbon dioxide usage based on the processing of a textile using the baseline recipe for the production of the textile;
determining the quantifiable alternate recipe data related to at least: an alternate recipe cost, an alternate recipe energy usage, an alternate recipe water usage, an alternate recipe processing time, and an alternate recipe carbon dioxide usage based on the processing of a textile using the alternate recipe for the production of the textile;
determining a set of differences between the baseline recipe and the alternate recipe that includes at least the difference between the baseline recipe cost and the alternate recipe cost, the differences between the baseline recipe energy usage and the alternate recipe energy usage, the difference between the baseline recipe water usage and the alternate recipe water usage, the difference between the baseline recipe processing time and the alternate recipe processing time, and the baseline recipe carbon dioxide usage and the alternate recipe carbon dioxide usage;
displaying a quantitative estimate of at least one of the set of differences to at least one user of a computing system having a graphical user interface that displays the at least one of the set of differences on an output display of a computing device;
determining whether the baseline recipe or the alternate recipe is more environmentally sustainable, financially sustainable, or both more environmentally sustainable and financially sustainable by a processor evaluating the set of differences between the baseline recipe and the alternate recipe; and
changing either or both of: (1) the use parameters corresponding to the physical pieces of equipment and the physically available wash inputs at the textile processing facility; and (2) the physical pieces of equipment and physically available wash inputs at the textile processing facility of the textile processing facility used recipe implemented at the textile processing facility to correspond to at least a portion of the alternate recipe if the alternate recipe is determined to be more environmentally sustainable, more financially sustainable, or both more environmentally sustainable and financially sustainable.

2. The process for implementing changes to a textile processing facility that positively impact the environmental sustainability, the financial sustainability, or both the environmental sustainability and financial sustainability of the textile processing facility of claim 1, wherein the step of defining a washing plant comprises a user (1) selecting one or more listed virtual textile factory pieces of textile processing equipment from a list of virtual textile factory pieces of textile processing equipment displayed on the user's mobile computing device where the one or more listed virtual textile factory pieces of textile processing equipment correspond to a corresponding piece of physical textile processing equipment used in a physical textile processing plant such that the selected one or more listed virtual textile factory pieces of textile processing equipment is added to the virtual wash plant or (2) manually adding at least an identification and an amount of resources and use requirement information related to a new virtual textile factory piece of textile processing equipment via the user's mobile computing device such that the new virtual textile factory piece is added to the virtual wash plant.

3. The process for implementing changes to a textile processing facility that positively impact the environmental sustainability, the financial sustainability, or both the environmental sustainability and financial sustainability of the textile processing facility of claim 2, wherein the virtual wash plant includes one or more virtual textile factory pieces of textile processing equipment that are not currently available for use as a physical textile processing piece of equipment in the textile processing facility.

4. The process for implementing changes to a textile processing facility that positively impact the environmental sustainability, the financial sustainability, or both the environmental sustainability and financial sustainability of the textile processing facility of claim 1, wherein the virtual wash plant includes one or more virtual textile factory pieces of textile processing equipment that are not currently available for use as a physical textile processing piece of equipment in the textile processing facility.

5. The process for implementing changes to a textile processing facility that positively impact the environmental sustainability, the financial sustainability, or both the environmental sustainability and financial sustainability of the textile processing facility of claim 4, wherein the step of defining a baseline recipe for the production of a textile using the virtual wash plant comprises using at least one virtual processing step chosen from the group consisting of: desizing; scouring; stonewashing; biopolishing; mechanical scraping; laser scraping; bleaching; finishing; applying a three-dimensional effect; curing in one or more oven; sandblasting; cleaning to enhance contrast or to remove the effect of back staining on denim; water extraction; drying; rinsing; neutralization; de-fibrillation; nebulization; and any combination of the above.

6. The process for implementing changes to a textile processing facility that positively impact the environmental sustainability, the financial sustainability, or both the environmental sustainability and financial sustainability of the textile processing facility of claim 5, wherein the baseline recipe for the production of a textile corresponds to a physically used recipe employed in a physical textile plant using physical equipment in a physical textile processing facility.

7. The process for implementing changes to a textile processing facility that positively impact the environmental sustainability, the financial sustainability, or both the environmental sustainability and financial sustainability of the textile processing facility of claim 6, wherein the step of providing feedback to the user based on the comparison of the baseline recipe to the alternate recipe comprising graphically displaying the differences to the user in the form of a displayed ring and further comprising a visual display of the quantitative difference in numerical form.

8. The process for implementing changes to a textile processing facility that positively impact the environmental sustainability, the financial sustainability, or both the environmental sustainability and financial sustainability of the textile processing facility of claim 7, wherein the process further comprises the step of a user adding an added virtual textile factory piece of textile processing equipment into the virtual wash plant that is not a physical piece of equipment at the textile washing facility.

9. The process for implementing changes to a textile processing facility that positively impact the environmental sustainability, the financial sustainability, or both the environmental sustainability and financial sustainability of the textile processing facility of claim 8 further comprises the step of installing a physical piece of equipment that corresponds to the added virtual textile factory piece of equipment if the virtual textile factory piece of equipment is part of the alternate recipe when the alternate recipe is the more environmentally sustainable, more financial sustainable, or both more environmentally sustainable and financially sustainable recipe than the baseline recipe.

10. The process for implementing changes to a textile processing facility that positively impact the environmental sustainability, the financial sustainability, or both the environmental sustainability and financial sustainability of the textile processing facility of claim 8, wherein the following data are evaluated for both the baseline recipe and the alternate recipe and used by a processor to determine the baseline recipe cost, the alternate recipe cost, the baseline recipe energy usage, the alternate recipe energy usage, the baseline recipe water usage, the alternate recipe water usage, the baseline recipe processing time, and the alternate recipe processing time, and the baseline recipe carbon dioxide usage and the alternate recipe carbon dioxide usage: the ambient air temperature of the virtual washing plant or the average ambient temperature; the feed water temperature (average or real-time data); the cost per cubic meter of water used by the alternate recipe and the baseline recipe; the overall weight of the garments to be treated; the type of washing machines, including brand, model, weight, maximum rpm speed, capacity, and power consumption; the type of tumble driers, including at least the following factors for the driers: capacity, air flow rate, type of energy used, and electrical power consumption; the type of spinners or centrifuges, including at least the following factors: capacity, and power consumption; the type of auxiliary machines; the amount of water added into the system/process by the auxiliary machine, the volume of water generated by the auxiliary machines, flow rate of water created by the auxiliary machines; the power consumption of the auxiliary machines; a type of scraping machine, a type of laser machine, a mannequin; a type of a boiler or a type of heater; the type of fuel used by the boiler or the heater; the thermal efficiency of the boiler or heater; a fuel used to heat air; a fuel used to heat water; the heat of combustion (kJ/mol) or materials used as fuel; a cost per weight of the used fuel; a geographical area where the textile processing facility is located; a carbon intensity of electricity per country or power suppliers (gCO2/kWh); a cost of the electricity (currency/kWh); an amount by volume of water needed in any washing cycle for each unit of mass of garments (bath ratio); a temperature of the bath in any washing cycle; a duration of each cycle in minutes; an identification of a chemical or chemicals involved in each washing cycle; a dose of the chemical or chemicals used, percentage on the weight of fabrics; and a monetary cost per weight of the chemicals; and
wherein the textile processing facility is an industrial clothing laundry.

11. A process for evaluating and changing an overall textile processing facility to be more sustainable comprising the steps of:
defining a virtual wash plant having virtual pieces of equipment and virtual wash inputs;
defining a baseline recipe for the production of a textile using the virtual wash plant that at least substantially corresponds to a textile processing facility used recipe at the textile processing facility implemented by the physical pieces of equipment and physically available wash inputs at the textile processing facility;
defining an alternate recipe for the production of the textile that is different than the baseline recipe using the virtual wash plant;
determining a set of processing sustainability related cost and input usage differences between the baseline recipe and the alternate recipe;
a user reviewing the set of processing sustainability related cost and input usage differences and determining whether the baseline recipe or the alternate recipe is more environmentally sustainable, financial sustainable, or both environmentally sustainable and financially sustainable based on the set of processing sustainability related cost and input usage differences; and
changing the textile processing facility used recipe at the textile processing facility to correspond to the alternate recipe if the alternate recipe is determined to be more environmentally sustainable, more financially sustainable, or both more environmentally sustainable and financially sustainable than the baseline recipe.

12. The process for evaluating and changing an overall textile processing facility to be more sustainable of claim 11, wherein the step of defining a washing plant comprises a user (1) selecting one or more listed virtual textile factory pieces of textile processing equipment from a list of virtual textile factory pieces of textile processing equipment displayed on the user's mobile computing device where the one or more listed virtual textile factory pieces of textile processing equipment correspond to a corresponding piece of physical textile processing equipment used in a physical textile processing plant such that the selected one or more listed virtual textile factory pieces of textile processing equipment is added to the virtual wash plant or (2) manually adding at least an identification and an amount of resources and use requirement information related to a new virtual textile factory piece of textile processing equipment via the user's mobile computing device such that the new virtual textile factory piece is added to the virtual wash plant.

13. The process for evaluating and changing an overall textile processing facility to be more sustainable of claim 12, wherein the virtual wash plant includes one or more virtual textile factory pieces of textile processing equipment that are not currently available for use as a physical textile processing piece of equipment in the textile processing facility.

14. The process for evaluating changing an overall textile processing facility to be more sustainable of claim 13, wherein the virtual wash plant includes one or more virtual textile factory pieces of textile processing equipment that are not currently available for use as a physical textile processing piece of equipment in the textile processing facility.

15. The process for evaluating and changing an overall textile processing facility to be more sustainable of claim 14, wherein the step of defining a baseline recipe for the production of a textile using the virtual wash plant comprises using at least one virtual processing step chosen from the group consisting of: desizing; scouring; stonewashing; biopolishing; mechanical scraping; laser scraping; bleaching; finishing; applying a three-dimensional effect; curing in one or more oven; sandblasting; cleaning to enhance contrast or to remove the effect of back staining on denim; water extraction; drying; rinsing; neutralization; de-fibrillation; nebulization; and any combination of the above.

16. The process for evaluating and changing an overall textile processing facility to be more sustainable of claim 11, wherein the step of defining a baseline recipe for the production of a textile using the virtual wash plant comprises using at least two virtual processing steps wherein the at least two virtual processing steps are chosen from the group consisting of: desizing; scouring; stonewashing; biopolishing; mechanical scraping; laser scraping; bleaching; finishing; applying a three-dimensional effect; curing in one or more oven; sandblasting; cleaning to enhance contrast or to remove the effect of back staining on denim; water extraction; drying; rinsing; neutralization; de-fibrillation; nebulization; and any combination of the above.

17. The process for evaluating changing an overall textile processing facility to be more sustainable of claim 16, wherein the baseline recipe for the production of a textile corresponds to a physically used recipe employed in a physical textile plant using physical equipment in a physical textile processing facility.

18. The process for evaluating and changing an overall textile processing facility to be more sustainable of claim 17 further comprising the step of providing feedback to the user based on the comparison of the baseline recipe to the alternate recipe comprising graphically displaying the differences to the user in the form of a displayed ring and further comprising a visual display of the quantitative difference in numerical form;
wherein the process further comprises the step of a user adding an added virtual textile factory piece of textile processing equipment into the virtual wash plant that is not a physical piece of equipment at the textile washing facility;
wherein the process further comprises the step of installing a physical piece of equipment that corresponds to the added virtual textile factory piece of equipment if the virtual textile factory piece of equipment is part of the alternate recipe when the alternate recipe is the more environmentally sustainable, more financially sustainable, or both more environmentally sustainable and financially sustainable recipe than the baseline recipe;
wherein the following data are evaluated for both the baseline recipe and the alternate recipe and used by a processor to determine the baseline recipe cost, the alternate recipe cost, the baseline recipe energy usage, the alternate recipe energy usage, the baseline recipe water usage, the alternate recipe water usage, the baseline recipe processing time, and the alternate recipe processing time, and the baseline recipe carbon dioxide usage and the alternate recipe carbon dioxide usage: the ambient air temperature of the virtual washing plant or the average ambient temperature; the feed water temperature (average or real-time data); the cost per cubic meter of water used by the alternate recipe and the baseline recipe; the overall weight of the garments to be treated; the type of washing machines, including brand, model, weight, maximum rpm speed, capacity, and power consumption; the type of tumble driers, including at least the following factors for the driers: capacity, air flow rate, type of energy used, and electrical power consumption; the type of spinners or centrifuges, including at least the following factors: capacity, and power consumption; the type of auxiliary machines; the amount of water added into the system/process by the auxiliary machine, the volume of water generated by the auxiliary machines, flow rate of water created by the auxiliary machines; the power consumption of the auxiliary machines; a type of scraping machine, a type of laser machine, a mannequin; a type of a boiler or a type of heater; the type of fuel used by the boiler or the heater; the thermal efficiency of the boiler or heater; a fuel used to heat air; a fuel used to heat water; the heat of combustion (kJ/mol) or materials used as fuel; a cost per weight of the used fuel; a geographical area where the textile processing facility is located; a carbon intensity of electricity per country or power suppliers (gCO2/kWh); a cost of the electricity (currency/kWh); an amount by volume of water needed in any washing cycle for each unit of mass of garments (bath ratio); a temperature of the bath in any washing cycle; a duration of each cycle in minutes; an identification of a chemical or chemicals involved in each washing cycle; a dose of the chemical or chemicals used, percentage on the weight of fabrics; and a monetary cost per weight of the chemicals; and
wherein the textile processing facility is an industrial clothing laundry.

19. A method of evaluating and altering a textile processing system to improve the sustainability of the textile processing system comprising the steps of:
using a mobile computer system comprising a mobile computing processor, a signal transmitter, and a data signal receiver where the mobile computer system is located at a remote location from a textile process evaluation and comparison server system having one or more server processors;
transmitting data from the mobile computer system to the textile process evaluation and comparison server via the mobile computer system and create a baseline process that emulates an existing process for creating a textile in a textile processing facility that includes a plurality of textile processing equipment and a plurality of textile processing materials where the data transmitted by the user via the mobile computing device includes data corresponding to physical details of the plurality of textile processing equipment and a plurality of data regarding textile processing materials that corresponds to physical details of the textile processing materials;
using the data received from the user via the mobile application supplied to the one or more processors of the textile process evaluation and comparison server system to create and evaluate a plurality of alternative processes used to produce the textile in the textile processing facility that utilizes the plurality of textile processing equipment data and the plurality of data regarding textile processing materials data to generate the plurality of alternative processes that are more environmentally sustainable, financially sustainable or both environmentally sustainable and financially sustainable alternative process;
altering the baseline recipe to coincide with a selected alternative process that is one of the plurality of alternative processes that improves the environmentally sustainable, financially sustainable or both environmentally sustainable and financially sustainable of the textile processing system more than the baseline recipe;
wherein the process further includes the step of automatically changing the selected alternative process based on real-time data received from one or more sensors associated with a water input source, one or more air temperature sensors, a transmitted data from and regarding one or more pieces of equipment being used in the textile processing facility to treat the textile; and
wherein the textile processing materials comprise a textile treating chemical or a plurality of textile treating chemicals.

20. The method of evaluating and altering a textile processing system to improve the sustainability of the textile processing system of claim 19 further comprising the step of determining a certification status of the textile process of the selected alternative process by transmitting the details of the selected alternative process to a remotely located certification association computing system.
